(19) United States
(12) Patent Application Publication
(10) Pub. No.: US 2025/0151610 A1
(43) Pub. Date: May 8, 2025

(54) ORGANOMETALLIC COMPLEX, LIGHT-EMITTING DEVICE, LIGHT-EMITTING APPARATUS, ELECTRONIC APPARATUS, AND LIGHTING DEVICE

(71) Applicant: SEMICONDUCTOR ENERGY LABORATORY CO., LTD, Atsugi-shi, Kanagawa-ken (JP)

(72) Inventors: Toshiaki TSUNOI, Atsugi, Kanagawa (JP); Tomoya YAMAGUCH, Atsugi, Kanagawa (JP); Hideko YOSHIZUMI, Atsugi, Kanagawa (JP); Satoshi SEO, Sagamihara, Kanagawa (JP)

(21) Appl. No.: 18/837,524

(22) PCT Filed: Feb. 9, 2023
(86) PCT No.: PCT/IB2023/051143

§ 371 Date: Aug. 9, 2024

(30) Foreign Application Priority Data
Feb. 18, 2022 (JP) 2022-023701

(51) Int. Cl. H10K 85/30; C07F 7/00; C09K 11/06; H10K 50/11; H10K 85/60

(52) U.S. Cl. CPC H10K 85/351; C07F 7/003; C09K 11/06; H10K 50/11; H10K 85/658; C09K 2211/188

(57) ABSTRACT

A novel organometallic complex that improves emission efficiency of a light-emitting device is provided. The organometallic complex represented by General Formula (G1) is provided. In the formula, X represents carbon or nitrogen, and the carbon is bonded to any one of hydrogen (including deuterium), a substituted or unsubstituted alkyl group, a substituted or unsubstituted cycloalkyl group, and a substituted or unsubstituted aryl group. Furthermore, R1 to R3 each independently represent any one of hydrogen (including deuterium), a substituted or unsubstituted alkyl group, a substituted or unsubstituted cycloalkyl group, and a substituted or unsubstituted aryl group. Furthermore, n represents an integer greater than or equal to 1 and less than or equal to 4. The borate ligands may be the same or different from each other. Furthermore, n's may be the same or different from each other. In the case where n is 2 or more, X's, R1's, and R2's may be the same or different from each other. In the case where n is 2 or less, R3's may be the same or different from each other.

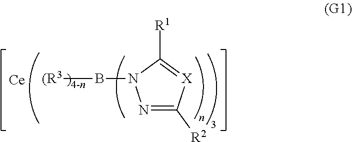

### TECHNICAL FIELD

One embodiment of the present invention relates to an organometallic complex, an organic compound, an organic semiconductor element, a light-emitting device, a light-emitting element, an organic EL element, an organic EL element, a photodiode sensor, a light-receiving device, a light-receiving element, a display module, a lighting module, a display apparatus, a light-emitting apparatus, an electronic apparatus, a lighting device, and an electronic device. Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor device, a display apparatus, a liquid crystal display apparatus, a light-emitting apparatus, a lighting device, a power storage device, a memory device, an imaging device, a driving method thereof, and a manufacturing method thereof.

### BACKGROUND ART

Light-emitting devices including organic compounds and utilizing electroluminescence (EL) (also referred to as light-emitting elements or organic EL elements) have been put into practical use. In the basic structure of such light-emitting devices, an organic compound layer containing a light-emitting material (an EL layer) is held between a pair of electrodes. Carriers are injected by application of voltage to the device, and recombination energy of the carriers is used, whereby light emission can be obtained from the light-emitting material.

Since organic EL elements are of self-luminous type, display apparatuses in which the elements are used for pixels have higher visibility than liquid crystal display apparatuses and do not need a backlight. Display apparatuses including such organic EL elements are also highly advantageous in that they can be thin and lightweight. Another feature is an extremely fast response speed.

Since light-emitting layers of such organic EL elements can be successively formed in a planar form, planar light emission can be obtained. This feature is difficult to realize with point light sources typified by incandescent lamps and LEDs or linear light sources typified by fluorescent lamps; thus, the organic EL elements also have great potential as planar light sources, which can be applied to lighting and the like.

Display apparatuses and lighting devices that include organic EL elements are suitable for a variety of electronic apparatuses as described above, and research and development of organic EL elements have progressed for better characteristics.

For example, Non-Patent Document 1 reports an organic EL element that includes a lanthanoid complex as a novel light-emitting dopant.

### REFERENCE

### Non-Patent Document

[Non-Patent Document 1] Liding Wang and six others, “Review on the Electroluminescence Study of Lanthanide Complexes”, Advanced Optical Materials, 2019, 7, 1801256

### SUMMARY OF THE INVENTION

### Problems to be Solved by the Invention

As described in Non-Patent Document 1, there are very few examples of considering the use of such an organic complex as a light-emitting substance (also referred to as a dopant) of an organic EL element, and sufficient consideration has not yet been carried out. Therefore, there is plenty of room for improvement in the performance of such an organic complex related to display quality, such as chromaticity or color purity, and development is expected.

In view of the above, one embodiment of the present invention provides a novel organometallic complex. One embodiment of the present invention provides a novel organometallic complex that can be used in a light-emitting device. One embodiment of the present invention provides a novel organometallic complex that can be used in an EL layer of a light-emitting device. An object of one embodiment of the present invention is to improve emission efficiency of a light-emitting device. An object of one embodiment of the present invention is to increase reliability of a light-emitting device. One embodiment of the present invention provides a novel light-emitting device.

Another object of one embodiment of the present invention is to provide a light-emitting device with high emission efficiency. Another object of one embodiment of the present invention is to provide a light-emitting device, a light-emitting apparatus, an electronic apparatus, a display apparatus, and an electronic device each having low power consumption.

Note that the description of these objects does not preclude the existence of other objects. One embodiment of the present invention does not necessarily need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is an organometallic complex represented by General Formula (G1).

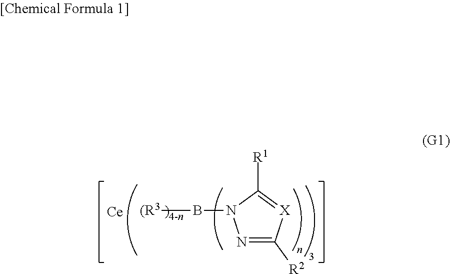

In General Formula (G1), X represents carbon or nitrogen, and the carbon is bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R¹ to R³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, n represents an integer greater than or equal to 1 and less than or equal to 4. The borate ligands may be the same or different from each other. Furthermore, n of one borate ligand may be the same as or different from n of another borate ligand. In the case where n is 2 or more, X of one borate ligand may be the same as or different from X of another borate ligand, R¹ of one borate ligand may be the same as or different from R¹ of another borate ligand, and R² of one borate ligand may be the same as or different from R² of another borate ligand. In the case where n is 2 or less, R³ of one borate ligand may be the same as or different from R³ of another borate ligand.

Another embodiment of the present invention is an organometallic complex represented by General Formula (G2).

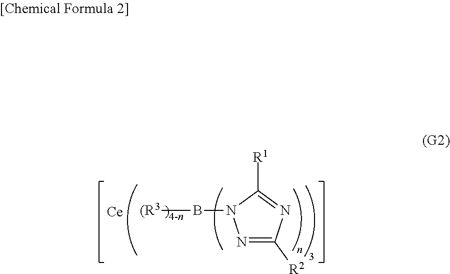

In General Formula (G2), R¹ to R³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, n represents an integer greater than or equal to 1 and less than or equal to 4. The borate ligands may be the same or different from each other. Furthermore, n of one borate ligand may be the same as or different from n of another borate ligand. In the case where n is 2 or more, X of one borate ligand may be the same as or different from X of another borate ligand, R¹ of one borate ligand may be the same as or different from R¹ of another borate ligand, and R² of one borate ligand may be the same as or different from R² of another borate ligand. In the case where n is 2 or less, R³ of one borate ligand may be the same as or different from R³ of another borate ligand.

Another embodiment of the present invention is an organometallic complex represented by General Formula (G3).

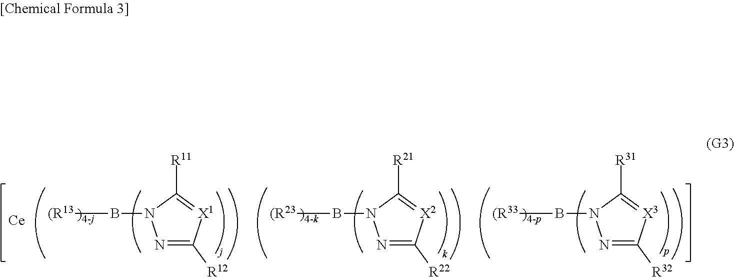

In General Formula (G3), X¹ to X³ each independently represent carbon or nitrogen, and the carbons are each independently bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R¹¹ to R¹³, R²¹ to R²³, and R³¹ to R³³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, j, k, and p each independently represent an integer greater than or equal to 1 and less than or equal 10 to 4. In the case where j is 2 or more, X¹¹'s may be the same or different from each other, R¹¹'s may be the same or different from each other, and R¹²'s may be the same or different from each other. In the case where k is 2 or more, X²'s may be the same or different from each other, R²¹'s may be the same or different from each other, and R²²'s may be the same or different from each other. In the case where p is 2 or more, X³'s may be the same or different from each other, R³¹'s may be the same or different from each other, and R³²'s may be the same or different from each other. In the case where j is 2 or less, R¹³'s may be the same or different from each other. In the case where k is 2 or less, R²³'s may be the same or different from each other. In the case where p is 2 or less, R³³'s may be the same or different from each other.

Another embodiment of the present invention is an organometallic complex represented by General Formula (G3′).

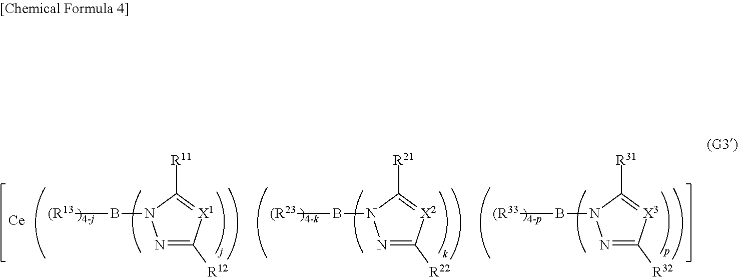

In General Formula (G3′), X¹ to X³ each independently represent carbon or nitrogen, and the carbons are each independently bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R¹¹ to R¹³, R²¹ to R²³, and R³¹ to R³³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, j represents an integer greater than or equal to 1 and less than or equal to 3. Furthermore, k and p each independently represent an integer greater than or equal to 1 and less than or equal to 4. In the case where j is 2 or more, X¹'s may be the same or different from each other, R¹¹'s may be the same or different from each other, and R¹²'s may be the same or different from each other. In the case where k is 2 or more, X²'s may be the same or different from each other, R²¹'s may be the same or different from each other, and R²²'s may be the same or different from each other. In the case where p is 2 or more, X³'s may be the same or different from each other, R³¹'s may be the same or different from each other, and R³²'s may be the same or different from each other. In the case where j is 2 or less, R¹³'s may be the same or different from each other. In the case where k is 2 or less, R²³'s may be the same or different from each other. In the case where p is 2 or less, R³³'s may be the same or different from each other.

Another embodiment of the present invention is an organometallic complex represented by General Formula (G4).

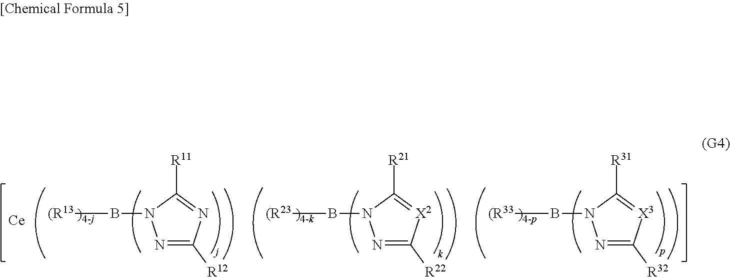

In General Formula (G4), X² and X³ each independently represent carbon or nitrogen, and the carbons are each independently bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R¹¹ to R¹³, R²¹ to R²³, and R³¹ to R³³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, j, k, and p each independently represent an integer greater than or equal to 1 and less than or equal to 4. In the case where j is 2 or more, R¹¹'s may be the same or different from each other and R¹²'s may be the same or different from each other. In the case where k is 2 or more, X²'s may be the same or different from each other, R²¹'s may be the same or different from each other, and R²²'s may be the same or different from each other. In the case where p is 2 or more, X³'s may be the same or different from each other, R³¹'s may be the same or different from each other, and R³²'s may be the same or different from each other. In the case where j is 2 or less, R¹³'s may be the same or different from each other. In the case where k is 2 or less, R²³'s may be the same or different from each other. In the case where p is 2 or less, R³³'s may be the same or different from each other.

Another embodiment of the present invention is an organometallic complex represented by General Formula (G5).

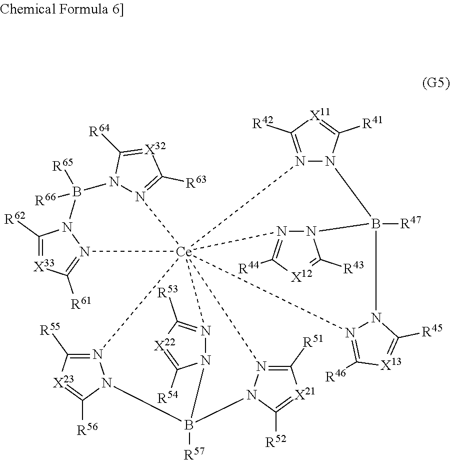

In General Formula (G5), X¹¹ to X¹³, X²¹ to X²³, X³¹, and X³² each independently represent carbon or nitrogen, and the carbons are each independently bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R⁴¹ to R⁴⁷, R⁵¹ to R⁵⁷, and R⁶¹ to R⁶⁶ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms.

Another embodiment of the present invention is organometallic complexes represented by Structural Formulae (125) and (150).

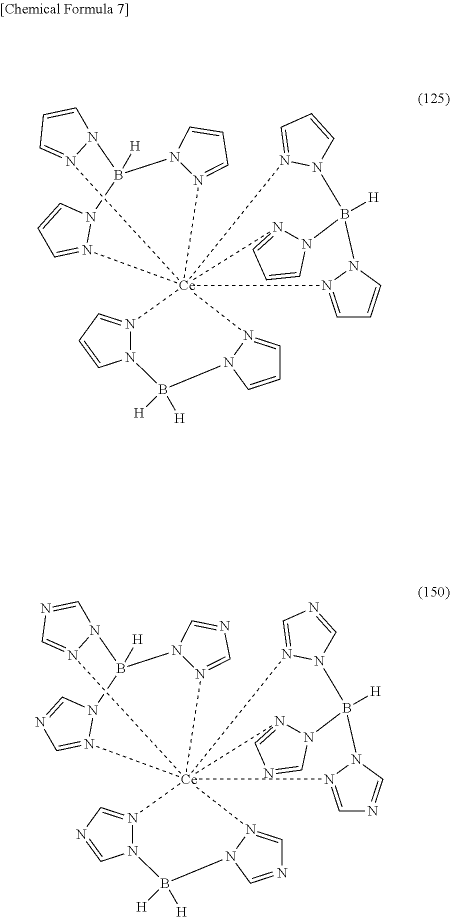

Another embodiment of the present invention is a light-emitting device containing the organic compound having any of the above structures.

Another embodiment of the present invention is a light-emitting apparatus including the light-emitting device with the above structure, and a transistor or a substrate.

Another embodiment of the present invention is an electronic apparatus including the light-emitting apparatus with the above structure, and a detecting portion, an input portion, or a communication portion.

Another embodiment of the present invention is a lighting device including the light-emitting apparatus with the above structure and a housing.

Note that the light-emitting apparatus in this specification includes, in its category, an image display device that uses a light-emitting device. The light-emitting apparatus may also include a module in which a light-emitting device over a substrate is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method. Furthermore, in some cases, lighting equipment or the like includes the light-emitting apparatus.

### Effect of the Invention

According to one embodiment of the present invention, a novel organometallic complex can be provided. According to one embodiment of the present invention, a novel organometallic complex that can be used in a light-emitting device can be provided. According to one embodiment of the present invention, a novel organometallic complex that can be used in an EL layer of a light-emitting device can be used. One embodiment of the present invention can improve emission efficiency of alight-emitting device. One embodiment of the present invention can increase reliability of a light-emitting device. According to one embodiment of the present invention, a novel light-emitting device can be provided.

According to another embodiment of the present invention, a light-emitting device with high emission efficiency can be provided. According to another embodiment of the present invention, a light-emitting device, a light-emitting apparatus, an electronic apparatus, a display apparatus, and an electronic device each having low power consumption can be provided.

Note that the description of these effects does not preclude the existence of other effects. Note that one embodiment of the present invention does not need to have all of these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A to FIG. 1E are diagrams illustrating structures of a light-emitting device of an embodiment.

FIG. 2A to FIG. 2D are diagrams illustrating a light-emitting apparatus of an embodiment.

FIG. 3A to FIG. 3C are diagrams illustrating a method for manufacturing a light-emitting apparatus of an embodiment.

FIG. 4A to FIG. 4C are diagrams illustrating a method for manufacturing a light-emitting apparatus of an embodiment.

FIG. 5A to FIG. 5C are diagrams illustrating a method for manufacturing a light-emitting apparatus of an embodiment.

FIG. 6A to FIG. 6D are diagrams illustrating a method for manufacturing a light-emitting apparatus of an embodiment.

FIG. 7A to FIG. 7D are diagrams illustrating a light-emitting apparatus of an embodiment.

FIG. 8A to FIG. 8C are diagrams illustrating a light-emitting apparatus of an embodiment.

FIG. 9A to FIG. 9F are diagrams illustrating an apparatus and pixel arrangement of an embodiment.

FIG. 10A to FIG. 10C are diagrams illustrating pixel circuits of an embodiment.

FIG. 11 is a diagram illustrating a light-emitting apparatus of an embodiment.

FIG. 12A to FIG. 12E are diagrams illustrating electronic apparatuses of an embodiment.

FIG. 13A to FIG. 13E are diagrams illustrating electronic apparatuses of an embodiment.

FIG. 14A and FIG. 14B are diagrams illustrating electronic apparatuses of an embodiment.

FIG. 15A and FIG. 15B are diagrams illustrating alighting device of an embodiment.

FIG. 16 is a diagram illustrating a lighting device of an embodiment.

FIG. 17A to FIG. 17C are diagrams illustrating a light-emitting device and a light-receiving device of an embodiment.

FIG. 18A and FIG. 18B are diagrams each illustrating a light-emitting device and a light-receiving device of an embodiment.

FIG. 19 shows an absorption spectrum and an emission spectrum of [Ce(bpz₃)₂(bpz₂)] in a dichloromethane solution.

FIG. 20 shows an emission spectrum of [Ce(btaz₃)₂(btaz₂)] in a dichloromethane solution.

FIG. 21 shows an emission spectrum of a powder of [Ce(btaz₃)₂(btaz₂)].

FIG. 22 is a diagram illustrating a structure of a light-emitting device 1.

FIG. 23 is a diagram showing the luminance-current density characteristics of the light-emitting device 1.

FIG. 24 is a diagram showing the current efficiency-luminance characteristics of the light-emitting device 1.

FIG. 25 is a diagram showing the luminance-voltage characteristics of the light-emitting device 1.

FIG. 26 is a diagram showing the current-voltage characteristics of the light-emitting device 1.

FIG. 27 is a diagram showing the external quantum efficiency-luminance characteristics of the light-emitting device 1.

FIG. 28 is a diagram showing the emission spectrum of the light-emitting device 1.

### MODE FOR CARRYING OUT THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

### Embodiment 1

It is a long time since displays (organic EL displays) that include organic EL elements as display elements were put into practical use. These displays are usually provided with pixels emitting light with at least three colors of red, green, and blue to achieve full-color display.

The pixels are provided with light-emitting devices for the respective emission colors. In a display fabricated by a side-by-side method, or what is called a separate coloring method, light-emitting devices contain light-emitting substances corresponding to the respective emission colors of the pixels.

Examples of the light-emitting substances often used in such light-emitting devices include a fluorescent substance emitting light from a singlet excited state, a substance exhibiting thermally activated delayed fluorescence (TADF), and a phosphorescent substance emitting light from a triplet excited state, and these substances have undergone intensive research.

It is known that in organic EL elements in which excitation occurs by current, the theoretical limit of the internal quantum efficiency of a fluorescent substance, which can utilize only a singlet excited state for light emission, is 25% since the ratio between the generation probability of a singlet excited state and that of a triplet excited state is 1:3. By contrast, a phosphorescent substance can convert a singlet excited state into a triplet excited state through intersystem crossing and thus enables an internal quantum efficiency of 100% theoretically, which allows a light-emitting device to have high emission efficiency. This is why phosphorescent substances are used in red- and green-light-emitting devices in currently commercialized organic EL displays in many cases.

However, even in a display in which phosphorescent substances are used in red- and green-light-emitting devices, not a phosphorescent substance but a fluorescent substance with lower efficiency is used in a blue-light-emitting device in most cases. The reason why a fluorescent substance is used in a blue-light-emitting device is not because of its efficiency but its reliability mainly. Generally, light-emitting devices using a phosphorescent substance as a dopant have short lifetimes and have difficulty in achieving high reliability. As a result, almost all the blue-light-emitting devices used in the organic EL displays that are now commercially available are fluorescent devices. Solving the lifetime problem would make it possible that organic EL displays have significantly improved performance by including blue phosphorescent substances with high emission efficiency in blue-light-emitting devices. The short lifetime of blue phosphorescent devices has two fundamental causes.

The first cause is that the energy of the triplet state of a common substance is lower than the energy of the singlet state thereof. Since blue light emission needs high energy, in order to obtain blue light emission from a triplet excited state, a substance having a higher triplet excited level than substances for the other two colors is necessary. In such a substance, generally, a singlet excited level is much higher, and the substance having such a level is likely to be unstable. In the case where a host material is used, the host material needs to be a substance having a triplet excited level and a singlet excited level of still much higher energy levels.

The second cause is that a phosphorescent substance has a long emission lifetime (also referred to as phosphorescence lifetime). Transition from a triplet excited state to a singlet ground state is spin-forbidden, whereas transition from a singlet excited state to a singlet ground state is spin-allowed; thus, the emission lifetime of phosphorescence is much longer than that of fluorescence (phosphorescence lifetime: ˜μs, fluorescence lifetime: ˜ns). A long phosphorescence lifetime means a long lifetime of a triplet exciton. Therefore, in a phosphorescent device, a light-emitting substance keeps being in a high-energy excited state for a long time, which promotes deterioration of the light-emitting substance or nearby substances.

Since the energy of the blue phosphorescent device in an excited state is higher than the energy of the phosphorescent devices of the other two colors, the blue phosphorescent device is affected more strongly by the influence of the exciton lifetime than the red phosphorescent device and the green phosphorescent device; thus, it is still difficult to obtain reliability sufficient for practical use.

Incidentally, the aforementioned TADF material, which emits light from a singlet excited state and is thus a kind of fluorescent substance, allows reverse intersystem crossing. Thus, triplet excitation energy can be converted into singlet excitation energy; and the TADF material can achieve an internal quantum efficiency of 100% theoretically, like a phosphorescent material. Thus, a light-emitting device including a TADF material as a dopant and a light-emitting device including a TADF material as a host and a fluorescent material as a dopant have been proposed, and both of the light-emitting devices have results of an internal quantum efficiency more than 25%. However, the TADF material suffers from the problem of a triplet excited level like a phosphorescent material, and the exciton lifetime is long because reverse intersystem crossing is forbidden; thus, the TADF material now has difficulty in achieving sufficient reliability like a blue phosphorescent device.

Here, organic complexes of Ce³⁺(4^{f1}) and Eu²⁺(4^{f7}) that emit light through f-d transition, which is a transition between an f orbital and a d orbital, are known. Both the ground state and the excited state of each of the organic complexes are doublet, and each of the organic complexes emits light from the doublet excited state. As described above, in the case where excitation occurs by current, the singlet excited level and the triplet excited level are generated at a ratio of 1:3 from the singlet ground state. Since both the ground state and the excited state of each of the organic complexes are doublet, each of the organic complexes is not subjected to restriction of a spin selection rule and enables generation of the doublet excited state with a probability of 100% theoretically, and an internal quantum efficiency of 100% can be achieved.

Although transition between different orbitals is sometimes parity-forbidden, the f-d transition is parity-allowed; thus, the transition rate is high and the exciton lifetime of the above-described organic complexes is short. Note that in particular, since the f-d transition of Ce³⁺(4^{f1}) is completely spin-allowed, the transition rate is substantially equivalent to that of a fluorescent material, i.e., extremely high.

As described above, the organic complexes of Ce³⁺(4^{f1}) and Eu²⁺(4^{f7}), each of which emits light from a doublet excited state due to the f-d transition, can have an internal quantum efficiency of 100% and have a short exciton lifetime, and this reveals that the organic complexes are each a light-emitting substance that is expected to have high efficiency and high reliability in a light-emitting device.

When organic complexes of Ce³⁺ and Eu²⁺ are used as light-emitting substances, the emission efficiency and reliability of a blue-light-emitting device can be improved.

In view of the above, in one embodiment of the present invention, an organic complex of Ce³⁺ having three borate ligands is provided. The borate ligand includes B⁻ and a group forming a covalent bond with B⁻. Part or all of the group forming a covalent bond with B⁻ includes an unshared electron pair that can be coordinated to Ce³⁺. With the use of such a borate ligand, the organic complex of Ce³⁺ that is stable in an excited state and is less likely to be decomposed by heat can be generated.

As the group forming a covalent bond with B⁻ in the borate ligand, a heteroaryl group having two or more nitrogen atoms can be used; specifically, one or both of a pyrazolyl group and a triazolyl group can be given. By supplying an unshared electron pair in a nitrogen atom of a pyrazolyl group or a triazolyl group, a borate ligand can be coordinated to Ce³⁺.

However, an excess total number of pyrazolyl groups and triazolyl groups each of which form a covalent bond with B⁻ might increase the molecular weight of the whole organic complex and degrade the sublimability of the organic complex. Thus, it is preferable that the total number of pyrazolyl groups and triazolyl groups in the whole organic complex be adjusted by synthesizing a borate ligand in which the number of pyrazolyl groups and the number of triazolyl groups is controlled to be the objective number and coordinating the borate ligand to Ce³⁺.

Note that in this specification, the description of a pyrazolyl group and a triazolyl group is applicable to both an organic complex having both a pyrazolyl group and a triazolyl group and an organic complex having only one of a pyrazolyl group and a triazolyl group.

The coordination number of Ce³⁺ is preferably greater than or equal to 7 and less than or equal to 9, further preferably 8. Thus, the total number of pyrazolyl groups and triazolyl groups in the organic complex is preferably greater than or equal to 7 and less than or equal to 9, further preferably 8. By setting the total number of pyrazolyl groups and triazolyl groups in this manner, an organic complex that is stable and has a high sublimability can be provided. Therefore, such an organic complex is suitably used as a light-emitting material of a light-emitting device.

Note that an alkyl group, a cycloalkyl group, or an aryl group may be bonded to one or more of the pyrazolyl group and the triazolyl group included in the borate ligand. By changing the kinds of these substituents, steric hindrance is controlled, and the bond distance between the borate ligand and Ce³⁺ is changed, so that emission color can be adjusted. Moreover, by changing the kinds of these substituents, the reliability can be expected to be improved.

In the borate ligand, an alkyl group, a cycloalkyl group, or an aryl group may be bonded to B⁻. By changing the kinds of these substituents, steric hindrance is controlled, and the bond distance between the borate ligand and Ce³⁺ is changed, so that emission color can be adjusted. Moreover, by changing the kinds of these substituents, the reliability of an organometallic complex can be expected to be improved.

That is, one embodiment of the present invention is an organometallic complex represented by General Formula (G1).

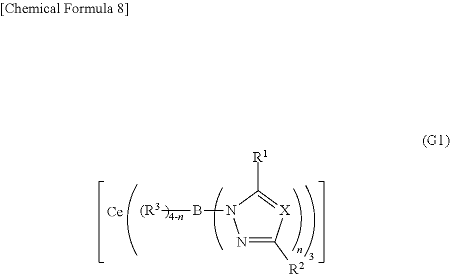

In General Formula (G1), X represents carbon or nitrogen, and the carbon is bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R¹ to R³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, n represents an integer greater than or equal to 1 and less than or equal to 4. The borate ligands may be the same or different from each other. Furthermore, n of one borate ligand may be the same as or different from n of another borate ligand. In the case where n is 2 or more, X of one borate ligand may be the same as or different from X of another borate ligand, R¹ of one borate ligand may be the same as or different from R¹ of another borate ligand, and R² of one borate ligand may be the same as or different from R² of another borate ligand. In the case where n is 2 or less, R³ of one borate ligand may be the same as or different from R³ of another borate ligand.

One embodiment of the present invention is an organometallic complex represented by General Formula (G2).

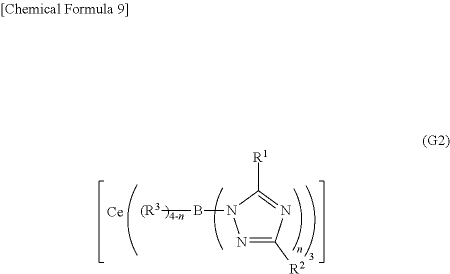

In General Formula (G2), each of R¹ to R³ independently represents any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, n represents an integer greater than or equal to 1 and less than or equal to 4. The borate ligands may be the same or different from each other. Furthermore, n of one borate ligand may be the same as or different from n of another borate ligand. In the case where n is 2 or more, X of one borate ligand may be the same as or different from X of another borate ligand; R¹ of one borate ligand may be the same as or different from R¹ of another borate ligand; and R² of one borate ligand may be the same as or different from R² of another borate ligand. In the case where n is 2 or less, R³ of one borate ligand may be the same as or different from R³ of another borate ligand.

In the case of an organic complex of Ce³⁺ including a borate ligand having a triazolyl group like the organometallic complex represented by General Formula (G2), molar absorption coefficient can be increased because ligand field splitting can be made small.

Note that as described above, the total number of pyrazolyl groups and triazolyl groups in the organic complex of Ce³⁺ is preferably greater than or equal to 7 and less than or equal to 9, further preferably 8. Therefore, in General Formulae (G1) and (G2), the sum of three n's is preferably greater than or equal to 7 and less than or equal to 9, and is further preferably 8.

One embodiment of the present invention is an organometallic complex represented by General Formula (G3).

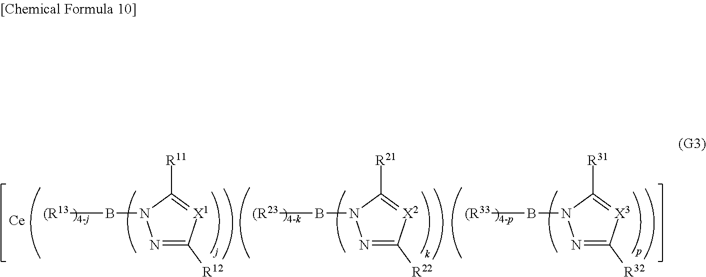

In General Formula (G3), X¹ to X³ each independently represent carbon or nitrogen, and the carbons are each independently bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R¹¹ to R¹³, R²¹ to R²³, and R³¹ to R³³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, j, k, and p each independently represent an integer greater than or equal to 1 and less than or equal to 4. In the case where j is 2 or more, X¹¹'s may be the same or different from each other, R¹¹'s may be the same or different from each other, and R¹²'s may be the same or different from each other. In the case where k is 2 or more, X²'s may be the same or different from each other, R²¹'s may be the same or different from each other, and R²²'s may be the same or different from each other. In the case where p is 2 or more, X³'s may be the same or different from each other, R³¹'s may be the same or different from each other, and R³²'s may be the same or different from each other. In the case where j is 2 or less, R¹³'s may be the same or different from each other. In the case where k is 2 or less, R²³'s may be the same or different from each other. In the case where p is 2 or less, R³³'s may be the same or different from each other.

One embodiment of the present invention is an organometallic complex represented by General Formula (G3′).

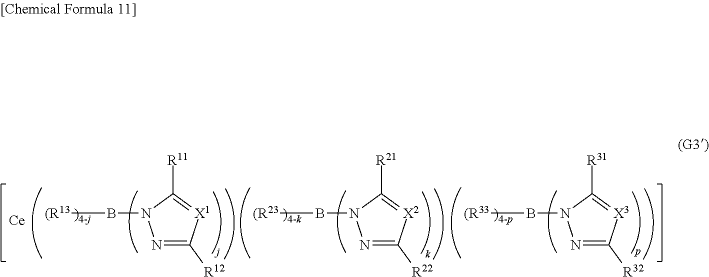

In General Formula (G3′), X¹ to X³ each independently represent carbon or nitrogen, and the carbons are each independently bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R¹¹ to R¹³, R²¹ to R²³, and R³¹ to R³³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, j represents an integer greater than or equal to 1 and less than or equal to 3. Furthermore, k and p each independently represent an integer greater than or equal to 1 and less than or equal to 4. In the case where j is 2 or more, X¹¹'s may be the same or different from each other, R¹¹'s may be the same or different from each other, and R¹²'s may be the same or different from each other. In the case where k is 2 or more, X²'s may be the same or different from each other, R²¹'s may be the same or different from each other, and R²²'s may be the same or different from each other. In the case where p is 2 or more, X³'s may be the same or different from each other, R³¹'s may be the same or different from each other, and R³²'s may be the same or different from each other. In the case where j is 2 or less, R¹³'s may be the same or different from each other. In the case where k is 2 or less, R²³'s may be the same or different from each other. In the case where p is 2 or less, R³³'s may be the same or different from each other.

One embodiment of the present invention is an organometallic complex represented by General Formula (G4).

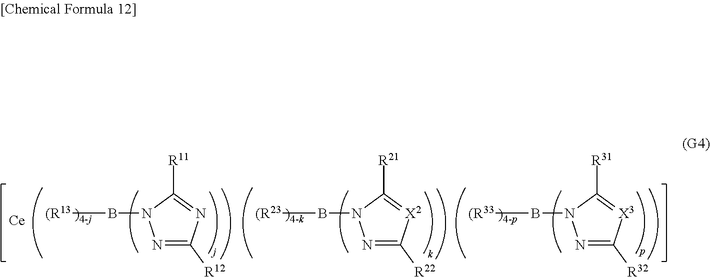

In General Formula (G4), X² and X³ each independently represent carbon or nitrogen, and the carbons are each independently bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R¹¹ to R¹³, R²¹ to R²³, and R³¹ to R³³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, j, k, and p each independently represent an integer greater than or equal to 1 and less than or equal to 4. In the case where j is 2 or more, R¹¹'s may be the same or different from each other and R¹²'s may be the same or different from each other. In the case where k is 2 or more, X²'s may be the same or different from each other, R²¹'s may be the same or different from each other, and R²²'s may be the same or different from each other. In the case where p is 2 or more, X³'s may be the same or different from each other, R³¹'s may be the same or different from each other, and R³²'s may be the same or different from each other. In the case where j is 2 or less, R¹³'s may be the same or different from each other. In the case where k is 2 or less, R²³'s may be the same or different from each other. In the case where p is 2 or less, R³³'s may be the same or different from each other.

When an organic complex of Ce³⁺ includes a borate ligand having at least one triazolyl group like the organometallic complex represented by General Formula (G4), molar absorption coefficient can be increased because ligand field splitting can be made small.

Note that as described above, the total number of pyrazolyl groups and triazolyl groups in the organic complex of Ce³⁺ is preferably greater than or equal to 7 and less than or equal to 9, further preferably 8. Therefore, in General Formulae (G3), (G3′), and (G4), the sum of j, k, and p is preferably greater than or equal to 7 and less than or equal to 9, and is further preferably 8.

One embodiment of the present invention is an organometallic complex represented by General Formula (G5).

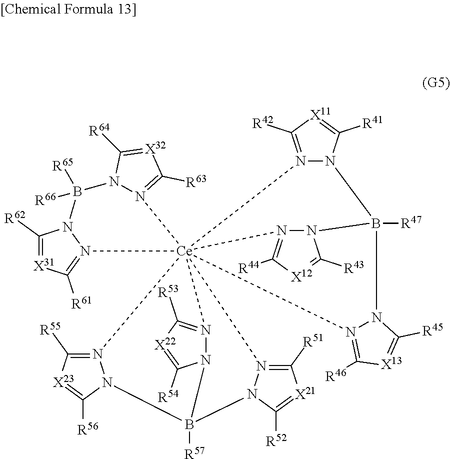

In General Formula (G5), X¹¹ to X¹³, X²¹ to X²³, X³¹, and X³² each independently represent carbon or nitrogen, and the carbons are each independently bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R⁴¹ to R⁴⁷, R⁵¹ to R⁵⁷, and R⁶¹ to R⁶⁶ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms.

Like the organometallic complex represented by General Formula (G5), the organic complex preferably includes two borate ligands each having pyrazolyl groups and/or triazolyl groups to have three groups in total and one borate ligand having pyrazolyl groups and/or triazolyl groups to have two groups in total, in which case the coordination number of Ce³⁺ can be 8. With such a structure, the organometallic complex can be stable and have a high sublimability. Thus, the organometallic complex can be suitably used as a light-emitting material of the light-emitting device.

In General Formulae (G1) to (G5) above, specific examples of the alkyl group having 1 to 10 carbon atoms include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group. In the case where the alkyl group having 1 to 10 carbon atoms includes a substituent, the substituent is an alkyl group having 1 to 4 carbon atoms, a cycloalkyl group having 3 to 6 carbon atoms, or an aryl group having 6 to 13 carbon atoms.

Specific examples of the cycloalkyl group having 3 to 10 carbon atoms in General Formulae (G1) to (G5) above include a cyclopropyl group, a cyclobutyl group, a methylcyclobutyl group, a cyclopentyl group, a methylcyclopentyl group, an isopropylcyclopentyl group, a tert-butylcyclopropyl group, a cyclohexyl group, a methylcyclohexyl group, an isopropylcyclohexyl group, a tert-butylcyclohexyl group, a cycloheptyl group, a methylcycloheptyl group, an isopropylcycloheptyl group, a cyclooctyl group, a methylcyclooctyl group, a cyclononyl group, a methylcyclononyl group, and a cyclodecyl group. In the case where the cycloalkyl group having 3 to 10 carbon atoms includes a substituent, the substituent is an alkyl group having 1 to 4 carbon atoms, a cycloalkyl group having 3 to 6 carbon atoms, or an aryl group having 6 to 13 carbon atoms.

Examples of the aryl group having 6 to 30 carbon atoms in General Formulae (G1) to (G5) above include a phenyl group, an o-tolyl group, an m-tolyl group, a p-tolyl group, a mesityl group, an o-biphenyl group, an m-biphenyl group, a p-biphenyl group, a 1-naphthyl group, a 2-naphthyl group, a fluorenyl group, a 9,9-dimethylfluorenyl group, a 9,9-diphenylfluorenyl group, a spirofluorenyl group, a phenanthrenyl group, a terphenyl group, an anthracenyl group, and a fluoranthenyl group. In the case where the substituted or unsubstituted aryl group having 6 to 30 carbon atoms has a substituent, the substituent is an alkyl group having 1 to 4 carbon atoms, a cycloalkyl group having 3 to 6 carbon atoms, or an aryl group having 6 to 13 carbon atoms.

As described above, by introducing these substituents, steric hindrance in the organometallic complex is controlled, and the bond distance between the borate ligand and Ce³⁺ is changed, so that emission color can be adjusted. Furthermore, by introducing these substituents, the reliability of an organometallic complex can be expected to be improved. For example, when a methyl group is introduced, appropriate steric hindrance can be obtained; thus, the reliability of the organometallic complex can be improved.

The following shows specific examples of the organometallic complex of one embodiment of the present invention and the organometallic complex that can be used for the light-emitting device of one embodiment of the present invention, which have any of the structures represented by General Formulae (G1) to (G5) above.

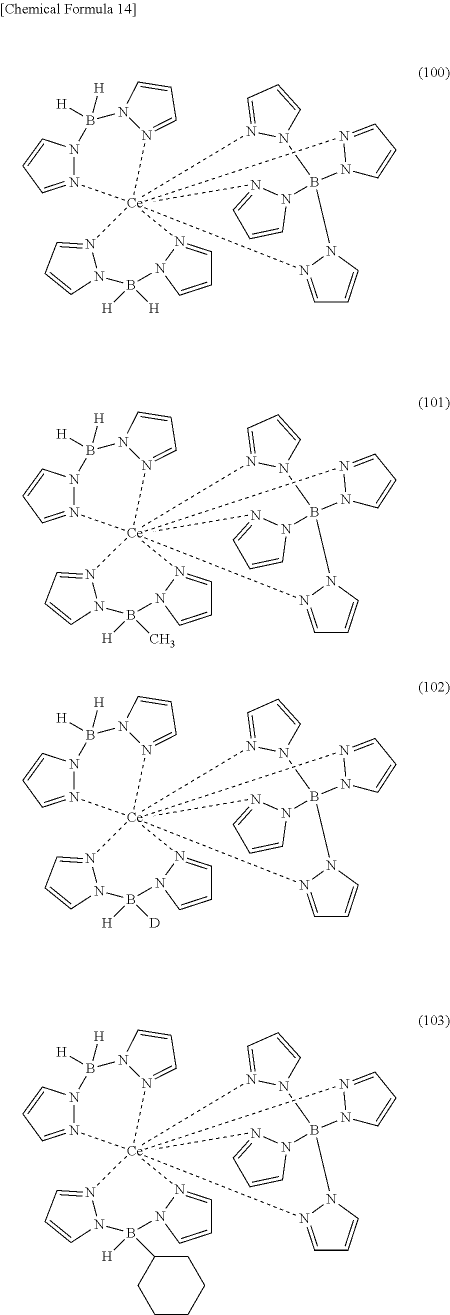

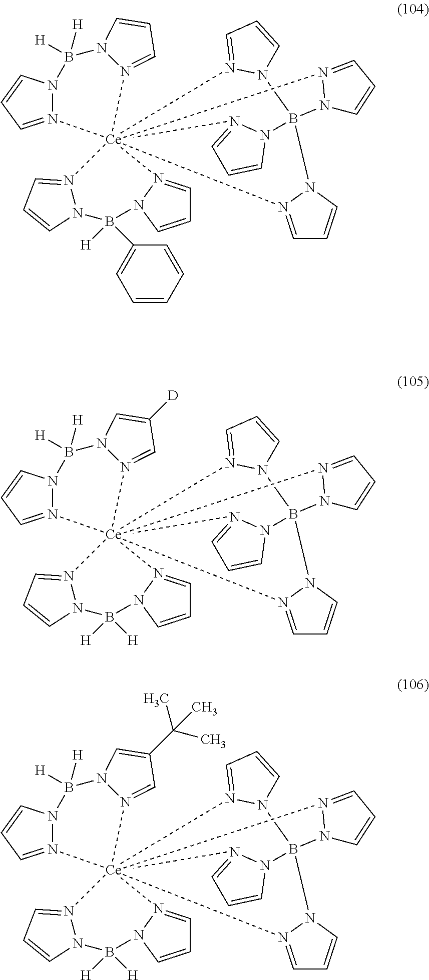

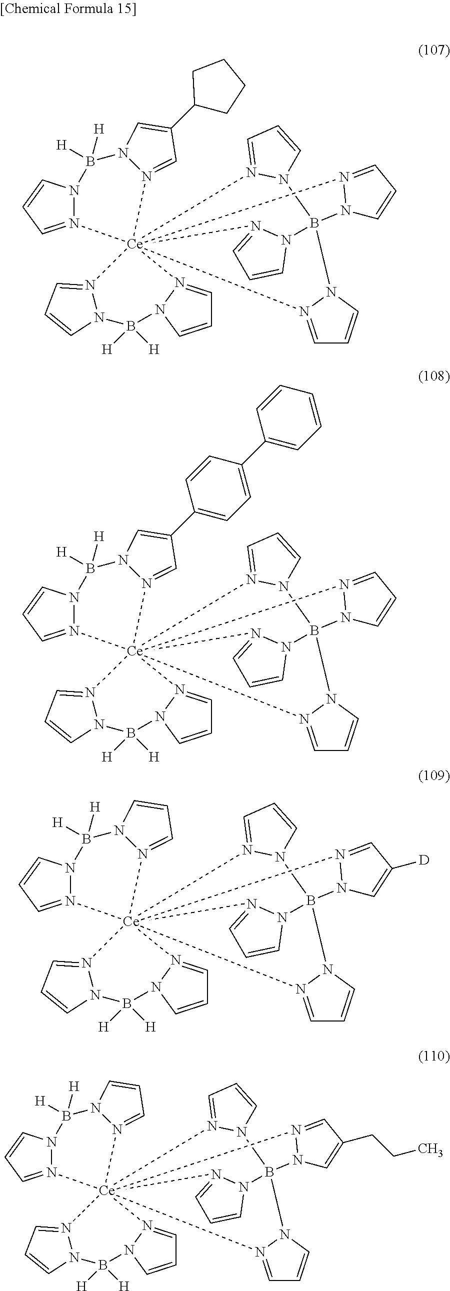

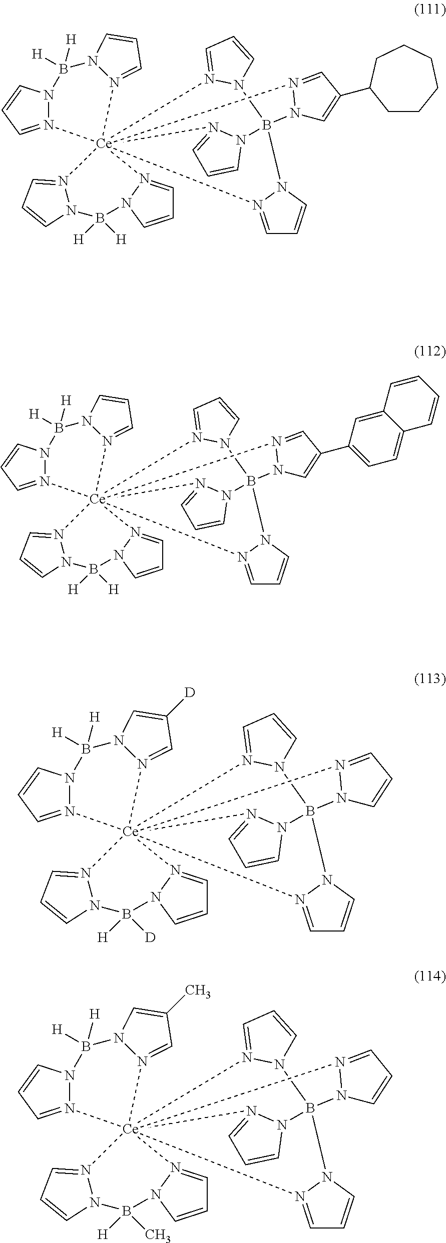

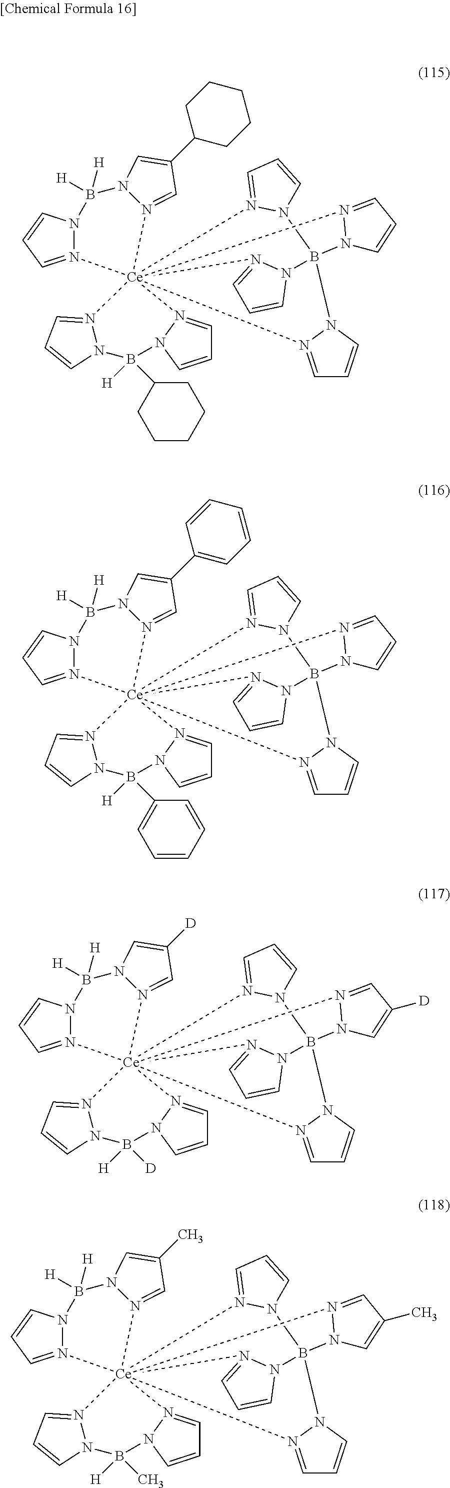

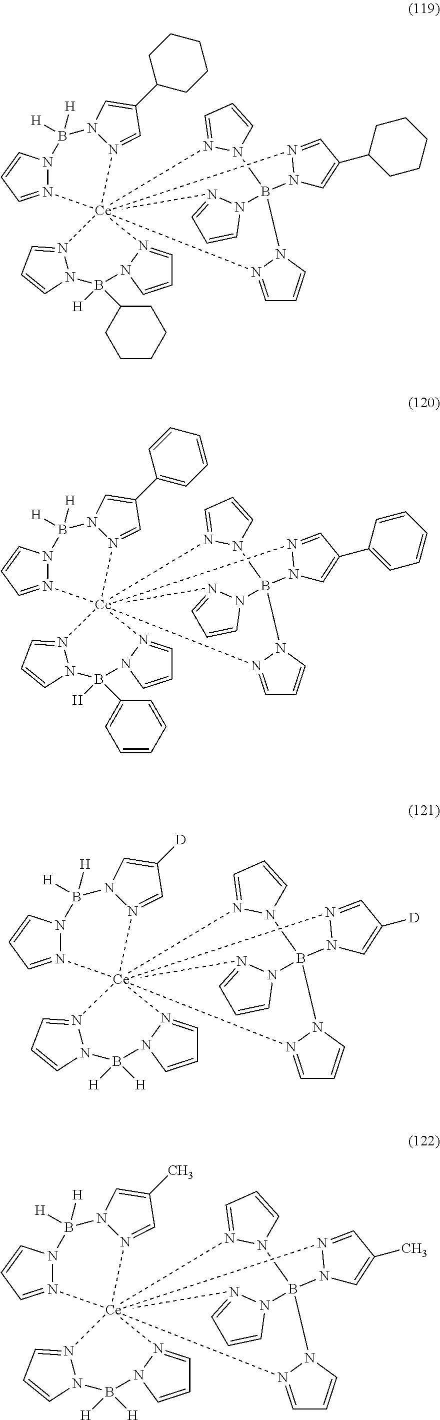

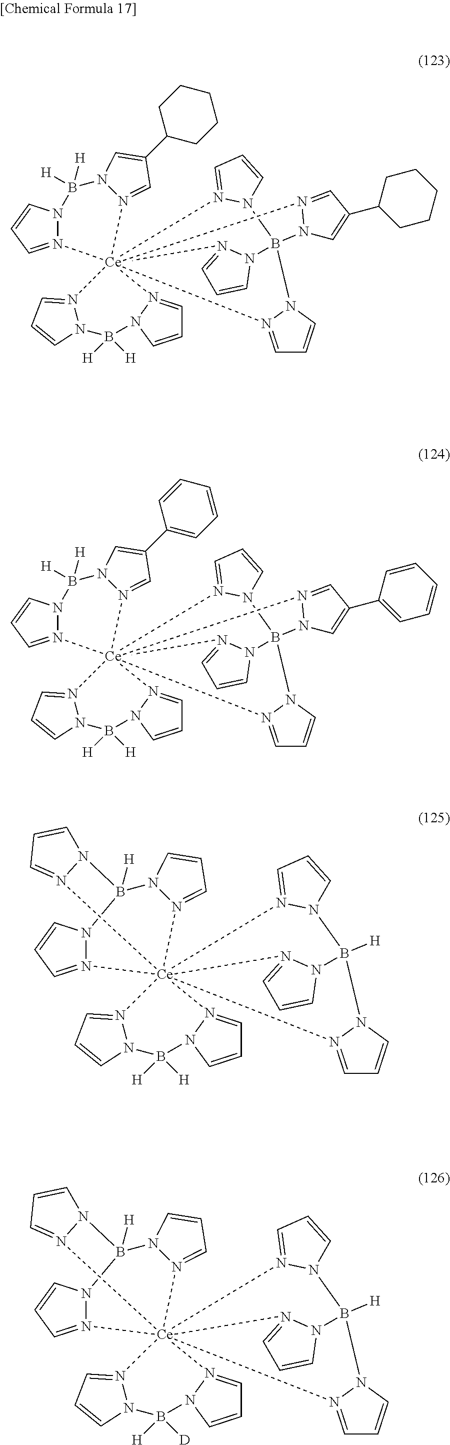

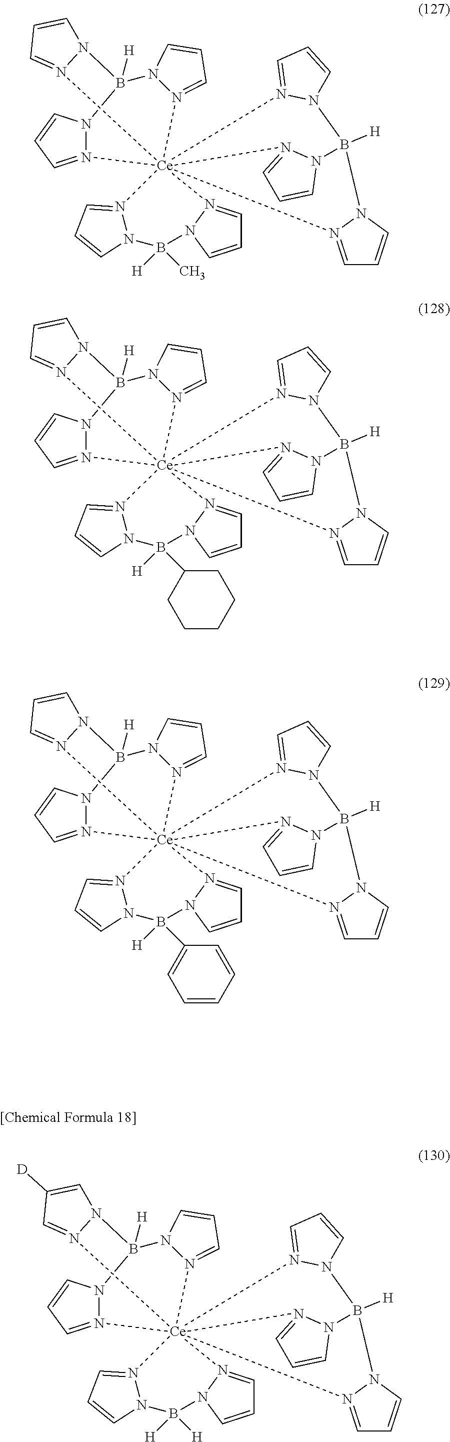

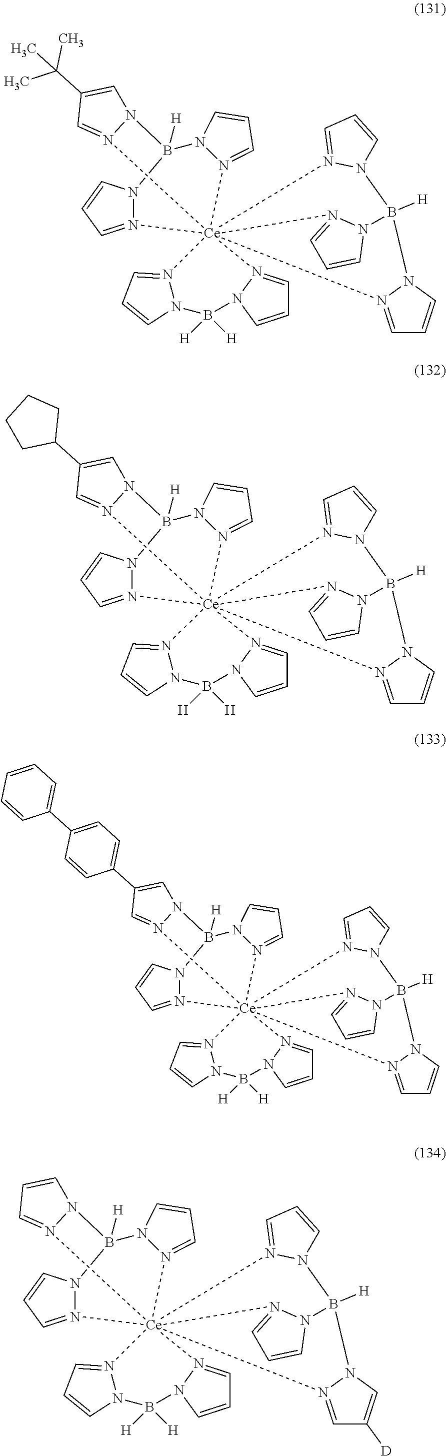

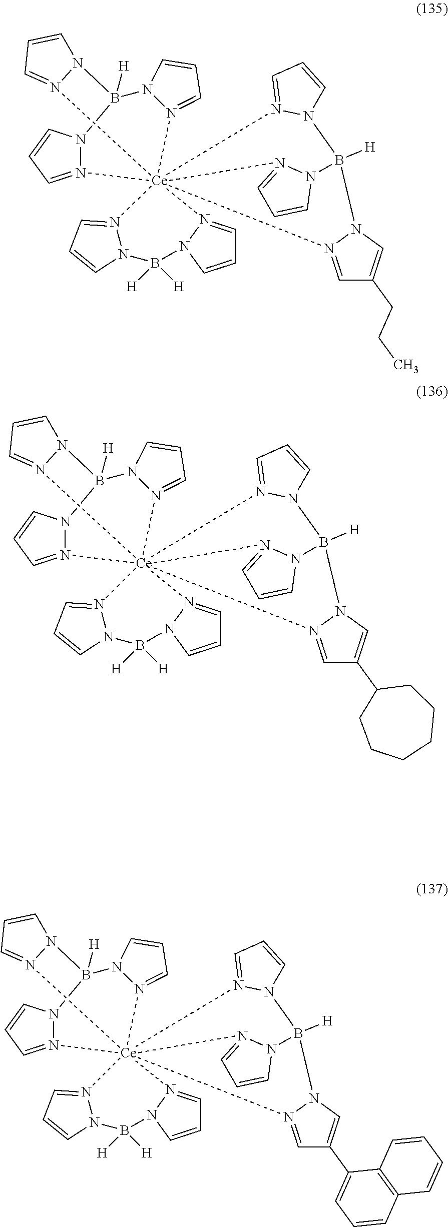

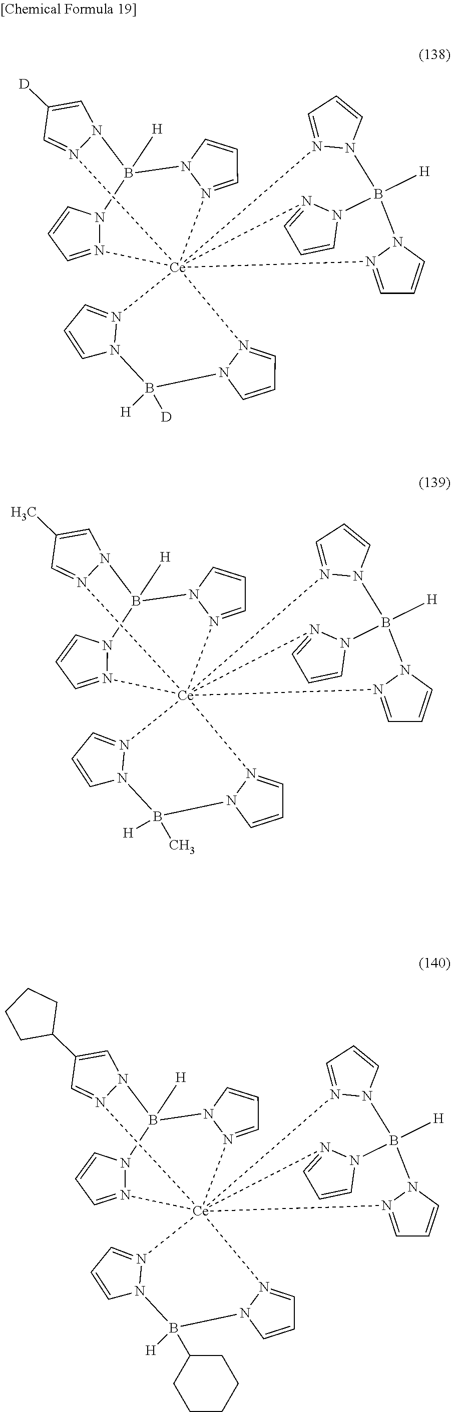

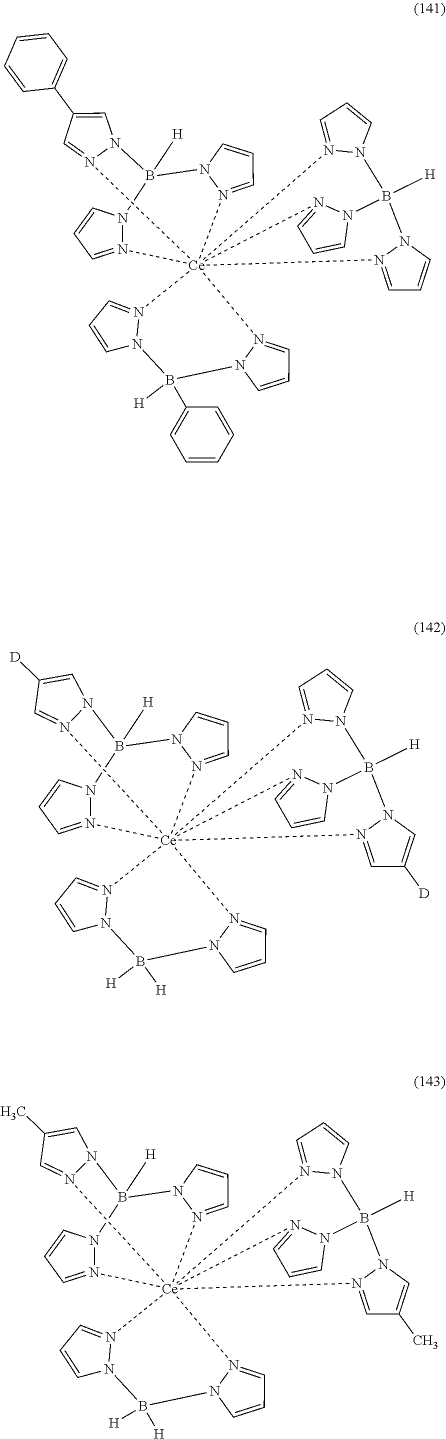

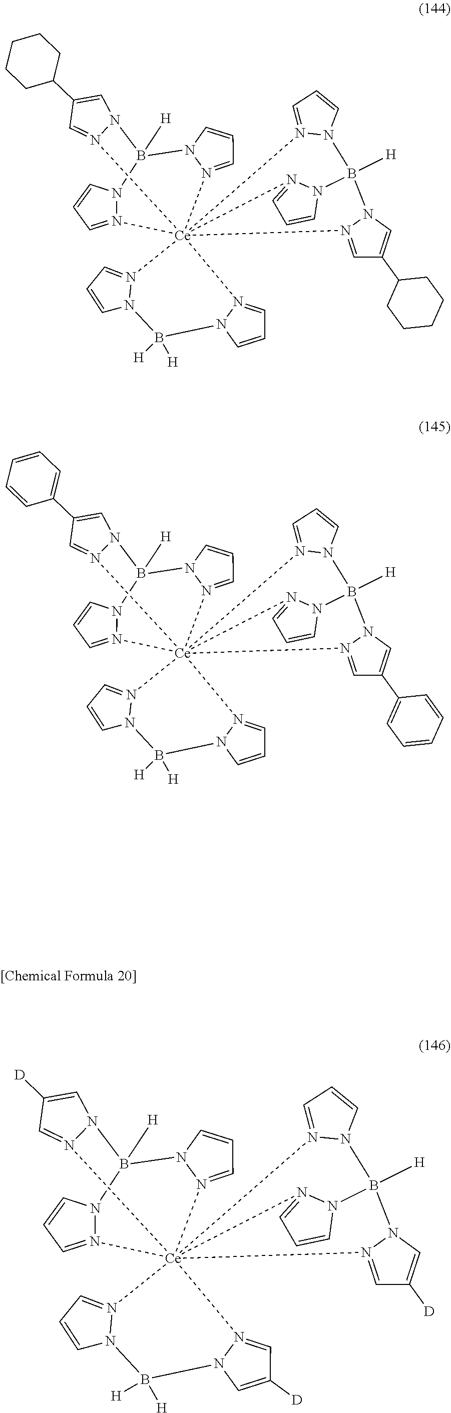

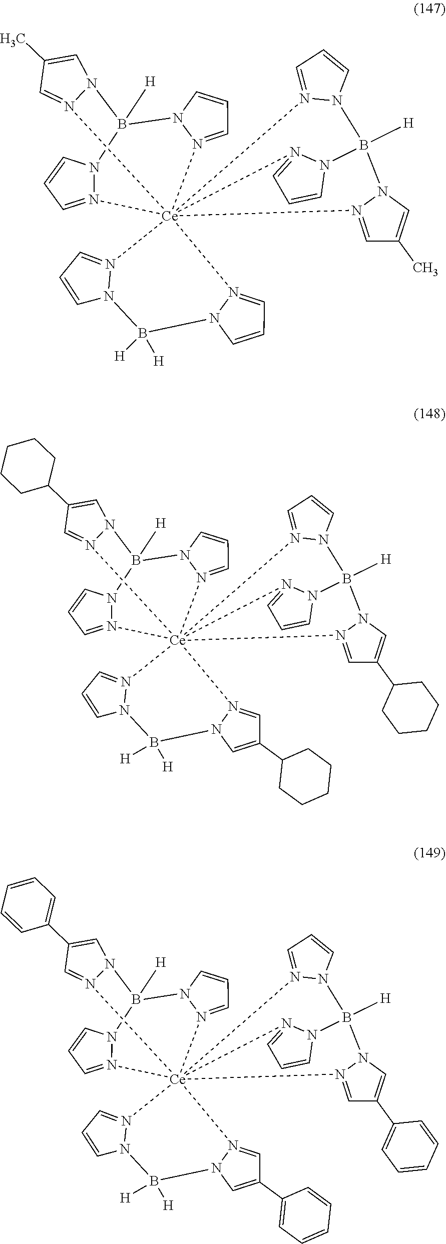

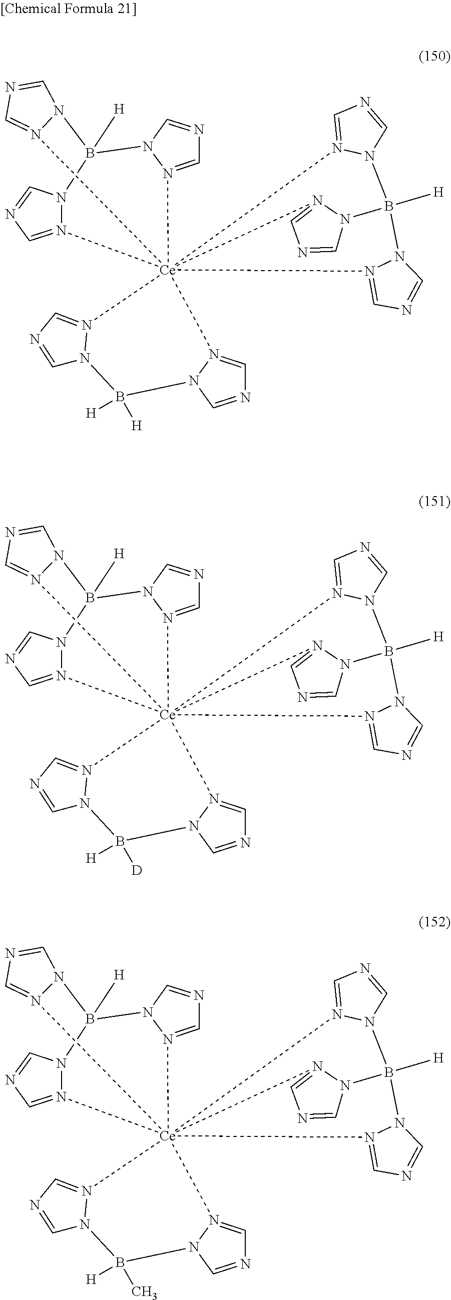

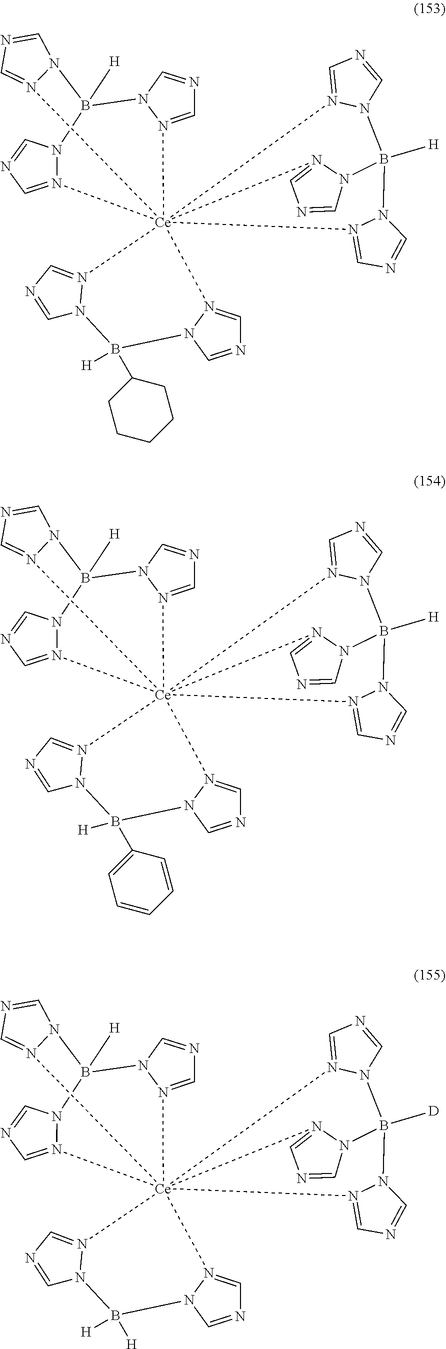

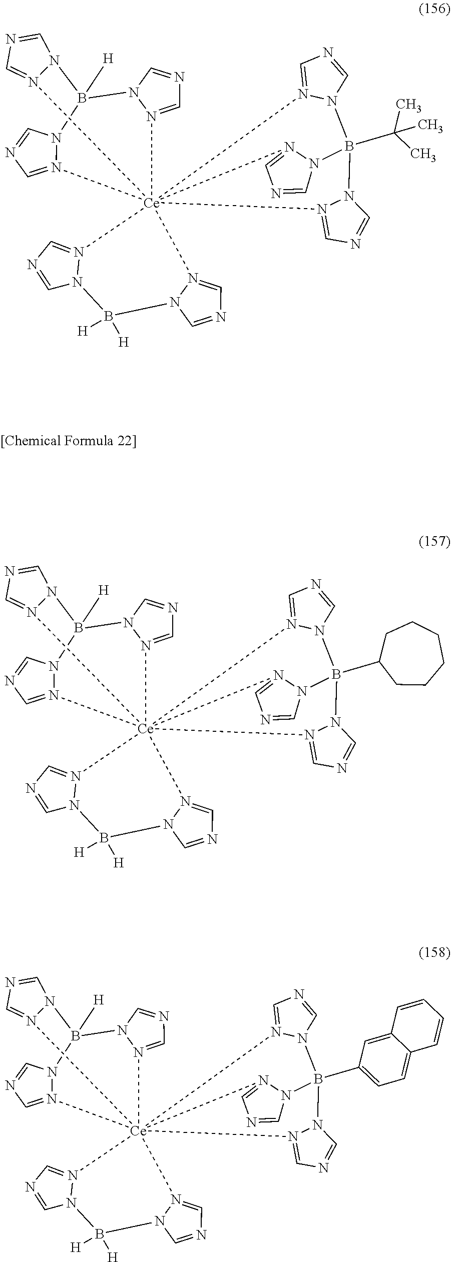

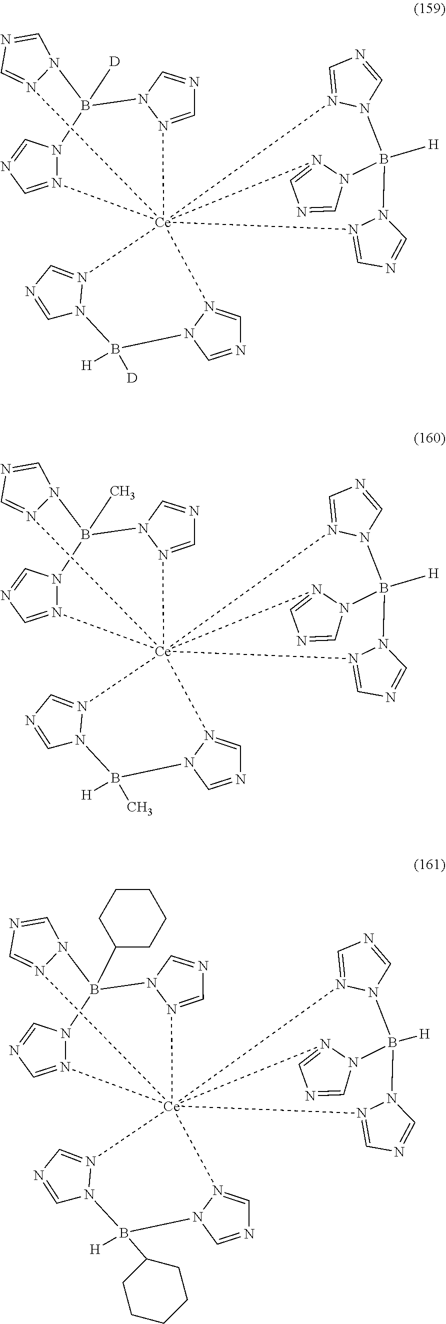

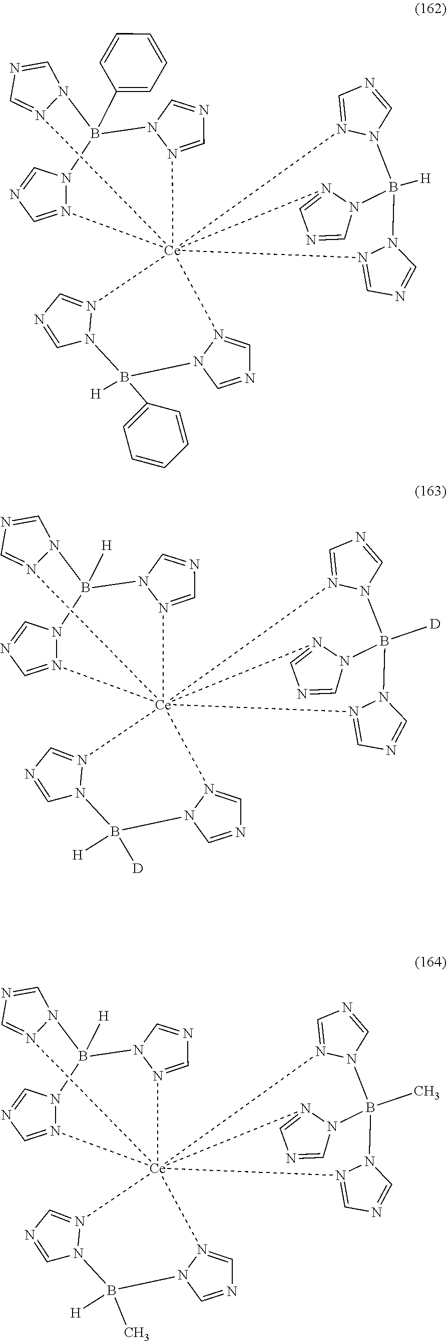

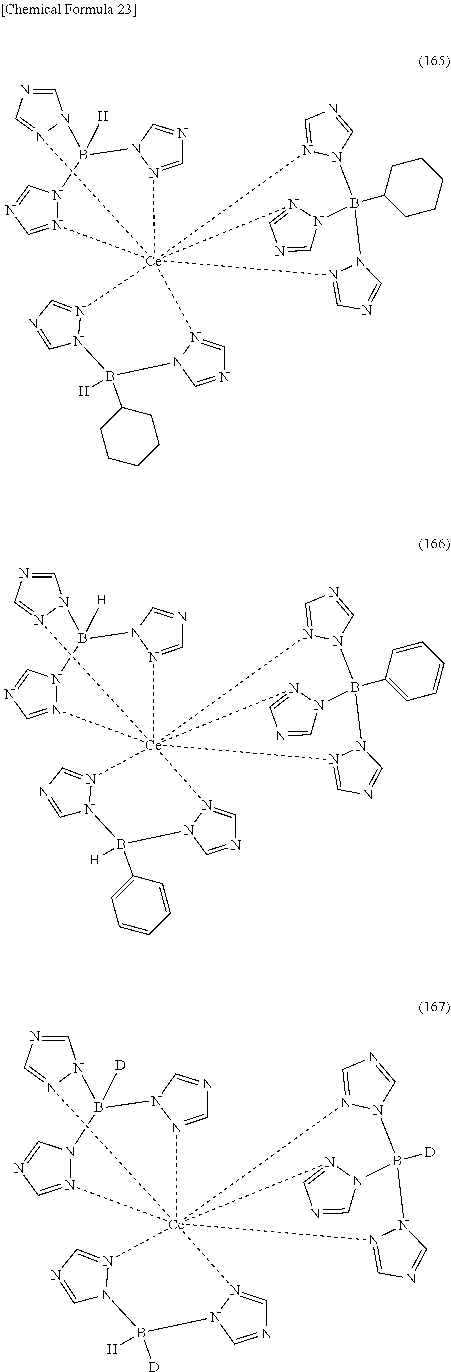

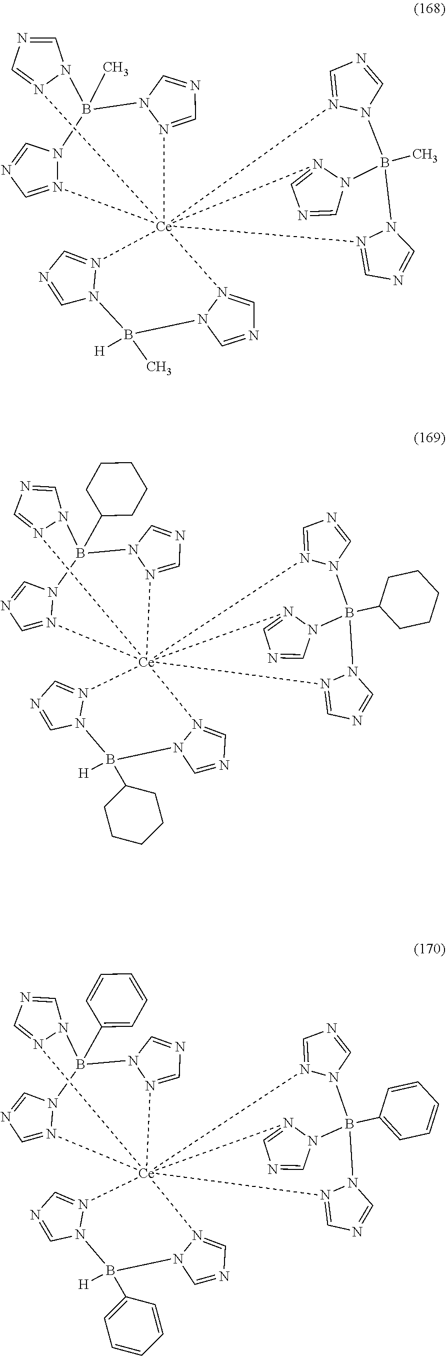

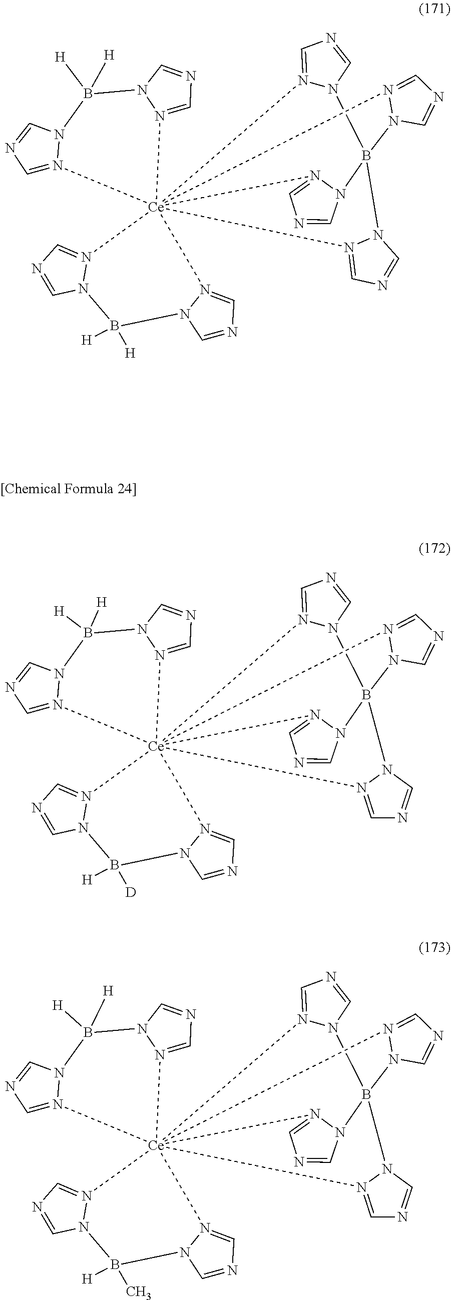

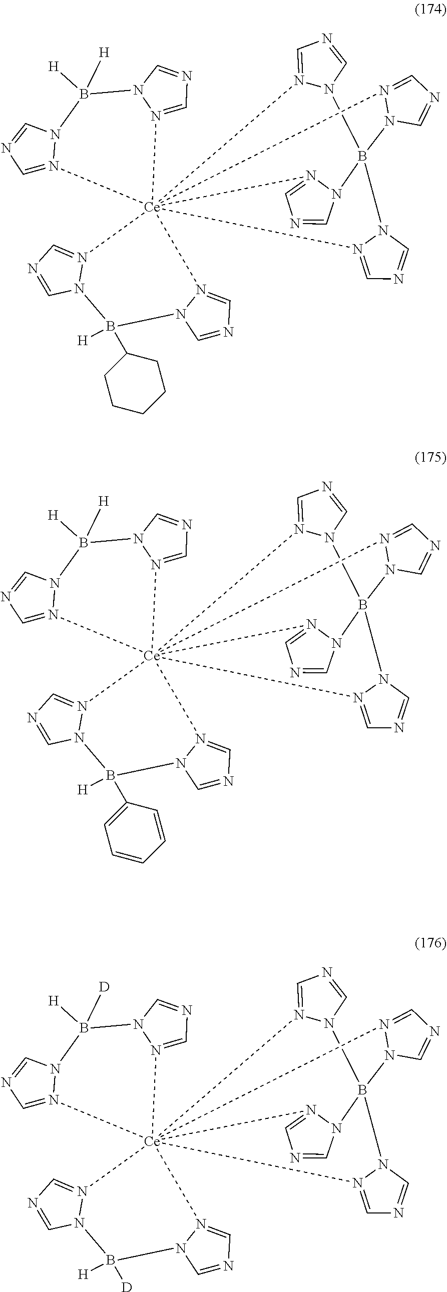

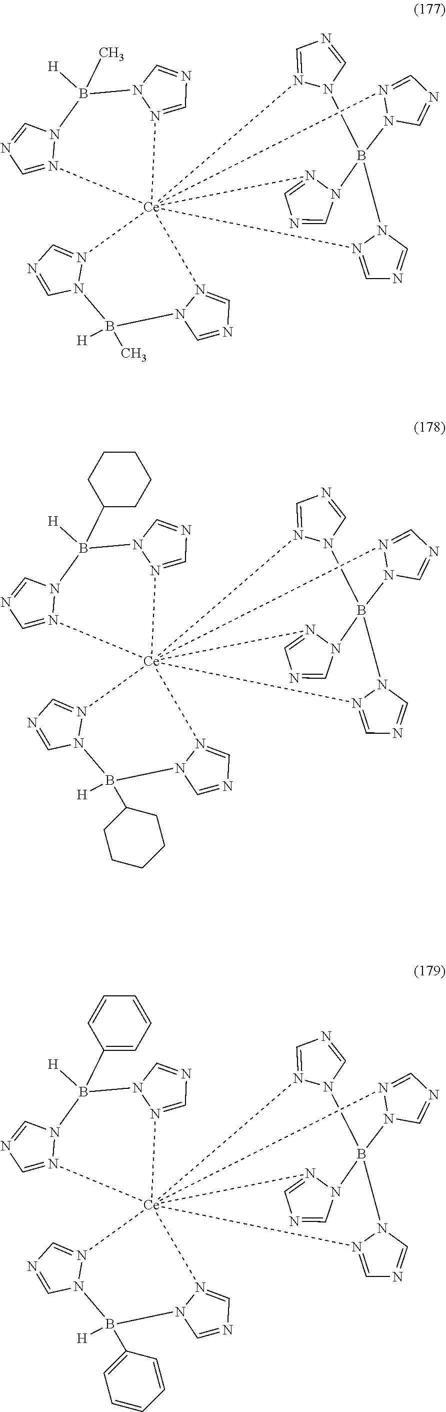

The organometallic complexes represented by Structural Formulae (100) to (179) above are specific examples of the structures represented by General Formulae (G1) to (G5), but the organometallic complex of one embodiment of the present invention is not limited thereto.

Next, a method for synthesizing the organometallic complex of one embodiment of the present invention represented by General Formula (G1) below will be described.

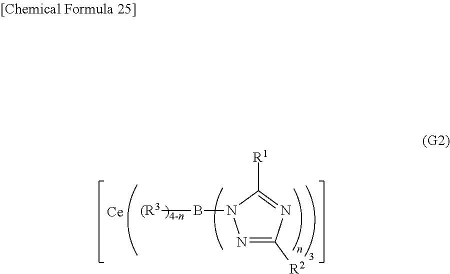

In General Formula (G1), X represents carbon or nitrogen, and the carbon is bonded to any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, R¹ to R³ each independently represent any one of hydrogen (including deuterium), a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms. Furthermore, n represents an integer greater than or equal to 1 and less than or equal to 4. The borate ligands may be the same or different from each other. Furthermore, n of one borate ligand may be the same as or different from n of another borate ligand. In the case where n is 2 or more, X of one borate ligand may be the same as or different from X of another borate ligand, R¹ of one borate ligand may be the same as or different from R¹ of another borate ligand, and R² of one borate ligand may be the same as or different from R² of another borate ligand. In the case where n is 2 or less, R³ of one borate ligand may be the same as or different from R³ of another borate ligand.

Method for synthesizing organometallic complex of one embodiment of present invention As shown in Synthesis Scheme (A-1) below, the organometallic complex of one embodiment of the present invention represented by General Formula (G1) above is obtained by using a boron compound having a heteroaromatic ring represented by General Formula (g1), a cerium compound (a trivalent cerium salt such as cerium(III) chloride, cerium(III) nitrate, or cerium(III) trifluoromethanesulfonate), and one or more kinds of organic solvents such as an alcohol-based solvent, tetrahydrofuran, and chloroform and stirring them in an inert gas atmosphere.

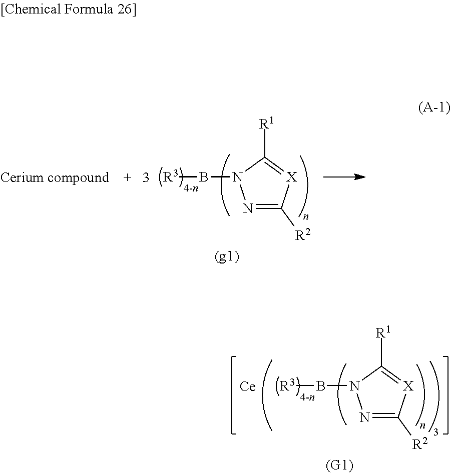

The structure described in this embodiment can be used in an appropriate combination with any of the structures described in the other embodiments.

### Embodiment 2

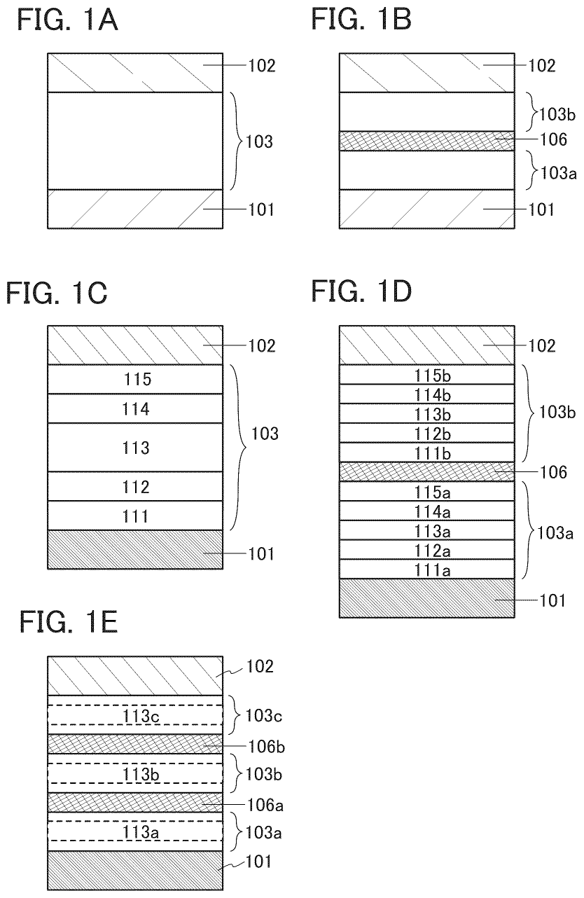

In this embodiment, a structure of a light-emitting device in which a material that emits light from a doublet excited state is used in a light-emitting layer as a light-emitting substance is described with reference to FIG. 1A to FIG. 1E. Although there is no particular limitation on the light-emitting substance as long as it emits light from a doublet excited state, the organometallic complex described in Embodiment 1 is preferably used.

Basic structure of light-emitting device A basic structure of a light-emitting device is described. FIG. TA illustrates a light-emitting device in which an EL layer including a light-emitting layer is provided between a pair of electrodes. Specifically, the light-emitting device has a structure in which an EL layer 103 is sandwiched between a first electrode 101 and a second electrode 102.

FIG. 1B illustrates a light-emitting device with a stacked-layer structure (a tandem structure) in which a plurality of EL layers (103a and 103b, two layers in FIG. 1B) are provided between a pair of electrodes and a charge-generation layer 106 is provided between the EL layers. With a light-emitting device having a tandem structure, a light-emitting apparatus with high efficiency can be achieved without changing the current amount.

The charge-generation layer 106 has a function of injecting electrons to one of the EL layers (103a or 103b) and injecting holes to the other of the EL layers (103b or 103a) when a potential difference is generated between the first electrode 101 and the second electrode 102. Thus, when voltage is applied such that the potential of the first electrode 101 is higher than that of the second electrode 102 in FIG. 1B, electrons are injected to the EL layer 103a and holes are injected to the EL layer 103b from the charge-generation layer 106.

Note that in terms of light extraction efficiency, it is preferable that the charge-generation layer 106 have a light-transmitting property with respect to visible light (specifically, the visible light transmittance with respect to the charge-generation layer 106 is preferably 40% or higher). Furthermore, the charge-generation layer 106 functions even when having lower conductivity than the first electrode 101 or the second electrode 102.

FIG. 1C illustrates a stacked-layer structure of the EL layer 103 in the light-emitting device of one embodiment of the present invention. Note that in this case, the first electrode 101 functions as an anode and the second electrode 102 functions as a cathode. The EL layer 103 has a structure in which a hole-injection layer 111, a hole-transport layer 112, a light-emitting layer 113, an electron-transport layer 114, and an electron-injection layer 115 are stacked sequentially over the first electrode 101. Note that the light-emitting layer 113 may have a stacked-layer structure of a plurality of light-emitting layers that emit light of different colors. For example, a light-emitting layer containing a light-emitting substance that emits red light, a light-emitting layer containing a light-emitting substance that emits green light, and a light-emitting layer containing a light-emitting substance that emits blue light may be stacked with or without a layer containing a carrier-transport material therebetween. Alternatively, alight-emitting layer containing alight-emitting substance that emits yellow light and a light-emitting layer containing a light-emitting substance that emits blue light may be used in combination. Note that the stacked-layer structure of the light-emitting layer 113 is not limited to the above. For example, the light-emitting layer 113 may have a stacked-layer structure of a plurality of light-emitting layers that emit light of the same color. For example, a first light-emitting layer containing a light-emitting substance that emits blue light and a second light-emitting layer containing a light-emitting substance that emits blue light may be stacked with or without a layer containing a carrier-transport material therebetween. The structure in which a plurality of light-emitting layers that emit light of the same color are stacked can achieve higher reliability than a single-layer structure in some cases. Even in the case where a plurality of EL layers are provided as in the tandem structure illustrated in FIG. 1B, the EL layers are sequentially stacked from the anode side as described above. When the first electrode 101 is a cathode and the second electrode 102 is an anode, the stacking order in the EL layer 103 is reversed. Specifically, the layer 111 over the first electrode 101 serving as the cathode denotes an electron-injection layer; the layer 112 denotes an electron-transport layer; the layer 113 denotes a light-emitting layer; the layer 114 denotes a hole-transport layer; and the layer 115 denotes a hole-injection layer.

The light-emitting layer 113 included in the EL layers (103, 103a, and 103b) contains a plurality of substances such as a material that emits light from a doublet excited state in an appropriate combination. Furthermore, a structure in which different emission colors can be obtained from the plurality of EL layers (103a and 103b) illustrated in FIG. 1B may be employed. Also in that case, light-emitting substances and other substances may be different between the stacked light-emitting layers.

In addition, the light-emitting device of one embodiment of the present invention can have an optical micro resonator (microcavity) structure with the first electrode 101 being a reflective electrode and the second electrode 102 being a transflective electrode in FIG. 1C, for example, and light emission obtained from the light-emitting layer 113 in the EL layer 103 can be resonated between the electrodes and light emitted through the second electrode 102 can be intensified.

Note that when the first electrode 101 of the light-emitting device is a reflective electrode having a stacked-layer structure of a reflective conductive material and a light-transmitting conductive material (a transparent conductive film), optical adjustment can be performed by adjusting the thickness of the transparent conductive film. Specifically, when the wavelength of light obtained from the light-emitting layer 113 is λ, the optical path length (the product of the film thickness and the refractive index) between the first electrode 101 and the second electrode 102 is preferably adjusted to mλ/2 (m is an integer of 1 or larger) or the vicinity thereof.

To amplify desired light (wavelength: λ) obtained from the light-emitting layer 113, the optical path length from the first electrode 101 to a region where the desired light is obtained in the light-emitting layer 113 (a light-emitting region) and the optical path length from the second electrode 102 to the region where the desired light is obtained in the light-emitting layer 113 (the light-emitting region) are preferably adjusted to (2m′+1)λ/4 (m′ is an integer of 1 or larger) or the vicinity thereof. Here, the light-emitting region refers to a region where holes and electrons are recombined in the light-emitting layer 113.

By performing such optical adjustment, the spectrum of specific monochromatic light obtained from the light-emitting layer 113 can be narrowed and light emission with high color purity can be obtained.

Note that in the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained with given positions in the first electrode 101 and the second electrode 102 being supposed to be reflective regions. Furthermore, the optical path length between the first electrode 101 and the light-emitting layer from which the desired light is obtained is, to be exact, the optical path length between the reflective region in the first electrode 101 and the light-emitting region in the light-emitting layer from which the desired light is obtained. However, it is difficult to precisely determine the reflective region in the first electrode 101 and the light-emitting region in the light-emitting layer from which the desired light is obtained; thus, it is assumed that the above effect can be sufficiently obtained with a given position in the first electrode 101 being supposed to be the reflective region and a given position in the light-emitting layer from which the desired light is obtained being supposed to be the light-emitting region.

The light-emitting device illustrated in FIG. 1D is a light-emitting device having a tandem structure. Owing to a microcavity structure of the light-emitting device, light (monochromatic light) with different wavelengths from the EL layers (103a and 103b) can be extracted. Thus, side-by-side patterning for obtaining different emission colors (e.g., RGB) is not necessary. Therefore, higher resolution can be easily achieved. In addition, a combination with coloring layers (color filters) is also possible. Furthermore, the emission intensity of light with a specific wavelength in the front direction can be increased, whereby power consumption can be reduced.

A light-emitting device illustrated in FIG. 1E is an example of the light-emitting device with the tandem structure illustrated in FIG. 1B, and includes three EL layers (103a, 103b, and 103c) stacked with charge-generation layers (106a and 106b) therebetween, as illustrated in the drawing. Note that the three EL layers (103a, 103b, and 103c) include respective light-emitting layers (113a, 113b, and 113c) and the emission colors of the respective light-emitting layers can be combined freely. For example, the light-emitting layer 113a can emit blue light, the light-emitting layer 113b can emit red, green, or yellow light, and the light-emitting layer 113c can emit blue light; for another example, the light-emitting layer 113a can emit red light, the light-emitting layer 113b can emit blue, green, or yellow light, and the light-emitting layer 113c can emit red light.

In the above light-emitting device of one embodiment of the present invention, at least one of the first electrode 101 and the second electrode 102 is a light-transmitting electrode (a transparent electrode, a transflective electrode, or the like). In the case where the light-transmitting electrode is a transparent electrode, the visible light transmittance of the transparent electrode is 40% or higher. In the case where the light-transmitting electrode is a transflective electrode, the visible light reflectance of the transflective electrode is higher than or equal to 20% and lower than or equal to 80%, preferably higher than or equal to 40% and lower than or equal to 70%. The resistivity of these electrodes is preferably 1×10⁻² Ωcm or lower.

In the case where one of the first electrode 101 and the second electrode 102 is an electrode having a reflecting property (a reflective electrode) in the above light-emitting device of one embodiment of the present invention, the visible light reflectance of the electrode having a reflecting property is higher than or equal to 40% and lower than or equal to 100%, preferably higher than or equal to 70% and lower than or equal to 100%. The resistivity of this electrode is preferably 1×10⁻² Ωcm or lower.

### <<Specific Structure of Light-Emitting Device>>

Next, a specific structure of the light-emitting device of one embodiment of the present invention will be described. Here, description is made using FIG. 1D illustrating the tandem structure. Note that the structure of the EL layer applies also to the light-emitting devices having a single structure in FIG. TA and FIG. 1C. In the case where the light-emitting device illustrated in FIG. 1D has a microcavity structure, the first electrode 101 is formed as a reflective electrode and the second electrode 102 is formed as a transflective electrode. Thus, a single-layer structure or a stacked-layer structure can be formed using one or more kinds of desired electrode materials. Note that the second electrode 102 is formed after formation of the EL layer 103b, with the use of a material selected as appropriate.

### <First Electrode and Second Electrode>

As materials for forming the first electrode 101 and the second electrode 102, any of the following materials can be used in an appropriate combination as long as the functions of the both electrodes described above can be fulfilled. For example, a metal, an alloy, an electrically conductive compound, and a mixture of these can be used as appropriate. Specifically, an In—Sn oxide (also referred to as ITO), an In—Si—Sn oxide (also referred to as ITSO), an In—Zn oxide, and an In—W—Zn oxide are given. In addition, it is also possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 in the periodic table, which is not listed above as an example (for example, lithium (Li), cesium (Cs), calcium (Ca), or strontium (Sr)), a rare earth metal such as europium (Eu) or ytterbium (Yb), an alloy containing an appropriate combination of any of these elements, graphene, or the like.

In the light-emitting device illustrated in FIG. 1D, when the first electrode 101 is an anode, a hole-injection layer 111a and a hole-transport layer 112a of the EL layer 103a are sequentially stacked over the first electrode 101 by a vacuum evaporation method. After the EL layer 103a and the charge-generation layer 106 are formed, a hole-injection layer 111b and a hole-transport layer 112b of the EL layer 103b are sequentially stacked over the charge-generation layer 106 in a similar manner.

### <Hole-Injection Layer>

The hole-injection layers (111, 111a, and 111b) are each a layer that injects holes from the first electrode 101 which is an anode or from the charge-generation layers (106, 106a, and 106b) to the EL layers (103, 103a, and 103b) and contains an organic acceptor material and a material with a high hole-injection property.

The organic acceptor material is a material that allows holes to be generated in another organic compound whose HOMO (Highest Occupied Molecular Orbital) level value is close to the LUMO (Lowest Unoccupied Molecular Orbital) level value of the organic acceptor material when charge separation is caused between the organic acceptor material and the organic compound. Thus, as the organic acceptor material, a compound having an electron-withdrawing group (a halogen group or a cyano group), such as a quinodimethane derivative, a chloranil derivative, or a hexaazatriphenylene derivative, can be used. For example, it is possible to use 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile. Note that among organic acceptor materials, a compound in which electron-withdrawing groups are bonded to condensed aromatic rings each having a plurality of heteroatoms, such as HAT-CN, is particularly preferred because it has a high acceptor property and stable film quality against heat. Alternatively, a [3] radialene derivative having an electron-withdrawing group (in particular, a cyano group or a halogen group such as a fluoro group) has a very high electron-accepting property and thus is preferable. Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like can be used.

As the material having a high hole-injection property, an oxide of a metal belonging to Group 4 to Group 8 in the periodic table (e.g., a transition metal oxide such as a molybdenum oxide, a vanadium oxide, a ruthenium oxide, a tungsten oxide, or a manganese oxide) can be used. As specific examples, a molybdenum oxide, a vanadium oxide, a niobium oxide, a tantalum oxide, a chromium oxide, a tungsten oxide, a manganese oxide, and a rhenium oxide are given. In particular, a molybdenum oxide is preferable because it is stable in the air, has a low hygroscopic property, and is easily handled. It is also possible to use phthalocyanine (abbreviation: H₂Pc), a phthalocyanine-based compound such as copper phthalocyanine (abbreviation: CuPc), or the like.

In addition to the above materials, it is also possible to use an aromatic amine compound, which is a low molecular compound, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), N,N-bis[4-bis(3-methylphenyl)aminophenyl]-N,N-diphenyl-4,4′-diaminobiphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), or 3-[N-(1-naphthyl)-N-(9-phenylcarbazol-3-yl)amino]-9-phenylcarbazole (abbreviation: PCzPCN1).

It is also possible to use a high molecular compound (an oligomer, a dendrimer, a polymer, or the like) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), or poly[N,N-bis(4-butylphenyl)-N,N-bis(phenyl)benzidine](abbreviation: Poly-TPD). It is also possible to use a high molecular compound to which acid such as poly(3,4-ethylenedioxythiophene)/polystyrenesulfonic acid (abbreviation: PEDOT/PSS) or polyaniline/polystyrenesulfonic acid (abbreviation: PAni/PSS) is added.

As the material with a high hole-injection property, a mixed material containing a hole-transport material and the above-described organic acceptor material (an electron-accepting material) can be used. In that case, the organic acceptor material extracts electrons from the hole-transport material, so that holes are generated in the hole-injection layer 111 and the holes are injected into the light-emitting layer 113 through the hole-transport layer 112. Note that the hole-injection layer 111 may be formed as a single layer of a mixed material containing the hole-transport material and the organic acceptor material (an electron-accepting material), or may be formed by stacking a layer containing the hole-transport material and a layer containing the organic acceptor material (the electron-accepting material).

The hole-transport material is preferably a substance having a hole mobility higher than or equal to 1×10⁻⁶ cm²/Vs in the case where the square root of the electric field strength [V/cm] is 600. Note that other substances can be used as long as they have a property of transporting more holes than electrons.

As the hole-transport material, a material having a high hole-transport property such as a compound having a π-electron rich heteroaromatic ring (e.g., a carbazole derivative, a furan derivative, or a thiophene derivative) or an aromatic amine (an organic compound having an aromatic amine skeleton), is preferable.

Examples of the above carbazole derivative (an organic compound having a carbazole ring) include a bicarbazole derivative (e.g., a 3,3′-bicarbazole derivative) and an aromatic amine having a carbazolyl group.

Specific examples of the above bicarbazole derivative (e.g., a 3,3′-bicarbazole derivative) include 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(1,1′-biphenyl-3-yl)-3,3′-bi-9H-carbazole (abbreviation: BismBPCz), 9-(1,1′-biphenyl-3-yl)-9′-(1,1′-biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: PNCCP).

Specific examples of the above aromatic amine having a carbazolyl group include 4-phenyl-4′-(9-phenyl-9H-carbazol-3-yl)triphenylamine (abbreviation: PCBA1BP), N-(4-biphenyl)-N-(9,9-dimethyl-9H-fluoren-2-yl)-9-phenyl-9H-carbazol-3-amine (abbreviation: PCBiF), N-(biphenyl-4-yl)-N-[4-(9-phenyl-9H-carbazol-3-yl)phenyl]-9,9-dimethyl-9H-fluoren-2-amine (abbreviation: PCBBiF), N-[4-(9-phenyl-9H-carbazol-3-yl)phenyl]-bis(9,9-dimethyl-9H-fluoren-2-yl)amine (abbreviation: PCBFF), N-(1,1′-biphenyl-4-yl)-N-[4-(9-phenyl-9H-carbazol-3-yl)phenyl]-9,9-dimethyl-9H-fluoren-4-amine, N-[4-(9-phenyl-9H-carbazol-3-yl)phenyl]-(9,9-dimethyl-9H-fluoren-2-yl)-9,9-dimethyl-9H-fluoren-4-amine, N-(1,1′-biphenyl-4-yl)-N-[4-(9-phenyl-9H-carbazol-3-yl)phenyl]-9,9-diphenyl-9H-fluoren-2-amine, N-(1,1′-biphenyl-4-yl)-N-[4-(9-phenyl-9H-carbazol-3-yl)phenyl]-9,9-diphenyl-9H-fluoren-4-amine, N-(1,1′-biphenyl-4-yl)-N-[4-(9-phenyl-9H-carbazol-3-yl)phenyl]-9,9′-spirobi(9H-fluoren)-2-amine, N-(1,1′-biphenyl-4-yl)-N-[4-(9-phenyl-9H-carbazol-3-yl)phenyl]-9,9′-spirobi(9H-fluoren)-4-amine, N-[4-(9-phenyl-9H-carbazol-3-yl)phenyl]-N-(1,1′: 3′,1″-terphenyl-4-yl)-9,9-dimethyl-9H-fluoren-2-amine, N-[4-(9-phenyl-9H-carbazol-3-yl)phenyl]-N-(1,1′: 4′,1″-terphenyl-4-yl)-9,9-dimethyl-9H-fluoren-2-amine, N-[4-(9-phenyl-9H-carbazol-3-yl)phenyl]-N-(1,1′: 3′,1″-terphenyl-4-yl)-9,9-dimethyl-9H-fluoren-4-amine, N-[4-(9-phenyl-9H-carbazol-3-yl)phenyl]-N-(1,1′: 4′,1″-terphenyl-4-yl)-9,9-dimethyl-9H-fluoren-4-amine, 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N-bis(9-phenylcarbazol-3-yl)-N,N-diphenylbenzene-1,3-diamine (abbreviation: PCA2B), N,N,N′-triphenyl-N,N,N′-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 2-[N-(9-phenylcarbazol-3-yl)-N-phenylamino]spiro-9,9′-bifluorene (abbreviation: PCASF), N-[4-(9H-carbazol-9-yl)phenyl]-N-(4-phenyl)phenylaniline (abbreviation: YGA1BP), N,N-bis[4-(carbazol-9-yl)phenyl]-N,N-diphenyl-9,9-dimethylfluorene-2,7-diamine (abbreviation: YGA2F), and 4,4′,4″-tris(carbazol-9-yl)triphenylamine (abbreviation: TCTA).

In addition to the above, other examples of the carbazole derivative include 9-[4-(9-phenyl-9H-carbazol-3-yl)phenyl]phenanthrene (abbreviation: PCPPn), 3-[4-(1-naphthyl)-phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA).

Specific examples of the above furan derivative (an organic compound having a furan ring) include 4,4′,4″-(benzene-1,3,5-triyl)tri(dibenzofuran) (abbreviation: DBF3P-II), and 4-{3-[3-(9-phenyl-9H-fluoren-9-yl)phenyl]phenyl}dibenzofuran (abbreviation: mmDBFFLBi-II).

Specific examples of the above thiophene derivative (an organic compound having a thiophene ring) include 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV).

Specific examples of the above aromatic amine include 4,4′-bis[N-(1-naphthyl)-N-phenylamino]biphenyl (abbreviation: NPB or a-NPD), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 2,7-bis[N-(4-diphenylaminophenyl)-N-phenylamino]-spiro-9,9′-bifluorene (abbreviation: DPA2SF), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: m-MTDATA), N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), DNTPD, 1,3,5-tris[N-(4-diphenylaminophenyl)-N-phenylamino]benzene (abbreviation: DPA3B), N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)-triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-[4-(9-phenylfluoren-9-yl)phenyl]triphenylamine (abbreviation: BPAFLBi), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Alternatively, it is also possible to use, as the hole-transport material, a high molecular compound (e.g., an oligomer, a dendrimer, or a polymer) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), poly[N,N-bis(4-butylphenyl)-N,N-bis(phenyl)benzidine](abbreviation: Poly-TPD), or the like. Alternatively, it is also possible to use a high molecular compound to which acid such as poly(3,4-ethylenedioxythiophene)/polystyrenesulfonic acid (abbreviation: PEDOT/PSS), and polyaniline/polystyrenesulfonic acid (abbreviation: PAni/PSS) is added.

Note that the hole-transport material is not limited to the above, and one of or a combination of various known materials may be used as the hole-transport material.

Note that the hole-injection layers (111, 111a, and 111b) can be formed by any of various known deposition methods, and can be formed by a vacuum evaporation method, for example.

### <Hole-Transport Layer>

The hole-transport layers (112, 112a, and 112b) are each a layer that transports the holes, which are injected from the first electrode 101 by the hole-injection layers (111, 111a, and 111b), to the light-emitting layers (113, 113a, 113b, and 113c). Note that the hole-transport layers (112, 112a, and 112b) are each a layer containing a hole-transport material. Thus, for the hole-transport layers (112, 112a, and 112b), a hole-transport material that can be used for the hole-injection layers (111, 111a, and 111b) can be used.

Note that in the light-emitting device of one embodiment of the present invention, the organic compound used for the hole-transport layers (112, 112a, and 112b) can also be used for the light-emitting layers (113, 113a, 113b, and 113c). The use of the same organic compound for the hole-transport layers (112, 112a, and 112b) and the light-emitting layers (113, 113a, 113b, and 113c) is preferable, in which case holes can be efficiently transported from the hole-transport layers (112, 112a, and 112b) to the light-emitting layers (113, 113a, 113b, and 113c).

### <Light-Emitting Layer>

The light-emitting layers (113, 113a, 113b, and 113c) are each a layer containing a light-emitting substance. As the light-emitting substance, a material that emits light from a doublet excited state can be used. Although there is no particular limitation on the light-emitting substance as long as it emits light from a doublet excited state, the organometallic complex described in Embodiment 1 is preferably used. The light-emitting layers (113, 113a, 113b, and 113c) may each contain one or more kinds of organic compounds (a host material and the like) in addition to a light-emitting substance (a guest material).

Examples of the organic compound used as the host material include the hole-transport material that can be used for the hole-transport layers (112, 112a, and 112b) described above and an electron-transport material that can be used for the electron-transport layers (114, 114a, and 114b) described later, as long as the conditions of the host material used for the light-emitting layer are satisfied.

Here, the present inventors have found that when a material that emits light from a doublet excited state is used as a light-emitting substance in a light-emitting layer, a host material preferably contains an electron-transport heteroaromatic compound. This is because in consideration of the carrier-transport property of the doublet light-emitting material, the host material is preferably responsible for electron transport, and a heteroaromatic ring is stable as an electron-transport skeleton. As the electron-transport heteroaromatic compound used as the host material, a π-electron deficient heteroaromatic compound is preferably used. Although there is no particular limitation on the light-emitting substance in this case as long as it emits light from a doublet excited state, the organometallic complex described in Embodiment 1 is preferable.

Specific examples of the π-electron deficient heteroaromatic compound include compounds including a six-membered heteroaromatic ring having nitrogen, such as a phenanthroline derivative, a quinoline derivative, a benzoquinoline derivative, a quinoxaline derivative, a dibenzoquinoxaline derivative, a pyridine derivative, a bipyridine derivative, a diazine (pyrimidine, pyrazine, or pyridazine) derivative, and a triazine derivative. An aromatic ring such as a benzene ring may be further condensed to the heteroaromatic rings of these derivatives. Note that specific examples of the π-electron deficient heteroaromatic compound are not limited thereto, and a π-electron deficient heteroaromatic compound can be selected from the organic compounds such as the above-described hole-transport material and the later-described electron-transport material.

### <Electron-Transport Layer>

The electron-transport layers (114, 114a, and 114b) are layers transporting the electrons, which are injected from the second electrode 102 and the charge-generation layers (106, 106a, and 106b) by electron-injection layers (115, 115a, and 115b) described later, to the light-emitting layers (113, 113a, 113b, and 113c). Note that the heat resistance of the light-emitting device of one embodiment of the present invention can be improved by including the stacked electron-transport layers. It is preferable that the electron-transport materials used in the electron-transport layers (114, 114a, and 114b) be substances with an electron mobility higher than or equal to 1×10⁻⁶ cm²/Vs in the case where the square root of the electric field strength [V/cm] is 600. Note that other substances can also be used as long as they have an electron-transport property higher than a hole-transport property. Each of the electron-transport layers (114, 114a, and 114b) function even in the form of a single layer but may have a stacked-layer structure of two or more layers. Note that since the above-described mixed material has heat resistance, performing a photolithography step over the electron-transport layer including such a material can inhibit the influence of a thermal process on the device characteristics.

### <<Electron-Transport Material>>

As the electron-transport material that can be used for the electron-transport layers (114, 114a, and 114b), an organic compound with a high electron-transport property can be used; for example, a heteroaromatic compound can be used. The heteroaromatic compound refers to a cyclic compound containing at least two different kinds of elements in a ring. Examples of cyclic structures include a three-membered ring, a four-membered ring, a five-membered ring, a six-membered ring, and the like, among which a five-membered ring and a six-membered ring are particularly preferable; the elements contained in the heteroaromatic compound are preferably one or more of nitrogen, oxygen, sulfur, and the like, as well as carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and a it-electron deficient heteroaromatic compound including the nitrogen-containing heteroaromatic compound, is preferably used.

Note that the electron-transport material can be different from the materials used for the light-emitting layer. Not all excitons formed by recombination of carriers in the light-emitting layer can contribute to light emission and some excitons are diffused into a layer in contact with the light-emitting layer or a layer in the vicinity of the light-emitting layer. In order to avoid this phenomenon, the electron-transport material is preferably different from the materials used in the light-emitting layer. Thus, alight-emitting device with high emission efficiency can be obtained.

The heteroaromatic compound is an organic compound including at least one heteroaromatic ring.

Note that the heteroaromatic ring includes any one of a pyridine ring, a diazine ring, a triazine ring, a polyazole ring, an oxazole ring, a thiazole ring, and the like. A heteroaromatic ring having a diazine ring includes a heteroaromatic ring having a pyrimidine ring, a pyrazine ring, a pyridazine ring, or the like. A heteroaromatic ring having a polyazole ring includes a heteroaromatic ring having an imidazole ring, a triazole ring, or an oxadiazole ring.

The heteroaromatic ring includes a fused heteroaromatic ring having a fused ring structure. Examples of the fused heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of a heteroaromatic compound including carbon and one or more of nitrogen, oxygen, sulfur, and the like and having a five-membered ring structure include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benzimidazole ring.

Examples of a heteroaromatic compound including carbon and one or more of nitrogen, oxygen, sulfur, and the like and having a six-membered ring structure include a heteroaromatic compound having a heteroaromatic ring such as a pyridine ring, a diazine ring (a pyrimidine ring, a pyrazine ring, a pyridazine ring, or the like), a triazine ring, or a poly azole ring. Other examples include a heteroaromatic compound having a bipyridine structure and a heteroaromatic compound having a terpyridine structure, which are included in heteroaromatic compounds in which pyridine rings are connected.

Examples of the heteroaromatic compound having a fused ring structure including the above six-membered ring structure as a part include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure in which an aromatic ring is fused to the furan ring of a furodiazine ring), or a benzimidazole ring.

Specific examples of the above-described heteroaromatic compound having a five-membered ring structure (e.g., a polyazole ring (including an imidazole ring, a triazole ring, an oxadiazole ring), an oxazole ring, a thiazole ring, or a benzimidazole ring) include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOs).

Specific examples of the above-described heteroaromatic compound having a six-membered ring structure (including a heteroaromatic ring having a pyridine ring, a diazine ring, a triazine ring, or the like) include a heteroaromatic compound including a heteroaromatic ring having a pyridine ring, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB), a heteroaromatic compound including a heteroaromatic ring having a triazine ring, such as 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn), 2-{3-[3-(dibenzothiophen-4-yl)phenyl]phenyl}-4,6-diphenyl-1,3,5-triazine (abbreviation: mDBtBPTzn), or 2-[3′-(9,9-dimethyl-9H-fluoren-2-yl)biphenyl-3-yl]-4,6-diphenyl-1,3,5-triazine (abbreviation: mFBPTzn), and a heteroaromatic compound including a heteroaromatic ring having a diazine (pyrimidine) ring, such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 6-(biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(biphenyl-4-yl)pyrimidine (abbreviation: 6BP-4Cz2PPm), 4-[3-(dibenzothiophen-4-yl)phenyl]-8-(naphthalen-2-yl)-[1]benzofuro[3,2-d]pyrimidine (abbreviation: 8βN-4mDBtPBfpm), 8-(1,1′-biphenyl-4-yl)-4-[3-(dibenzothiophene-4-yl)phenyl]-[1]benzofuro[3,2-d]pyrimidine (abbreviation: 8BP-4mDBtPBfpm), 9-[3′-(dibenzothiophen-4-yl)biphenyl-3-yl]naphtho[1′,2′: 4,5]furo[2,3-b]pyrazine (abbreviation: 9mDBtBPNfpr), 9-[3′-(dibenzothiophen-4-yl)biphenyl-4-yl]naphtho[1′,2′: 4,5]furo[2,3-b]pyrazine (abbreviation: 9pmDBtBPNfpr), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl)]naphtho[1′,2′: 4,5]furo[3,2-d]pyrimidine (abbreviation: 8mDBtBPNfpm), or 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm). Note that the above aromatic compounds including a heteroaromatic ring include a heteroaromatic compound having a fused heteroaromatic ring.

Other examples include a heteroaromatic compound including a heteroaromatic ring having a diazine (pyrimidine) ring, such as 2,2′-(pyridine-2,6-diyl)bis(4-phenylbenzo[h]quinazoline) (abbreviation: 2,6(P-Bqn)2Py), 2,2′-(2,2′-bipyridine-6,6′-diyl)bis(4-phenylbenzo[h]quinazoline) (abbreviation: 6,6′(P-Bqn)2BPy), 2,2′-(pyridine-2,6-diyl)bis{4-[4-(2-naphthyl)phenyl]-6-phenylpyrimidine}(abbreviation: 2,6(NP—PPm)2Py), or 6-(biphenyl-3-yl)-4-[3,5-bis(9H-carbazol-9-yl)phenyl]-2-phenylpyrimidine (abbreviation: 6mBP-4Cz2PPm), and a heteroaromatic compound including a heteroaromatic ring having a triazine ring, such as 2,4,6-tris[3′-(pyridin-3-yl)biphenyl-3-yl]-1,3,5-triazine (abbreviation: TmPPPyTz), 2,4,6-tris(2-pyridyl)-1,3,5-triazine (abbreviation: 2Py3Tz), or 2-[3-(2,6-dimethyl-3-pyridyl)-5-(9-phenanthrenyl)phenyl]-4,6-diphenyl-1,3,5-triazine (abbreviation: mPn-mDMePyPTzn).

Specific examples of the above-described heteroaromatic compound having a fused ring structure including the six-membered ring structure as a part (a heteroaromatic compound having a fused ring structure) include a heteroaromatic compound having a quinoxaline ring, such as bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2,2′-(pyridine-2,6-diyl)bis(4-phenylbenzo[h]quinazoline) (abbreviation: 2,6(P-Bqn)2Py), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), or 2-[4′-(9-phenyl-9H-carbazole-3-yl)-3,1′-biphenyl-1-yl]dibenzo[f,h]quinoxaline (abbreviation: 2mpPCBPDBq).

For the electron-transport layers (114, 114a, and 114b), any of the metal complexes given below as well as the heteroaromatic compounds given above can be used. Examples of the metal complexes include a metal complex having a quinoline ring or a benzoquinoline ring, such as tris(8-quinolinolato)aluminum(III) (abbreviation: Alq₃), tris(4-methyl-8-quinolinolato)aluminum(III) (abbreviation: Almq₃), 8-quinolinolato-lithium (abbreviation: Liq), BeBq2, bis(2-methyl-8-quinolinolato)(4-phenylphenolato)aluminum(III) (abbreviation: BAlq), or bis(8-quinolinolato)zinc(II) (abbreviation: Znq), and a metal complex having an oxazole ring or a thiazole ring, such as bis[2-(2-benzoxazolyl)phenolato]zinc(II) (abbreviation: ZnPBO) or bis[2-(2-benzothiazolyl)phenolato]zinc(II) (abbreviation: ZnBTZ).

A high molecular compound such as poly(2,5-pyridinediyl) (abbreviation: PPy), poly[(9,9-dihexylfluorene-2,7-diyl)-co-(pyridine-3,5-diyl)](abbreviation: PF-Py), or poly[(9,9-dioctylfluorene-2,7-diyl)-co-(2,2′-bipyridine-6,6′-diyl)](abbreviation: PF-BPy) can also be used as an electron-transport material.

The electron-transport layer (114, 114a, or 114b) is not limited to a single layer, and may be a stack of two or more layers each made of any of the above substances.

### <Electron-Injection Layer>

The electron-injection layers (115, 115a, and 115b) are each a layer containing a substance having a high electron-injection property. The electron-injection layers (115, 115a, and 115b) are each a layer for increasing the efficiency of electron injection from the second electrode 102 and are each preferably formed using a material whose LUMO level value has a small difference (0.5 eV or less) from the work function value of the material used for the second electrode 102. Thus, the electron-injection layer 115 can be formed using an alkali metal, an alkaline earth metal, or a compound thereof, such as lithium, cesium, lithium fluoride (LiF), cesium fluoride (CsF), calcium fluoride (CaF₂), 8-quinolinolato-lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. A rare earth metal or a rare earth metal compound such as erbium fluoride (ErF₃) or ytterbium (Yb) can also be used. Note that to form the electron-injection layers (115, 115a, and 115b), a plurality of kinds of the above-described materials may be mixed or a plurality of kinds of the above-described materials may be stacked. Electrode may also be used for the electron-injection layers (115, 115a, and 115b). Examples of the electrode include a substance in which electrons are added at high concentration to a mixed oxide of calcium and aluminum. Note that any of the substances used in the electron-transport layers (114, 114a, and 114b), which are given above, can also be used.

A mixed material in which an organic compound and an electron donor (donor) are mixed may also be used in the electron-injection layers (115, 115a, and 115b). Such a mixed material is excellent in an electron-injection property and an electron-transport property because electrons are generated in the organic compound by the electron donor. In this case, the organic compound is preferably a material excellent in transporting the generated electrons; specifically, for example, the above-mentioned electron-transport materials (metal complexes, heteroaromatic compounds, and the like) used in the electron-transport layers (114, 114a, and 114b) can be used. Any substance showing an electron-donating property with respect to the organic compound can serve as an electron donor. Specifically, an alkali metal, an alkaline earth metal, and a rare earth metal are preferable, and lithium, cesium, magnesium, calcium, erbium, ytterbium, and the like are given. In addition, an alkali metal oxide and an alkaline earth metal oxide are preferable, and lithium oxide, calcium oxide, barium oxide, and the like are given. A Lewis base such as magnesium oxide can also be used. An organic compound such as tetrathiafulvalene (abbreviation: TTF) can also be used. Alternatively, a stack of these materials may be used.

Moreover, a mixed material in which an organic compound and a metal are mixed may also be used in the electron-injection layers (115, 115a, and 115b). The organic compound used here preferably has a LUMO level higher than or equal to −3.6 eV and lower than or equal to −2.3 eV. Moreover, a material having an unshared electron pair is preferable.

Thus, as the organic compound used in the above mixed material, a mixed material obtained by mixing a metal and the heteroaromatic compound given above as the material that can be used for the electron-transport layer may be used. Preferable examples of the heteroaromatic compound include materials having an unshared electron pair, such as a heteroaromatic compound having a five-membered ring structure (e.g., an imidazole ring, a triazole ring, an oxazole ring, an oxadiazole ring, a thiazole ring, or a benzimidazole ring), a heteroaromatic compound having a six-membered ring structure (e.g., a pyridine ring, a diazine ring (including a pyrimidine ring, a pyrazine ring, a pyridazine ring, and the like), a triazine ring, a bipyridine ring, or a terpyridine ring), and a heteroaromatic compound having a fused ring structure including a six-membered ring structure as a part (e.g., a quinoline ring, a benzoquinoline ring, a quinoxaline ring, a dibenzoquinoxaline ring, or a phenanthroline ring). Since the materials are specifically described above, description thereof is omitted here.

As the metal used for the above mixed material, a transition metal that belongs to Group 5, Group 7, Group 9, or Group 11 in the periodic table or a material that belongs to Group 13 is preferably used, and Ag, Cu, Al, In, and the like can be given as examples. In this case, the organic compound forms a singly occupied molecular orbital (SOMO) with the transition metal.

To amplify light obtained from the light-emitting layer 113b, for example, the optical path length between the second electrode 102 and the light-emitting layer 113b is preferably less than one fourth of the wavelength λ of light emitted from the light-emitting layer 113b. In that case, the optical path length can be adjusted by changing the thickness of the electron-transport layer 114b or the electron-injection layer 115b.

When the charge-generation layer 106 is provided between the two EL layers (103a and 103b) as in the light-emitting device in FIG. 1D, a structure in which a plurality of EL layers are stacked between a pair of electrodes (the structure is also referred to as a tandem structure) can be obtained.

### <Charge-Generation Layer>

The charge-generation layer 106 has a function of injecting electrons into the EL layer 103a and injecting holes into the EL layer 103b when a voltage is applied between the first electrode (anode) 101 and the second electrode (cathode) 102. The charge-generation layer 106 may have either a structure in which an electron acceptor (acceptor) is added to a hole-transport material (also referred to as a P-type layer) or a structure in which an electron donor (donor) is added to an electron-transport material (also referred to as an electron-injection buffer layer). Alternatively, both of these structures may be stacked. Furthermore, an electron-relay layer may be provided between the P-type layer and the electron-injection buffer layer. Note that forming the charge-generation layer 106 with the use of any of the above materials can inhibit an increase in driving voltage caused by the stack of the EL layers.

In the case where the charge-generation layer 106 has a structure in which an electron acceptor is added to a hole-transport material that is an organic compound (P-type layer), any of the materials described in this embodiment can be used as the hole-transport material. As examples of the electron acceptor, 7,7,8,8-tetracyano-2,3,5,6-tetrafluoroquinodimethane (abbreviation: F₄-TCNQ), chloranil, and the like can be given. Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of the P-type layer or a stack of single films containing the respective materials may be used.

In the case where the charge-generation layer 106 has a structure in which an electron donor is added to an electron-transport material (electron-injection buffer layer), any of the materials described in this embodiment can be used as the electron-transport material. As the electron donor, it is possible to use an alkali metal, an alkaline earth metal, a rare earth metal, a metal belonging to Group 2 or Group 13 of the periodic table, or an oxide or a carbonate thereof. Specifically, lithium (Li), cesium (Cs), magnesium (Mg), calcium (Ca), ytterbium (Yb), indium (In), lithium oxide (Li₂O), cesium carbonate, or the like is preferably used. An organic compound such as tetrathianaphthacene may be used as the electron donor.

When an electron-relay layer is provided between a P-type layer and an electron-injection buffer layer in the charge-generation layer 106, the electron-relay layer contains at least a substance having an electron-transport property and has a function of preventing an interaction between the electron-injection buffer layer and the P-type layer and transferring electrons smoothly. The LUMO level of the substance having an electron-transport property in the electron-relay layer is preferably between the LUMO level of the acceptor substance in the P-type layer and the LUMO level of the substance having an electron-transport property in the electron-transport layer in contact with the charge-generation layer 106. A specific energy level of the LUMO level of the substance having an electron-transport property in the electron-relay layer is preferably higher than or equal to −5.0 eV, further preferably higher than or equal to −5.0 eV and lower than or equal to −3.0 eV. Note that as the substance having an electron-transport property in the electron-relay layer, a phthalocyanine-based material or a metal complex having a metal-oxygen bond and an aromatic ligand is preferably used.

Although FIG. 1D illustrates the structure in which two EL layers 103 are stacked, three or more EL layers may be stacked with charge-generation layers each provided between different EL layers.

### <Cap Layer>

Although not illustrated in FIG. 1A to FIG. 1E, a cap layer may be provided over the second electrode 102 of the light-emitting device. For example, a material with a high refractive index can be used for the cap layer. When the cap layer is provided over the second electrode 102, extraction efficiency of light emitted from the second electrode 102 can be improved.

Specific examples of a material that can be used for the cap layer include 5,5′-diphenyl-2,2′-di-5H-[1]benzothieno[3,2-c]carbazole (abbreviation: BisBTc) and 4,4′,4″-(benzene-1,3,5-triyl)tri(dibenzothiophene) (abbreviation: DBT3P-II).

### <Substrate>

The light-emitting device described in this embodiment can be formed over a variety of substrates. Note that the type of substrate is not limited to a certain type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, and a base material film including a fibrous material.

Examples of the glass substrate include barium borosilicate glass, aluminoborosilicate glass, and soda lime glass. Examples of the flexible substrate, the attachment film, and the base material film include plastics typified by polyethylene terephthalate (PET), polyethylene naphthalate (PEN), and polyether sulfone (PES), a synthetic resin such as acrylic resin, polypropylene, polyester, polyvinyl fluoride, polyvinyl chloride, polyamide, polyimide, aramid, epoxy resin, an inorganic vapor deposition film, and paper.

For fabrication of the light-emitting device described in this embodiment, a vapor phase method such as an evaporation method or a liquid phase method such as a spin coating method and an ink-jet method can be used. In the case of using an evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, layers having a variety of functions (the hole-injection layer 111, the hole-transport layer 112, the light-emitting layer 113, the electron-transport layer 114, and the electron-injection layer 115) included in the EL layer of the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

In the case where a film formation method such as the coating method or the printing method is employed, a high molecular compound (e.g., an oligomer, a dendrimer, or a polymer), a middle molecular compound (a compound between a low molecular compound and a high molecular compound with a molecular weight of greater than or equal to 400 and less than or equal to 4000), an inorganic compound (e.g., a quantum dot material), or the like can be used. The quantum dot material can be a colloidal quantum dot material, an alloyed quantum dot material, a core-shell quantum dot material, a core quantum dot material, or the like.

Materials that can be used for the layers (the hole-injection layer 111, the hole-transport layer 112, the light-emitting layer 113, the electron-transport layer 114, and the electron-injection layer 115) included in the EL layer 103 of the light-emitting device described in this embodiment are not limited to the materials described in this embodiment, and other materials can be used in combination as long as the functions of the layers are fulfilled.

Note that in this specification and the like, the term “layer” and the term “film” can be interchanged with each other as appropriate.

The structures described in this embodiment can be used in an appropriate combination with any of the structures described in the other embodiments.

### Embodiment 3

In this embodiment, a light-emitting and light-receiving apparatus 700 will be described in order to describe specific structure examples and an example of a manufacturing method of a light-emitting and light-receiving apparatus of one embodiment of the present invention. The light-emitting and light-receiving apparatus 700 includes a light-emitting device and thus can be regarded as a light-emitting apparatus; includes a light-receiving device and thus can be regarded as a light-receiving apparatus; and can be used in a display portion in an electronic apparatus and thus can be regarded as a display panel or a display apparatus.

### <Structure Example of Light-Emitting and Light-Receiving Apparatus 700>

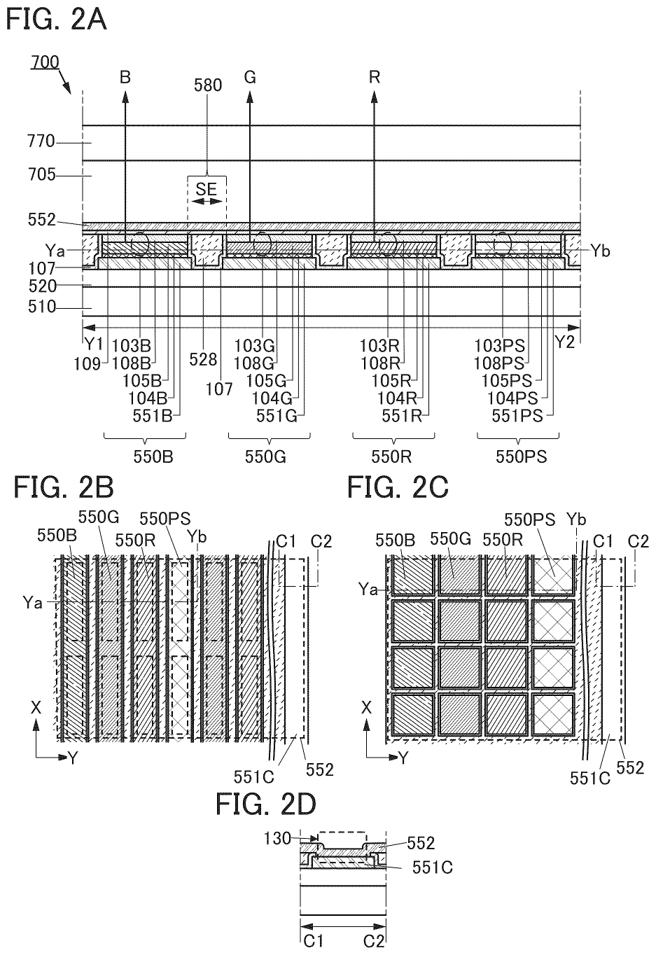

The light-emitting and light-receiving apparatus 700 illustrated in FIG. 2A includes a light-emitting device 550B, a light-emitting device 550G, a light-emitting device 550R, and a light-receiving device 550PS that are formed over a functional layer 520 over a first substrate 510. The functional layer 520 includes driver circuits such as a gate driver and a source driver that are composed of a plurality of transistors and wirings that electrically connect these circuits. Note that these driver circuits are electrically connected to the light-emitting device 550B, the light-emitting device 550G, the light-emitting device 550R, and the light-receiving device 550PS, for example, and can drive them. The light-emitting and light-receiving apparatus 700 includes an insulating layer 705 over the functional layer 520 and the devices (the light-emitting devices and the light-receiving device), and the insulating layer 705 has a function of bonding a second substrate 770 and the functional layer 520.

The light-emitting device 550B, the light-emitting device 550G, and the light-emitting device 550R include the device structure described in Embodiment 2, and the light-receiving device 550PS has a device structure described later in Embodiment 8. In addition, the structure of the EL layer 103 (see FIG. TA) differs between the light-emitting devices; for example, a light-emitting layer 105B of an EL layer 103B can emit blue light, a light-emitting layer 105G of an EL layer 103G can emit green light, and a light-emitting layer 105R of an EL layer 103G can emit red light.

Note that although in this embodiment, the case where the devices (a plurality of light-emitting devices and a light-receiving device) are formed separately is described, part of an EL layer of a light-emitting device (a hole-injection layer, a hole-transport layer, or an electron-transport layer) and part of an active layer of a light-receiving device (a hole-injection layer, a hole-transport layer, or an electron-transport layer) may be formed using the same material at the same time in the manufacturing process. The details will be described in Embodiment 8.

In this specification and the like, a structure in which light-emitting layers in light-emitting devices of different colors (e.g., blue (B), green (G), and red (R)) and light-receiving layers in light-receiving devices are separately formed or separately patterned may be referred to as an SBS(Side By Side) structure. Note that in the light-emitting and light-receiving apparatus 700 illustrated in FIG. 2A, the light-emitting device 550B, the light-emitting device 550G, the light-emitting device 550R, and the light-receiving device 550PS are arranged in this order; however, one embodiment of the present invention is not limited thereto. For example, in the light-emitting and light-receiving apparatus 700, the light-emitting device 550R, the light-emitting device 550G, the light-emitting device 550B, and the light-receiving device 550PS may be arranged in this order.

In FIG. 2A, the light-emitting device 550B includes an electrode 551B, an electrode 552, and the EL layer 103B interposed between the electrode 551B and the electrode 552. The light-emitting device 550G includes an electrode 551G, the electrode 552, and the EL layer 103G interposed between the electrode 551G and the electrode 552. The light-emitting device 550R includes an electrode 551R, the electrode 552, and the EL layer 103R interposed between the electrode 551R and the electrode 552. The EL layers (103B, 103G, and 103R) each have a stacked-layer structure of layers having different functions including light-emitting layers (105B, 105G, and 105R). A specific structure of each layer of the light-emitting device is as described in Embodiment 2.

In FIG. 2A, the light-receiving device 550PS includes an electrode 551PS, the electrode 552, and a light-receiving layer 103PS interposed between the electrode 551PS and the electrode 552. The light-receiving layer 103PS has a stacked-layer structure of layers having different functions including an active layer 105PS. Note that a specific structure of each layer of the light-receiving device is as described in Embodiment 8.

FIG. 2A illustrates a case where the EL layer 103B includes a hole-injection/transport layer 104B, the light-emitting layer 105B, an electron-transport layer 108B, and an electron-injection layer 109; the EL layer 103G includes a hole-injection/transport layer 104G, the light-emitting layer 105G, an electron-transport layer 108G, and the electron-injection layer 109; the EL layer 103R includes a hole-injection/transport layer 104R, the light-emitting layer 105R, an electron-transport layer 108R, and the electron-injection layer 109; and the light-receiving layer 103PS includes a hole-injection/transport layer 104PS, the active layer 105PS, an electron-transport layer 108PS, and the electron-injection layer 109. However, the present invention is not limited to the case.

Note that the electron-transport layers (108B, 108G, 108R, and 108PS) may have a function of blocking holes moving from the anode side to the cathode side through the light-emitting layers (105B, 105G, and 105R) and the active layer 105PS of the light-receiving device. The electron-injection layer 109 may have a stacked-layer structure in which some or all of layers are formed using different materials.

As illustrated in FIG. 2A, an insulating layer 107 may be formed on side surfaces (or end portions) of the hole-injection/transport layers (104B, 104G, and 104R), the light-emitting layers (105B, 105G, and 105R), and the electron-transport layers (108B, 108G, and 108R) included in the EL layers (103B, 103G, and 103R), and side surfaces (or end portions) of the hole-injection/transport layer 104PS, the active layer 105PS, and the electron-transport layer 108PS included in the light-receiving layer 103PS. The insulating layer 107 is formed in contact with the side surfaces (or the end portions) of the EL layers (103B, 103G, and 103R) and the light-receiving layer 103PS. This can inhibit entry of oxygen, moisture, or constituent elements thereof into the inside through the side surfaces of the EL layers (103B, 103G, and 103R) and the light-receiving layer 103PS. For the insulating layer 107, aluminum oxide, magnesium oxide, hafnium oxide, gallium oxide, indium gallium zinc oxide, silicon nitride, silicon nitride oxide, or the like can be used, for example. Some of the above-described materials may be stacked to form the insulating layer 107. The insulating layer 107 can be formed by a sputtering method, a CVD method, an MBE method, a PLD method, an ALD method, or the like and is formed preferably by an ALD method, which enables favorable coverage. Note that the insulating layer 107 continuously covers the side surfaces (or the end portions) of parts of the EL layers (103B, 103G, and 103R) of adjacent light-emitting devices and part of the light-receiving layer 103PS of the light-receiving device. For example, in FIG. 2A, the side surfaces of part of the EL layer 103B of the light-emitting device 550B and part of the EL layer 103G of the light-emitting device 550G are covered with an insulating layer 107. In a region covered with the insulating layer 107, a partition wall 528 formed using an insulating material is preferably formed, as illustrated in FIG. 2A.

In FIG. 2A, the electron-injection layer 109 and the electrode 552 are layers (common layers) shared by the devices (550B, 550G, 550R, and 550PS). Note that the electron-injection layer 109 may have a stacked-layer structure of two or more layers (for example, stacked layers having different electric resistances).

The partition walls 528 are provided between the electrodes (551B, 551G, 551R, and 551PS), parts of the EL layers (103B, 103G, and 103R), and part of the light-receiving layer 103PS. As illustrated in FIG. 2A, the partition walls 528 are in contact with the side surfaces (or the end portions) of the electrodes (551B, 551G, 551R, and 551PS) and parts of the EL layers (103B, 103G, and 103R) and part of the light-receiving layer 103PS of the devices through the insulating layer 107.

In each of the EL layers and the light-receiving layer, particularly the hole-injection layer, which is included in the hole-transport region between the anode and the light-emitting layer and the hole-transport region between the anode and the active layer, often has high conductivity; therefore, a hole-injection layer formed as a layer shared by adjacent light-emitting devices might cause crosstalk. Thus, as described in this structure example, the partition walls 528 formed using an insulating material are provided between the EL layers and between the EL layer and the light-receiving layer, which can inhibit occurrence of crosstalk between adjacent devices.

In the manufacturing method described in this embodiment, side surfaces (or end portions) of the EL layer and the light-receiving layer are exposed in the patterning step. This may promote deterioration of the EL layer and the light-receiving layer by allowing the entry of oxygen, water, or the like through the side surfaces (or the end portions) of the EL layer and the light-receiving layer. Therefore, providing the partition wall 528 can inhibit the deterioration of the EL layer and the light-receiving layer in the manufacturing process.

Providing the partition wall 528 can flatten a depressed portion formed between adjacent devices. When the depressed portion is reduced, disconnection of the electrode 552 formed over the EL layers and the light-receiving layer can be inhibited. As an insulating material used for forming the partition wall 528, an organic material such as an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used, for example. An organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin can also be used. A photosensitive resin such as a photoresist can also be used. Note that as the photosensitive resin, a positive material or a negative material can be used.

With the photosensitive resin, the partition wall 528 can be fabricated only by light exposure and development steps. The partition wall 528 may be formed using a negative photosensitive resin (e.g., a resist material). In the case where an insulating layer containing an organic material is used as the partition wall 528, a material absorbing visible light is suitably used. When a material that absorbs visible light is used for the partition wall 528, light emitted from the EL layer can be absorbed by the partition wall 528, so that light that might leak to the adjacent EL layer and the adjacent light-receiving layer (stray light) can be inhibited. Thus, a display panel having high display quality can be provided.

For example, the difference between the top-surface level of the partition wall 528 and the top-surface level of any of the EL layers (103B, 103G, and 103R) and the light-receiving layer 103PS is preferably 0.5 times or less, further preferably 0.3 times or less the thickness of the partition wall 528. The partition wall 528 may be provided such that the top-surface level of any of the EL layer 103B, the EL layer 103G, the EL layer 103R, and the light-receiving layer 103PS is higher than the top-surface level of the partition wall 528, for example. Alternatively, the partition wall 528 may be provided such that the top-surface level of the partition wall 528 is higher than the top-surface level of each of the EL layer 103B, the EL layer 103G, the EL layer 103R, and the light-receiving layer 103PS, for example.

When electrical continuity is established between the EL layer 103B, the EL layer 103G, the EL layer 103R, and the light-receiving layer 103PS in a light-emitting and light-receiving apparatus (display panel) with a high resolution exceeding 1000 ppi, a crosstalk phenomenon occurs, resulting in a narrower color gamut of the light-emitting and light-receiving apparatus. Providing the partition wall 528 in a high-resolution display panel with more than 1000 ppi, preferably more than 2000 ppi, or further preferably in an ultrahigh-resolution display panel with more than 5000 ppi allows the display panel to express vivid colors.

FIG. 2B and FIG. 2C are each a schematic top view of the light-emitting and light-receiving apparatus 700 taken along the dashed-dotted line Ya-Yb in the cross-sectional view of FIG. 2A. The light-emitting devices (550B, 550G, and 550R) are arranged in a matrix. FIG. 2B illustrates what is called stripe arrangement, in which the light-emitting devices of the same color are arranged in X-direction. FIG. 2C illustrates a structure in which the light-emitting devices of the same color are arranged in the X-direction and separated by patterning for each pixel. Note that the arrangement method of the light-emitting devices is not limited thereto; another arrangement method such as delta arrangement, zigzag arrangement, PenTile arrangement, or diamond arrangement may also be used.

Each of the EL layers (103B, 103G, and 103R) and the light-receiving layer 103PS are processed to be separated by patterning using a photolithography method; hence, a high-resolution light-emitting and light-receiving apparatus (display panel) can be fabricated. End portions (side surfaces) of layers of the EL layer processed by patterning using a photolithography method have substantially one surface (or are positioned on substantially the same plane). In addition, the side surfaces (end portions) of the layers of the light-receiving layer processed by patterning using a photolithography method have substantially the same surface (or are positioned on substantially the same plane). In this case, the width (SE) of the space 580 between the EL layers and between the EL layer and the light-receiving layer is preferably 5 μm or less, further preferably 1 μm or less.

In the EL layer, particularly the hole-injection layer, which is included in the hole-transport region between the anode and the light-emitting layer, often has high conductivity; therefore, a hole-injection layer formed as a layer shared by adjacent light-emitting devices might cause crosstalk. Therefore, processing the EL layers to be separated by patterning using a photolithography method as shown in this structure example can suppress occurrence of crosstalk between adjacent light-emitting devices.

FIG. 2D is a schematic cross-sectional view taken along the dashed-dotted line C1-C2 in FIG. 2B and FIG. 2C. FIG. 2D illustrates a connection portion 130 where the connection electrode 551C and the electrode 552 are electrically connected. In the connection portion 130, the electrode 552 is provided over and in contact with the connection electrode 551C. In addition, the partition wall 528 is provided to cover the end portion of the connection electrode 551C.

### <Manufacturing Method Example of Light-Emitting and Light-Receiving Apparatus>

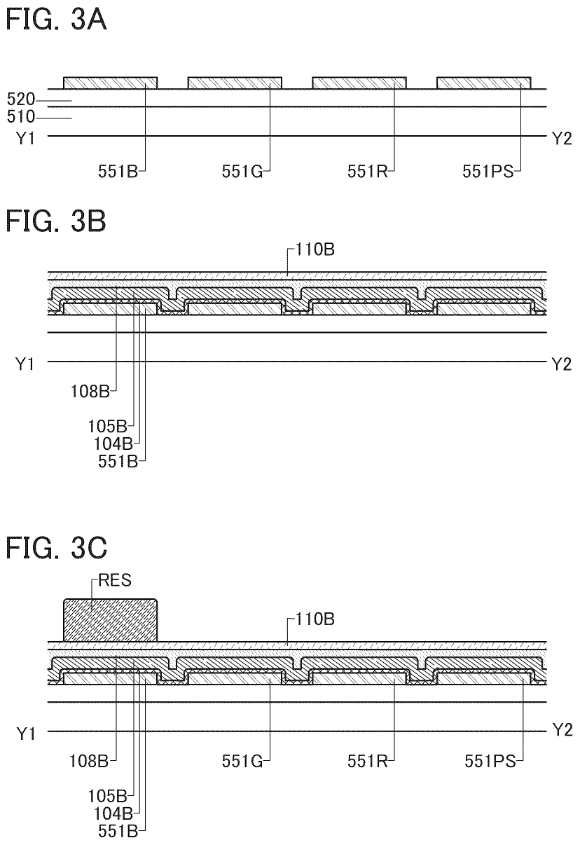

The electrode 551B, the electrode 551G, the electrode 551R, and the electrode 551PS are formed as illustrated in FIG. 3A. For example, a conductive film is formed over the functional layer 520 over the first substrate 510 and processed into predetermined shapes by a photolithography method.

The conductive film can be formed by a sputtering method, a chemical vapor deposition (CVD) method, a molecular beam epitaxy (MBE) method, a vacuum evaporation method, a pulsed laser deposition (PLD) method, an atomic layer deposition (ALD) method, or the like. Examples of the CVD method include a plasma-enhanced chemical vapor deposition (PECVD: Plasma Enhanced CVD) method and athermal CVD method. As an example of the thermal CVD method, a metal organic chemical vapor deposition (MOCVD: Metal Organic CVD) method can be given.

The conductive film may be processed by a nanoimprinting method, a sandblasting method, a lift-off method, or the like as well as a photolithography method described above. Alternatively, island-shaped thin films may be directly formed by a film formation method using a shielding mask such as a metal mask.

There are two typical processing methods using a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development. The former method involves heat treatment steps such as heating after resist application (PAB: Pre Applied Bake) and heating after light exposure (PEB: Post Exposure Bake). In one embodiment of the present invention, a lithography method is used not only for processing of a conductive film but also for processing of a thin film used for formation of an EL layer (a film made of an organic compound or a film partly including an organic compound).

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. Light exposure may be performed by liquid immersion light exposure technique. As the light for light exposure, extreme ultraviolet (EUV) light or X-rays may also be used. Instead of the light for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of a thin film using a resist mask, a dry etching method, a wet etching method, a sandblast method, or the like can be used.

Subsequently, as illustrated in FIG. 3B, the hole-injection/transport layer 104B, the light-emitting layer 105B, and the electron-transport layer 108B are formed over the electrode 551B, the electrode 551G, the electrode 551R, and the electrode 551PS. Note that the hole-injection/transport layer 104B, the light-emitting layer 105B, and the electron-transport layer 108B can be formed using a vacuum evaporation method, for example. Furthermore, a sacrificial layer 1101B is formed over the electron-transport layer 108B. For the formation of the hole-injection/transport layer 104B, the light-emitting layer 105B, and the electron-transport layer 108B, any of the materials described in Embodiment 1 and Embodiment 2 can be used.

For the sacrificial layer 110B, it is preferable to use a film highly resistant to etching treatment performed on the hole-injection/transport layer 104B, the light-emitting layer 105B, and the electron-transport layer 108B, i.e., a film having high etching selectivity. The sacrificial layer 1101B preferably has a stacked-layer structure of a first sacrificial layer and a second sacrificial layer which have different etching selectivities. Moreover, for the sacrificial layer 1101B, it is possible to use a film that can be removed by a wet etching method less likely to cause damage to the EL layer 103B. In wet etching, oxalic acid or the like can be used as an etching material. Note that in this specification and the like, a sacrificial layer may be referred to as a mask layer.

The sacrificial layer 110B can be formed using an inorganic film such as a metal film, an alloy film, a metal oxide film, a semiconductor film, or an inorganic insulating film, for example. The sacrificial layer 110B can be formed by any of a variety of film formation methods such as a sputtering method, an evaporation method, a CVD method, and an ALD method.

For the sacrificial layer 110B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used. It is particularly preferable to use a low-melting-point material such as aluminum or silver.

The sacrificial layer 1101B can be formed using a metal oxide such as indium gallium zinc oxide (In—Ga—Zn oxide, also referred to as IGZO). It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon can also be used, for example.

Note that an element M(M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above. In particular, M is preferably one or more kinds selected from gallium, aluminum, and yttrium.

For the sacrificial layer 110B, an inorganic insulating material such as aluminum oxide, hafnium oxide, or silicon oxide can be used.

The sacrificial layer 110B is preferably formed using a material that can be dissolved in a solvent chemically stable with respect to the electron-transport layer 108B, which is the uppermost layer. In particular, a material that will be dissolved in water or alcohol can be suitably used for the sacrificial layer 1101B. Information of the sacrificial layer 110B, it is preferable that application of such a material dissolved in a solvent such as water or alcohol be performed by a wet film formation method and followed by heat treatment for evaporating the solvent. At this time, the heat treatment is preferably performed in a reduced-pressure atmosphere, in which case the solvent can be removed at a low temperature in a short time and thermal damage to the hole-injection/transport layer 104B, the light-emitting layer 105B, and the electron-transport layer 108B can be reduced accordingly.

In the case where the sacrificial layer 1101B having a stacked-layer structure is formed, the stacked-layer structure can include the first sacrificial layer formed using any of the above-described materials and the second sacrificial layer thereover.

The second sacrificial layer in that case is a film used as a hard mask for etching of the first sacrificial layer. In processing the second sacrificial layer, the first sacrificial layer is exposed. Thus, a combination of films having high etching selectivity therebetween is selected for the first sacrificial layer and the second sacrificial layer. Thus, a film that can be used for the second sacrificial layer can be selected in accordance with the etching conditions of the first sacrificial layer and the etching conditions of the second sacrificial layer.

For example, in the case where dry etching using a gas containing fluorine (also referred to as a fluorine-based gas) is performed for the etching of the second sacrificial layer, silicon, silicon nitride, silicon oxide, tungsten, titanium, molybdenum, tantalum, tantalum nitride, an alloy containing molybdenum and niobium, an alloy containing molybdenum and tungsten, or the like can be used for the second sacrificial layer. Here, a metal oxide film of IGZO, ITO, or the like is given as an example of a film having high etching selectivity (that is, enabling low etching rate) in dry etching using the fluorine-based gas, and such a film can be used as the first sacrificial layer.

Note that the material for the second sacrificial layer is not limited to the above and can be selected from a variety of materials in accordance with the etching conditions of the first sacrificial layer and the etching conditions of the second sacrificial layer. For example, any of the films that can be used for the first sacrificial layer can be selected.

As the second sacrificial layer, a nitride film can be used, for example. Specifically, it is possible to use a nitride such as silicon nitride, aluminum nitride, hafnium nitride, titanium nitride, tantalum nitride, tungsten nitride, gallium nitride, or germanium nitride.

Alternatively, an oxide film can be used as the second sacrificial layer. Typically, a film of an oxide or an oxynitride such as silicon oxide, silicon oxynitride, aluminum oxide, aluminum oxynitride, hafnium oxide, or hafnium oxynitride can be used.

Next, as illustrated in FIG. 3C, a resist is applied onto the sacrificial layer 110B, and the resist having a desired shape (a resist mask RES) is formed by a photolithography method. Such a method involves heat treatment steps such as heating after resist application (PAB: Pre Applied Bake) and heating after light exposure (PEB: Post Exposure Bake). The PAB temperature reaches approximately 100° C. and the PEB temperature reaches approximately 120° C., for example. Therefore, the light-emitting device needs to be resistant to such treatment temperatures.

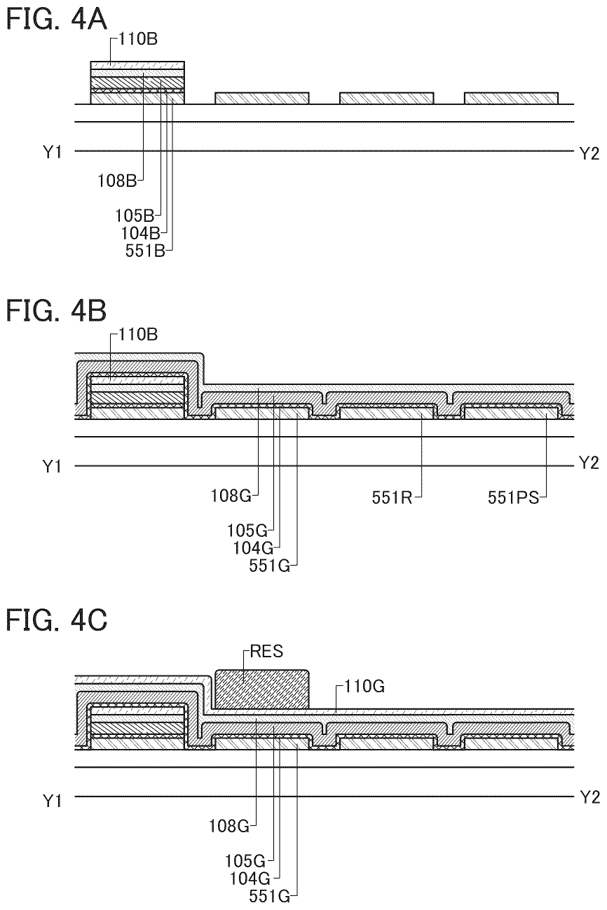

Next, part of the sacrificial layer 110B that is not covered with the resist mask RES is removed by etching using the obtained resist mask RES, the resist mask RES is removed, and then the hole-injection/transport layer 104B, the light-emitting layer 105B, and the electron-transport layer 108B that are not covered with the sacrificial layer 1101B are partly removed by etching, so that the hole-injection/transport layer 104B, the light-emitting layer 105B, and the electron-transport layer 108B are processed to have side surfaces (or have their side surfaces exposed) over the electrode 551B or have belt-like shapes extending in the direction intersecting with the paper. Note that dry etching is preferably employed for the etching. In the case where the sacrificial layer 1101B has the aforementioned stacked-layer structure of the first sacrificial layer and the second sacrificial layer, the hole-injection/transport layer 104B, the light-emitting layer 105B, and the electron-transport layer 108B may be processed into predetermined shapes in the following manner: part of the second sacrificial layer is etched with use of the resist mask RES, the resist mask RES is then removed, and part of the first sacrificial layer is etched with use of the second sacrificial layer as a mask. The shape illustrated in FIG. 4A is obtained through these etching treatment.

Subsequently, as illustrated in FIG. 4B, the hole-injection/transport layer 104G, the light-emitting layer 105G, and the electron-transport layer 108G are formed over the sacrificial layer 110B, the electrode 551G, the electrode 551R, and the electrode 551PS. As the materials for forming the hole-injection/transport layer 104G, the light-emitting layer 105G, and the electron-transport layer 108G, any of the materials described in Embodiment 1 and Embodiment 2 can be used. Note that the hole-injection/transport layer 104G, the light-emitting layer 105G, and the electron-transport layer 108G can be formed by a vacuum evaporation method, for example.

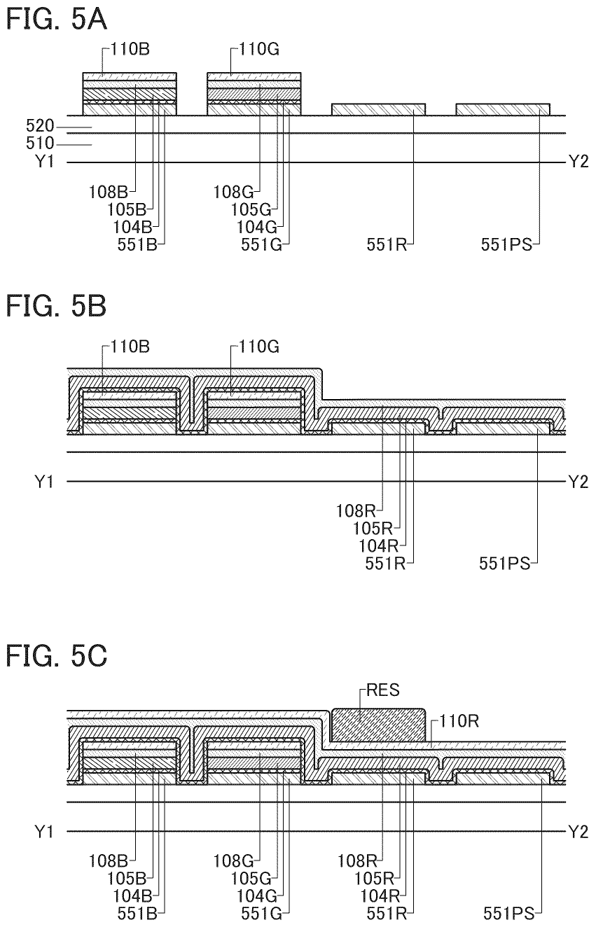

Next, as illustrated in FIG. 4C, the sacrificial layer 110G is formed over the electron-transport layer 108G, a resist is applied onto the sacrificial layer 110G, and the resist having a desired shape (the resist mask RES) is formed by a photolithography method. Part of the sacrificial layer 110G that is not covered with the obtained resist mask is removed by etching, the resist mask is then removed, and then the hole-injection/transport layer 104G, the light-emitting layer 105G, and the electron-transport layer 108G that are not covered with the sacrificial layer 110G are partly removed by etching. Thus, the hole-injection/transport layer 104G, the light-emitting layer 105G, and the electron-transport layer 108G are processed to have side surfaces (or have their side surfaces exposed) over the electrode 551G or have belt-like shapes extending in the direction intersecting with the paper. Note that dry etching is preferably employed for the etching. The sacrificial layer 110G can be formed using a material similar to that for the sacrificial layer 110B. In the case where the sacrificial layer 110G has the aforementioned stacked-layer structure of the first sacrificial layer and the second sacrificial layer, the hole-injection/transport layer 104G, the light-emitting layer 105G, and the electron-transport layer 108G may be processed into predetermined shapes in the following manner: part of the second sacrificial layer is etched with use of the resist mask RES, the resist mask RES is then removed, and then part of the first sacrificial layer is etched with use of the second sacrificial layer as a mask. The shape illustrated in FIG. 5A is obtained through these etching treatment.

Next, as illustrated in FIG. 5B, the hole-injection/transport layer 104R, the light-emitting layer 105R, and the electron-transport layer 108R are formed over the sacrificial layer 1101B, the sacrificial layer 110G, the electrode 551R, and the electrode 551PS. For the formation of the hole-injection/transport layer 104R, the light-emitting layer 105R, and the electron-transport layer 108R, any of the materials described in Embodiment 1 and Embodiment 2 can be used. Note that the hole-injection/transport layer 104R, the light-emitting layer 105R, and the electron-transport layer 108R can be formed by a vacuum evaporation method, for example.

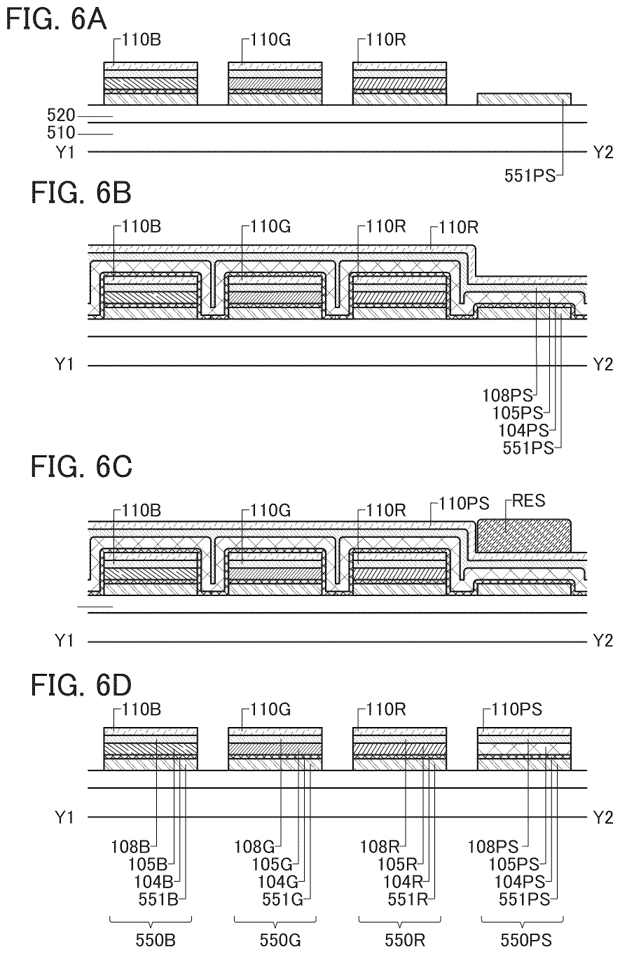

Next, as illustrated in FIG. 5C, the sacrificial layer 110R is formed over the electron-transport layer 108R, a resist is applied onto the sacrificial layer 110R, and the resist having a desired shape (the resist mask RES) is formed by a photolithography method. Part of the sacrificial layer 110R that is not covered with the obtained resist mask RES is removed by etching, the resist mask RES is then removed, and then the hole-injection/transport layer 104R, the light-emitting layer 105R, and the electron-transport layer 108R that are not covered with the sacrificial layer 110R are removed by etching. Thus, the hole-injection/transport layer 104R, the light-emitting layer 105R, and the electron-transport layer 108R are processed to have side surfaces (or have their side surfaces exposed) over the electrode 551R or have belt-like shapes extending in the direction intersecting with the paper. Note that dry etching is preferably employed for the etching. The sacrificial layer 110R can be formed using a material similar to that for the sacrificial layer 110B. In the case where the sacrificial layer 110R has the aforementioned stacked-layer structure of the first sacrificial layer and the second sacrificial layer, the hole-injection/transport layer 104R, the light-emitting layer 105R, and the electron-transport layer 108R may be processed into a predetermined shape in the following manner: part of the second sacrificial layer is etched with use of the resist mask RES, the resist mask RES is then removed, and part of the first sacrificial layer is etched with use of the second sacrificial layer as a mask. The shape illustrated in FIG. 6A is obtained through these etching treatment.

Next, as illustrated in FIG. 6B, the hole-injection/transport layer 104PS, the active layer 105PS, and the electron-transport layer 108PS are formed over the sacrificial layer 1101B, the sacrificial layer 110G, the sacrificial layer 110R, and the electrode 551PS. As a material for forming the hole-injection/transport layer 104PS, for example, the material for the hole-injection layer and the hole-transport layer of the light-emitting device described in Embodiment 2 can be used. As a material for the active layer 105PS, a material described in Embodiment 8 can be used. Furthermore, as a material for forming the electron-transport layer 108PS, for example, the material for the electron-transport layer and the electron-injection layer described in Embodiment 2 can be used. Note that the hole-injection/transport layer 104PS, the active layer 105PS, and the electron-transport layer 108PS can be formed by a vacuum evaporation method, for example.

Next, as illustrated in FIG. 6C, the sacrificial layer 110PS is formed over the electron-transport layer 108PS, a resist is applied onto the sacrificial layer 110PS, and the resist having a desired shape (the resist mask RES) is formed by a photolithography method. Part of the sacrificial layer 110PS that is not covered with the obtained resist mask RES is removed by etching, the resist mask RES is then removed, and the hole-injection/transport layer 104PS, the active layer 105PS, and the electron-transport layer 108PS that are not covered with the sacrificial layer are removed by etching. Thus, the hole-injection/transport layer 104PS, the active layer 105PS, and the electron-transport layer 108PS are processed to have side surfaces (or have their side surfaces exposed) over the electrode 551PS or have belt-like shapes extending in the direction intersecting with the paper. Note that dry etching is preferably employed for the etching. The sacrificial layer 110PS can be formed using a material similar to that for the sacrificial layer 110B. In the case where the sacrificial layer 110PS has the aforementioned stacked-layer structure of the first sacrificial layer and the second sacrificial layer, the hole-injection/transport layer 104PS, the active layer 105PS, and the electron-transport layer 108PS may be processed into a predetermined shape in the following manner: part of the second sacrificial layer is etched using the resist mask RES, the resist mask RES is then removed, and part of the first sacrificial layer is etched using the second sacrificial layer as a mask. The shape illustrated in FIG. 6D is obtained through these etching treatment.

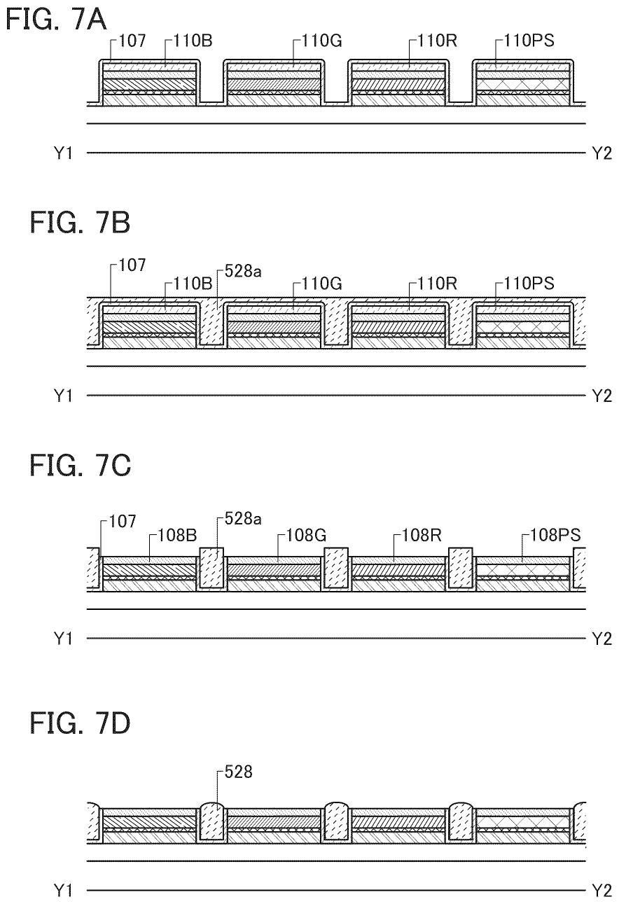

Next, as illustrated in FIG. 7A, the insulating layer 107 is formed over the sacrificial layer 110B, the sacrificial layer 110G, the sacrificial layer 110R, and the sacrificial layer 110PS.

For formation of the insulating layer 107, an ALD method can be used, for example. In this case, as illustrated in FIG. 7A, the insulating layer 107 is formed to be in contact with the side surfaces (end portions) of the hole-injection/transport layers (104B, 104G, and 104R), the light-emitting layers (105B, 105G, and 105R), and the electron-transport layers (108B, 108G, and 108R) of the light-emitting devices and the hole-injection/transport layer 104PS, the active layer 105PS, and the electron-transport layer 108PS of the light-receiving device. This can inhibit entry of oxygen, moisture, or constituent elements thereof into the inside through the side surfaces. As a material used for the insulating layer 107, aluminum oxide, magnesium oxide, hafnium oxide, gallium oxide, indium gallium zinc oxide, silicon nitride, silicon nitride oxide, or the like can be used, for example.

Next, as illustrated in FIG. 7B, a resin film 528a is formed over the insulating layer 107. As the resin film 528a, for example, a negative photosensitive resin or a positive photosensitive resin can be used.

Then, as illustrated in FIG. 7C, part of the resin film 528a, part of the insulating layer 107, and the sacrificial layers (110B, 110G, 110R, and 110PS) are removed to expose the top surfaces of the electron-transport layers (108B, 108G, 108R, and 108PS).

Next, heat treatment is performed to process an upper edge portion of the resin film 528a into a curved shape, so that the partition wall 528 is formed, as illustrated in FIG. 7D. When the upper edge portion of the partition wall 528 has a curved shape, good coverage with the electron-injection layer 109 to be formed later can be obtained. For example, in the case of using a positive photosensitive acrylic resin as a material for the resin film 528a, the partition wall 528 preferably has a curved surface with a curvature radius (0.2 μm to 3 μm) at the upper end portion.

Next, the electron-injection layer 109 is formed over the insulating layer 107, the electron-transport layers (108B, 108G, 108R, and 108PS), and the partition wall 528. The electron-injection layer 109 can be formed using any of the materials described in Embodiment 2. The electron-injection layer 109 is formed by a vacuum evaporation method, for example.

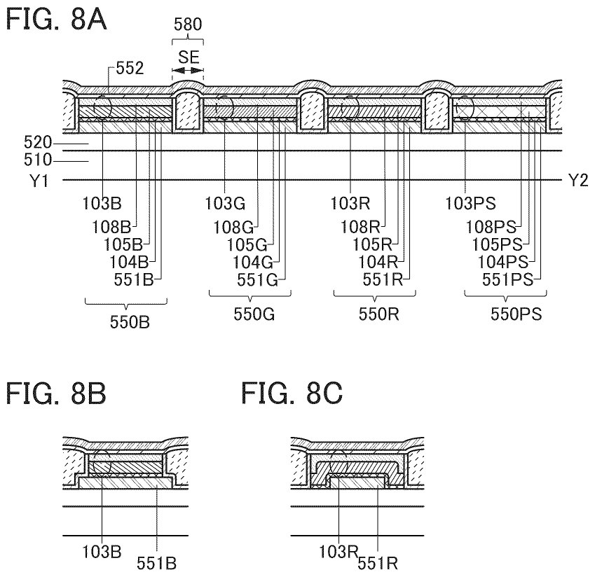

Next, as illustrated in FIG. 8A, the electrode 552 is formed over the electron-injection layer 109. The electrode 552 is formed by a vacuum evaporation method, for example.

Through the above steps, the EL layer 103B, the EL layer 103G, the EL layer 103R, and the light-receiving layer 103PS in the light-emitting device 550B, the light-emitting device 550G, the light-emitting device 550R, and the light-receiving device 550PS can be processed to be separated from each other.

The EL layers (the EL layer 103B, the EL layer 103G, and the EL layer 103R) and the light-receiving layer 103PS are processed to be separated by patterning using a photolithography method; hence, a high-resolution light-emitting and light-receiving apparatus (display panel) can be fabricated. End portions (side surfaces) of layers of the EL layer processed by patterning using a photolithography method have substantially one surface (or are positioned on substantially the same plane). In addition, the side surfaces (end portions) of the layers of the light-receiving layer processed by patterning using a photolithography method have substantially the same surface (or are positioned on substantially the same plane).

The hole-injection/transport layers (104B, 104G, and 104R) of the EL layers and the hole-injection/transport layer 104PS of the light-receiving layer often have high conductivity, and thus might cause crosstalk when formed as layers shared by adjacent light-emitting devices. Therefore, processing the EL layers to be separated by patterning using a photolithography method as shown in this structure example can suppress occurrence of crosstalk between a light-emitting device and a light-receiving device adjacent to each other.

In this structure, the hole-injection/transport layers (104B, 104G, and 104R), the light-emitting layers (105B, 105G, and 105R), andthe electron-transport layers (108B, 108G, and 108R) of the EL layers (103B, 103G, and 103R) included in the light-emitting devices and the hole-injection/transport layer 104PS, the active layer 105PS, and the electron-transport layer 108PS of the light-receiving layer 103PS included in the light-receiving device are processed to be separated by patterning using a photolithography method; thus, the end portions (side surfaces) of the processed EL layers have substantially the same surface (or are positioned on substantially the same plane). In addition, the side surfaces (end portions) of the layers of the light-receiving layer processed by patterning using a photolithography method have substantially the same surface (or are positioned on substantially the same plane).

In addition, the hole-injection/transport layers (104B, 104G, and 104R), the light-emitting layers (105B 105G, and 105R), and the electron-transport layers (108B, 108G, and 108R) of the EL layers (the EL layer 103B, the EL layer 103G, and the EL layer 103R) included in the light-emitting devices and the hole-injection/transport layer 104PS, the active layer 105PS, and the electron-transport layer 108PS of the light-receiving layer 103PS included in the light-receiving device are processed to be separated by patterning using a photolithography method. Thus, the space 580 is provided between the processed end portions (side surfaces) of adjacent light-emitting devices. In FIG. 8A, when a distance between the EL layers or between the EL layer and the light-receiving layer of the adjacent devices is denoted by SE, the aperture ratio can be increased and the resolution can be increased as the distance SE decreases. By contrast, as the distance SE increases, the effect of the difference in the fabrication process between the adjacent devices becomes permissible, which leads to an increase in manufacturing yield. Since the light-emitting device and the light-receiving device fabricated according to this specification is suitable for a miniaturization process, the distance SE between the EL layers or between the EL layer and the light-receiving layer of the adjacent devices can be longer than or equal to 0.5 μm and shorter than or equal to 5 μm, preferably longer than or equal to 1 μm and shorter than or equal to 3 μm, further preferably longer than or equal to 1 μm and shorter than or equal to 2.5 μm, and still further preferably longer than or equal to 1 μm and shorter than or equal to 2 μm. Typically, the distance SE is preferably longer than or equal to 1 μm and shorter than or equal to 2 μm (e.g., 1.5 μm or a neighborhood thereof).

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure. Since a light-emitting and light-receiving apparatus having the MML structure is manufactured without using a metal mask, the pixel arrangement, the pixel shape, and the like can be designed more flexibly than in a light-emitting and light-receiving apparatus having the FMM structure or the MM structure.

Note that an island-shaped EL layer of a light-emitting and light-receiving apparatus having an MML structure is formed not by patterning with use of a metal mask but by processing after formation of an EL layer. Accordingly, a light-emitting and light-receiving apparatus with a higher resolution or a higher aperture ratio than a conventional one can be achieved. Moreover, EL layers can be formed separately for the respective colors, enabling the light-emitting and light-receiving apparatus to perform extremely clear display with high contrast and high display quality. Moreover, providing the sacrificial layer over the EL layer can reduce damage to the EL layer in the manufacturing process, resulting in an increase in the reliability of the light-emitting device.

In FIG. 2A and FIG. 8A, the widths of the EL layers (103B, 103G, and 103R) are substantially equal to the widths of the electrodes (551B, 551G, and 551R) in the light-emitting device 550B, the light-emitting device 550G, and the light-emitting device 550R, and the width of the light-receiving layer 103PS is substantially equal to the width of the electrode 551PS in the light-receiving device 550PS; however, one embodiment of the present invention is not limited thereto.

In the light-emitting device 550B, the light-emitting device 550G, and the light-emitting device 550R, the widths of the EL layers (103B, 103G, and 103R) may be smaller than the widths of the electrodes (551B, 551G, and 551R). In the light-receiving device 550PS, the width of the light-receiving layer 103PS may be smaller than the width of the electrode 551PS. FIG. 8B illustrates an example in which the width of the EL layer 103B is smaller than the width of the electrode 551B in the light-emitting device 550B.

In the light-emitting device 550B, the light-emitting device 550G, and the light-emitting device 550R, the widths of the EL layers (103B, 103G, and 103R) may be larger than the widths of the electrodes (551B, 551G, and 551R). In the light-receiving device 550PS, the width of the light-receiving layer 103PS may be larger than the width of the electrode 551PS. FIG. 8C illustrates an example in which the width of the EL layer 103R is larger than the width of the electrode 551R in the light-emitting device 550R.

Note that the light-emitting and light-receiving apparatus described in this embodiment includes both a light-emitting device and a light-receiving device, and can also be referred to as a light-emitting apparatus including a light-receiving device or a light-receiving apparatus including a light-emitting device. Among the structures of the light-emitting and light-receiving apparatus described in this embodiment, an apparatus that does not include a light-receiving device can also be referred to as a light-emitting apparatus. Among the structures of the light-emitting and light-receiving apparatus described in this embodiment, an apparatus that does not include a light-emitting apparatus can also be referred to as a light-receiving device.

The structures described in this embodiment can be used in an appropriate combination with any of the structures described in the other embodiments.

### Embodiment 4

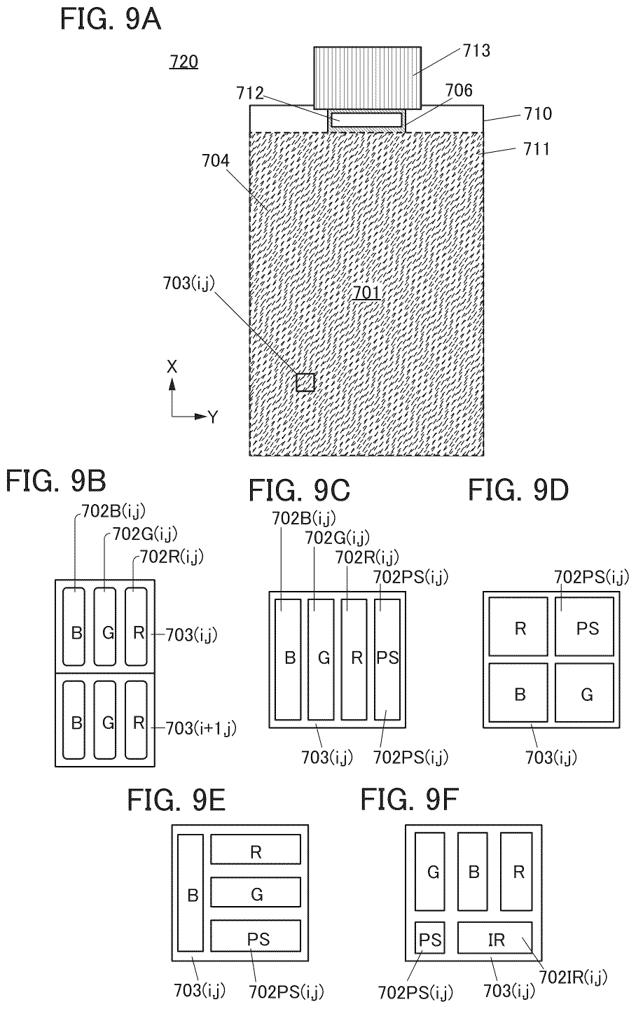

In this embodiment, an apparatus 720 will be described with reference to FIG. 9 to FIG. 11. The apparatus 720 illustrated in FIG. 9 to FIG. 11 includes any of the light-emitting devices described in Embodiment 2. Furthermore, the apparatus 720 described in this embodiment can be used in a display portion of an electronic apparatus or the like and thus can also be referred to as a display panel or a display apparatus. Moreover, when the apparatus includes the light-emitting device as a light source and a light-receiving device that can receive light from the light-emitting device, the apparatuses can also be referred to as a light-emitting and light-receiving apparatus. Note that the light-emitting apparatus, the display panel, the display apparatus, and the light-emitting and light-receiving apparatus each include at least a light-emitting device.

Furthermore, the light-emitting apparatus, the display panel, the display apparatus, and the light-emitting and light-receiving apparatus of this embodiment can each have a high definition or a large size. Accordingly, the light-emitting apparatus, the display panel, the display apparatus, and the light-emitting and light-receiving apparatus can be used for display portions of electronic apparatuses such as a digital camera, a digital video camera, a digital photo frame, a mobile phone, a portable game console, a smartphone, a wristwatch terminal, a tablet terminal, a portable information terminal, and an audio reproducing device, in addition to display portions of electronic apparatuses with a relatively large screen, such as a television device, a desktop or notebook personal computer, a monitor of a computer or the like, digital signage, and a large game machine such as a pachinko machine.

FIG. 9A is a top view of the apparatus 720 (including the light-emitting apparatus, the display panel, the display apparatus, and the light-emitting and light-receiving apparatus).

In FIG. 9A, the apparatus 720 has a structure in which a substrate 710 and a substrate 711 are bonded to each other. In addition, the apparatus 720 includes a display region 701, a circuit 704, a wiring 706, and the like. Note that the display region 701 includes a plurality of pixels. As illustrated in FIG. 9B, a pixel 703(i,j) illustrated in FIG. 9A has a pixel 703(i+1,j) adjacent to the pixel 703(i,j).

Furthermore, as illustrated in the example of FIG. 9A, the substrate 710 is provided with an IC (integrated circuit) 712 by a COG (Chip On Glass) method, a COF (Chip On Film) method, or the like in the apparatus 720. As the IC 712, an IC including a scan line driver circuit, a signal line driver circuit, or the like can be used, for example. FIG. 9A illustrates a structure where an IC including a signal line driver circuit is used as the IC 712, and a scan line driver circuit is used as the circuit 704.

The wiring 706 has a function of supplying signals and power to the display region 701 and the circuit 704. The signals and power are input to the wiring 706 from the outside through an FPC (Flexible Printed Circuit) 713 or to the wiring 706 from the IC 712. Note that the apparatus 720 is not necessarily provided with the IC. The IC may be mounted on the FPC by a COF method or the like.

FIG. 9B illustrates the pixel 703(i,j) and the pixel 703(i+1,j) of the display region 701. The pixel 703(i,j) can have a plurality of kinds of subpixels including light-emitting devices that emit light of different colors. In addition to the above, a plurality of subpixels including light-emitting devices that emit light of the same color may be included. In the case where a plurality of kinds of subpixels including light-emitting devices that emit different color light from each other are included in the pixel, three kinds of subpixels can be included, for example. The three subpixels can be of three colors of red (R), green (G), and blue (B) or of three colors of yellow (Y), cyan (C), and magenta (M), for example. Alternatively, the pixel can include four kinds of subpixels. As the four subpixels, subpixels of four colors of R, G, B, and white (W), subpixels of four colors of R, G, B, and Y, and the like can be given. Specifically, the pixel 703(i,j) can be composed of a subpixel 702B(i,j) displaying blue, a subpixel 702G(i,j) displaying green, and a subpixel 702R(i,j) displaying red.

The apparatus 720 includes not only a subpixel including a light-emitting device, but also a subpixel including a light-receiving device.

FIG. 9C to FIG. 9E illustrate various layout examples of the pixel 703(i,j) including a subpixel 702PS(i,j) including alight-receiving device. The pixel arrangement illustrated in FIG. 9C is stripe arrangement, and the pixel arrangement illustrated in FIG. 9D is matrix arrangement. In the pixel arrangement illustrated in FIG. 9E, three subpixels (the subpixel R, the subpixel G, and the subpixel PS) are vertically arranged next to one subpixel (the subpixel B).

Furthermore, as illustrated in FIG. 9F, a subpixel 702IR(i,j) that emits infrared rays may be added to any of the above-described sets of subpixels to form the pixel 703(i,j). In the pixel arrangement illustrated in FIG. 9F, the three vertically long subpixel G, subpixel B, and subpixel R are arranged laterally, and the subpixel PS and the horizontally long subpixel IR are arranged laterally below the three subpixels. Specifically, the subpixel 702IR(i,j) that emits light including light with a wavelength greater than or equal to 650 nm and less than or equal to 1000 nm may be used in the pixel 703(i,j). Note that the wavelength of light detected by the subpixel 702PS(i,j) is not particularly limited; however, the light-receiving device included in the subpixel 702PS(i,j) preferably has sensitivity to light emitted from the light-emitting device included in the subpixel 702R(i,j), the subpixel 702G(i,j), the subpixel 702B(i,j), or the subpixel 702IR(i,j). The light-receiving device preferably detects one or more of light in blue, violet, bluish violet, green, yellowish green, yellow, orange, red, and infrared wavelength ranges, for example.

Note that the arrangement of subpixels is not limited to the structures illustrated in FIG. 9B to FIG. 9F and a variety of arrangement methods can be employed. The arrangement of subpixels may be stripe arrangement, S stripe arrangement, matrix arrangement, delta arrangement, Bayer arrangement, or PenTile arrangement, for example.

Examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to a top surface shape of a light-emitting region of the light-emitting device.

In the case where a pixel includes a light-receiving device in addition to a light-emitting device, the pixel has a light-receiving function; thus, a touch or an approach of an object can be detected while an image is being displayed. For example, all the subpixels included in the light-emitting apparatus can display an image; alternatively, some of the subpixels can emit light as a light source, and the rest of the subpixels can display an image.

Note that the light-receiving area of the subpixel 702PS(i,j) is preferably smaller than the light-emitting areas of the other subpixels. A smaller light-receiving area leads to a narrower image-capturing range, inhibits a blur in an image capturing result, and improves the definition. Thus, by using the subpixel 702PS(i,j), high-resolution or high-definition image capturing is possible. For example, image capturing for personal authentication with the use of a fingerprint, a palm print, the iris, the shape of a blood vessel (including the shape of a vein and the shape of an artery), a face, or the like is possible by using the subpixel 702PS(i,j).

Moreover, the subpixel 702PS(i,j) can be used in a touch sensor (also referred to as a direct touch sensor), a near touch sensor (also referred to as a hover sensor, a hover touch sensor, a contactless sensor, or a touchless sensor), or the like. For example, the subpixel 702PS(i,j) preferably detects infrared light. Thus, a touch can be detected even in a dark place.

Here, the touch sensor or the near touch sensor can detect the approach or contact of an object (e.g., a finger, a hand, or a pen). The touch sensor can detect the object when the light-emitting and light-receiving apparatus and the object come in direct contact with each other. Furthermore, the near touch sensor can detect the object even when the object is not in contact with the light-emitting and light-receiving apparatus. For example, the display apparatus is preferably capable of detecting an object positioned in the range of 0.1 mm to 300 mm inclusive, further preferably 3 mm to 50 mm inclusive from the light-emitting and light-receiving apparatus. This structure enables the light-emitting and light-receiving apparatus to be operated without direct contact of an object, that is, enables the light-emitting and light-receiving apparatus to be operated in a contactless (touchless) manner. With the above-described structure, the light-emitting and light-receiving apparatus can be operated with a reduced risk of making the light-emitting and light-receiving apparatus dirty or damaging the light-emitting and light-receiving apparatus or without the object directly touching a dirt (e.g., dust, bacteria, or a virus) attached to the display apparatus.

For high-resolution image capturing, the subpixels 702PS(i,j) are preferably provided in all pixels included in the light-emitting and light-receiving apparatus. Meanwhile, in the case where the subpixel 702PS(i,j) is used in a touch sensor, a near touch sensor, or the like, high accuracy is not required as compared to the case of capturing an image of a fingerprint or the like; accordingly, the subpixel 702PS(i,j) may be provided in some pixels in the light-emitting and light-receiving apparatus. When the number of the subpixels 702PS(i,j) included in the light-emitting and light-receiving apparatus is smaller than the number of the subpixels 702R(i,j) or the like, higher detection speed can be achieved.

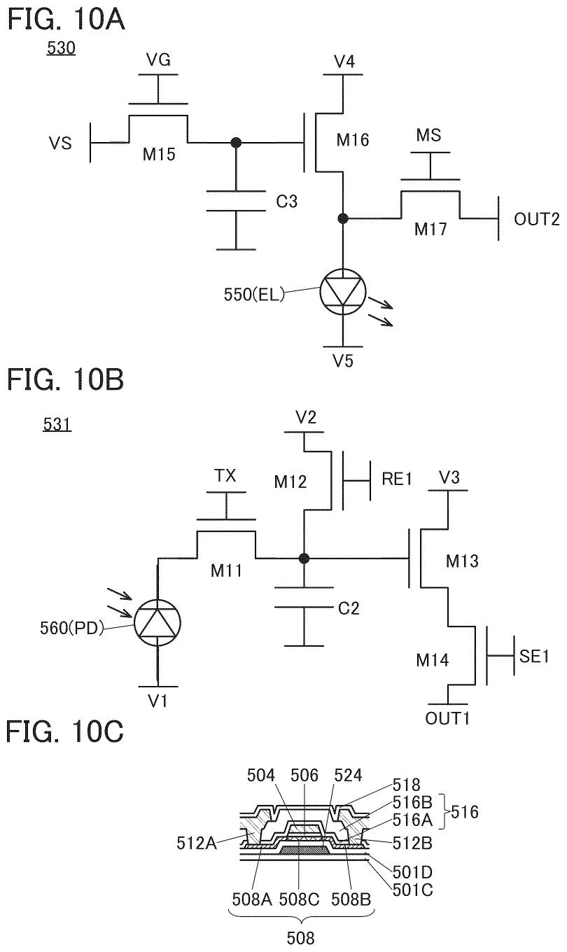

Next, an example of a pixel circuit of a subpixel including the light-emitting device is described with reference to FIG. 10A. A pixel circuit 530 illustrated in FIG. 10A includes a light-emitting device (EL) 550, a transistor M15, a transistor M16, a transistor M17, and a capacitor C3. Note that a light-emitting diode can be used as the light-emitting device 550. In particular, any of the light-emitting devices described in Embodiment 2 is preferably used as the light-emitting device 550.

In the transistor M15 illustrated in FIG. 10A, a gate is electrically connected to a wiring VG, one of a source and a drain is electrically connected to a wiring VS, and the other of the source and the drain is electrically connected to one electrode of the capacitor C3 and a gate of the transistor M16. One of a source and a drain of the transistor M16 is electrically connected to a wiring V4, and the other of the source and the drain of the transistor M16 is electrically connected to an anode of the light-emitting device 550 and one of a source and a drain of the transistor M17. A gate of the transistor M17 is electrically connected to a wiring MS, and the other of the source and the drain of the transistor M17 is electrically connected to a wiring OUT2. A cathode of the light-emitting device 550 is electrically connected to a wiring V5.

A constant potential is supplied to the wiring V4 and the wiring V5. In the light-emitting device 550, the anode side can have a high potential and the cathode side can have a lower potential than the anode side. The transistor M15 is controlled by a signal supplied to the wiring VG and functions as a selection transistor for controlling a selection state of the pixel circuit 530. The transistor M16 functions as a driving transistor that controls a current flowing through the light-emitting device 550 in accordance with a potential supplied to the gate of the transistor M16. When the transistor M15 is in a conduction state, a potential supplied to the wiring VS is supplied to the gate of the transistor M16, and the luminance of the light-emitting device 550 can be controlled in accordance with the potential. The transistor M17 is controlled by a signal supplied to the wiring MS and has a function of outputting a potential between the transistor M16 and the light-emitting device 550 to the outside through the wiring OUT2.

Here, transistors in which a metal oxide (an oxide semiconductor) is used in a semiconductor layer where a channel is formed are preferably used as the transistor M15, the transistor M16, the transistor M17 included in the pixel circuit 530 illustrated in FIG. 10A, and a transistor M11, the transistor M12, a transistor M13, and a transistor M14 included in the pixel circuit 531 illustrated in FIG. 10B.

A transistor using a metal oxide having a wider band gap and a lower carrier density than silicon achieves an extremely low off-state current. Therefore, owing to the low off-state current, charge accumulated in a capacitor that is connected in series with the transistor can be retained for a long time. Accordingly, it is particularly preferable to use transistors containing an oxide semiconductor as the transistor M11, the transistor M12, and the transistor M15 each of which is connected in series with a capacitor C2 or the capacitor C3. When the other transistors also include an oxide semiconductor, the manufacturing cost can be reduced.

Alternatively, transistors using silicon for a semiconductor in which a channel is formed can be used as the transistor M11 to the transistor M17. It is particularly preferable to use silicon with high crystallinity, such as single crystal silicon or polycrystalline silicon, because high field-effect mobility can be achieved and higher-speed operation can be performed.

Alternatively, a transistor using an oxide semiconductor may be used as one or more of the transistor M11 to the transistor M17, and transistors using silicon may be used as the other transistors.

Next, an example of a pixel circuit of a subpixel including a light-receiving device is described with reference to FIG. 10B. A pixel circuit 531 illustrated in FIG. 10B includes a light-receiving device (PD) 560, the transistor M11, the transistor M12, the transistor M13, the transistor M14, and the capacitor C2. Here, an example in which a photodiode is used as the light-receiving device (PD) 560 is illustrated.

In the light-receiving device (PD) 560 illustrated in FIG. 10B, an anode is electrically connected to a wiring V1, and a cathode is electrically connected to one of a source and a drain of the transistor M11. A gate of the transistor M11 is electrically connected to a wiring TX, and the other of the source and the drain of the transistor M11 is electrically connected to one electrode of the capacitor C2, one of a source and a drain of the transistor M12, and a gate of the transistor M13. A gate of the transistor M12 is electrically connected to a wiring RE1, and the other of the source and the drain of the transistor M12 is electrically connected to a wiring V2. One of a source and a drain of the transistor M13 is electrically connected to a wiring V3, and the other of the source and the drain of the transistor M13 is electrically connected to one of a source and a drain of the transistor M14. A gate of the transistor M14 is electrically connected to a wiring SE1, and the other of the source and the drain of the transistor M14 is electrically connected to a wiring OUT1.

A constant potential is supplied to each of the wiring V1, the wiring V2, and the wiring V3. When the light-receiving device (PD) 560 is driven with a reverse bias, the wiring V2 is supplied with a potential higher than the potential of the wiring V1. The transistor M12 is controlled by a signal supplied to the wiring RE1 and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with a current flowing through the light-receiving device (PD) 560. The transistor M13 functions as an amplifier transistor for performing output corresponding to the potential of the node. The transistor M14 is controlled by a signal supplied to the wiring SE1 and functions as a selection transistor for making an external circuit connected to the wiring OUT1 read the output corresponding to the potential of the node.

Although n-channel transistors are shown as the transistors in FIG. 10A and FIG. 10B, p-channel transistors can alternatively be used.

The transistors included in the pixel circuit 530 and the transistors included in the pixel circuit 531 are preferably formed to be arranged over the same substrate. It is particularly preferable that the transistors included in the pixel circuit 530 and the transistors included in the pixel circuit 531 be periodically arranged in one region.

One or more layers including the transistor and/or the capacitor are preferably provided to overlap with the light-receiving device (PD) 560 or the light-emitting device (EL) 550. Thus, the effective area occupied by each pixel circuit can be reduced, and a high-resolution light-receiving portion or display portion can be achieved.

FIG. 10C illustrates an example of a specific structure of a transistor that can be used in the pixel circuit described with reference to FIG. 10A and FIG. 10B. As the transistor, a bottom-gate transistor, a top-gate transistor, or the like can be used as appropriate.

The transistor illustrated in FIG. 10C includes a semiconductor film 508, a conductive film 504, an insulating film 506, a conductive film 512A, and a conductive film 512B. The transistor is formed over an insulating film 501C, for example. The transistor also includes an insulating film 516 (an insulating film 516A and an insulating film 516B) and an insulating film 518.

The semiconductor film 508 includes a region 508A electrically connected to the conductive film 512A and a region 508B electrically connected to the conductive film 512B. The semiconductor film 508 includes a region 508C between the region 508A and the region 508B.

The conductive film 504 includes a region overlapping with the region 508C and has a function of a gate electrode.

The insulating film 506 includes a region positioned between the semiconductor film 508 and the conductive film 504. The insulating film 506 has a function of a first gate insulating film.

The conductive film 512A has one of a function of a source electrode and a function of a drain electrode, and the conductive film 512B has the other of the function of the source electrode and the function of the drain electrode.

A conductive film 524 can be used in the transistor. The conductive film 524 includes a region where the semiconductor film 508 is positioned between the conductive film 504 and the conductive film 524. The conductive film 524 has a function of a second gate electrode. An insulating film 501D is positioned between the semiconductor film 508 and the conductive film 524 and has a function of a second gate insulating film.

The insulating film 516 functions as, for example, a protective film covering the semiconductor film 508. Specifically, a film including a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film can be used as the insulating film 516, for example.

For example, a material having a function of inhibiting diffusion of oxygen, hydrogen, water, an alkali metal, an alkaline earth metal, and the like is preferably used for the insulating film 518. Specifically, the insulating film 518 can be formed using silicon nitride, silicon oxynitride, aluminum nitride, or aluminum oxynitride, for example. In each of silicon oxynitride and aluminum oxynitride, the number of nitrogen atoms contained is preferably larger than the number of oxygen atoms contained.

Note that in a step of forming the semiconductor film used in the transistor of the pixel circuit, the semiconductor film used in the transistor of the driver circuit can be formed. A semiconductor film with the same composition as the semiconductor film used in the transistor of the pixel circuit can be used in the driver circuit, for example.

The semiconductor film 508 preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor film 508. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

In the case where the semiconductor film is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

There is no particular limitation on the crystallinity of a semiconductor material used for the transistors, and any of an amorphous semiconductor and a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be inhibited.

The semiconductor layer of the transistor preferably includes a metal oxide (also referred to as an oxide semiconductor). As the oxide semiconductor having crystallinity, a CAAC (c-axis aligned crystalline)-OS, an nc (nanocrystalline)-OS, and the like are given.

Alternatively, a transistor using silicon in a channel formation region (a Si transistor) may be used. Examples of silicon include single crystal silicon (single crystal Si), polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of a Si transistor such as an LTPS transistor, a circuit required to be driven at a high frequency (e.g., a source driver circuit) can be formed on the same substrate as the display portion. This allows simplification of an external circuit mounted on the light-emitting apparatus and a reduction in component cost and mounting cost.

An OS transistor has much higher field-effect mobility than a transistor using amorphous silicon. In addition, an OS transistor has an extremely low leakage current between a source and a drain in an off state (hereinafter also referred to as off-state current), and charge accumulated in a capacitor that is connected in series to the transistor can be retained for a long period. Furthermore, the power consumption of the light-emitting apparatus can be reduced with the OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting device included in a pixel circuit, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through an OS transistor than through a Si transistor. Thus, with use of an OS transistor as a driving transistor, current can be made flow stably through the light-emitting device, for example, even when a variation in current-voltage characteristics of the light-emitting device occurs. In other words, when the OS transistor operates in the saturation region, the source-drain current hardly changes with an increase in the source-drain voltage; hence, the emission luminance of the light-emitting device can be stable.

As described above, with use of an OS transistor as the driving transistor included in the pixel circuit, it is possible to achieve “inhibition of black floating”, “increase in emission luminance”, “increase in the number of gray levels”, “inhibition of variation in light-emitting devices”, and the like.

The semiconductor film used in the transistor of the driver circuit can be formed in the same step as the semiconductor film used in the transistor of the pixel circuit. The driver circuit can be formed over a substrate where the pixel circuit is formed. The number of components of an electronic apparatus can be reduced.

Silicon may be used for the semiconductor film 508. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of a transistor containing silicon, such as an LTPS transistor, a circuit required to be driven at a high frequency (e.g., a source driver circuit) can be formed on the same substrate as the display portion. This allows simplification of an external circuit mounted on the light-emitting apparatus and a reduction in component cost and mounting cost.

It is preferable to use a transistor containing a metal oxide (hereinafter also referred to as an oxide semiconductor) in its semiconductor where a channel is formed (hereinafter also referred to as an OS transistor) as at least one of the transistors included in the pixel circuit. An OS transistor has much higher field-effect mobility than a transistor using amorphous silicon. In addition, an OS transistor has an extremely low leakage current between a source and a drain in an off state (hereinafter also referred to as off-state current), and charge accumulated in a capacitor that is connected in series to the transistor can be retained for a long period. Furthermore, the power consumption of the light-emitting apparatus can be reduced with the OS transistor.

When LTPS transistors are used as some of the transistors included in the pixel circuit and OS transistors are used as the rest, the light-emitting apparatus can have low power consumption and high driving capability. As a favorable example, it is preferable that an OS transistor be used as a transistor functioning as a switch for controlling electrical continuity between wirings and an LTPS transistor be used as a transistor for controlling current. Note that a structure in which an LTPS transistor and an OS transistor are combined is referred to as LTPO in some cases. LTPO enables the display panel to have low power consumption and high driving capability.

For example, one transistor provided in the pixel circuit functions as a transistor for controlling current flowing through the light-emitting device and can also be referred to as a driving transistor. One of a source and a drain of the driving transistor is electrically connected to the pixel electrode of the light-emitting device. An LTPS transistor is preferably used as the driving transistor. Thus, current flowing through the light-emitting device in the pixel circuit can be increased.

In contrast, another transistor provided in the pixel circuit functions as a switch for controlling selection and non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

In the case of using an oxide semiconductor in a semiconductor film, the apparatus 720 includes a light-emitting device including an oxide semiconductor in its semiconductor film and having an MML (metal maskless) structure. With this structure, the leakage current that might flow through the transistor and the leakage current that might flow between adjacent light-emitting devices (also referred to as lateral leakage current, side leakage current, or the like) can be extremely low. With the structure, a viewer can notice any one or more of the image crispness, the image sharpness, a high chroma, and a high contrast ratio in an image displayed on the display apparatus. When the leakage current that might flow through the transistor and the lateral leakage current that might flow between light-emitting devices are extremely low, display with little leakage of light at the time of black display (what is called black floating) (such display is also referred to as deep black display) can be achieved.

In particular, in the case where a light-emitting device having an MML structure employs the above-described SBS structure, a layer provided between light-emitting devices (for example, also referred to as an organic layer or a common layer which is shared by the light-emitting devices) is divided; accordingly, display with no or extremely small lateral leakage can be achieved.

The structure of transistors used in a display panel may be selected as appropriate depending on the screen size of the display panel. For example, single crystal Si transistors can be used in the display panel with a screen diagonal greater than or equal to 0.1 inches and less than or equal to 3 inches. In addition, LTPS transistors can be used in the display panel with a screen diagonal greater than or equal to 0.1 inches and less than or equal to 30 inches, preferably greater than or equal to 1 inch and less than or equal to 30 inches. In addition, an LTPO structure (where an LTPS transistor and an OS transistor are used in combination) can be used in the display panel with a screen diagonal greater than or equal to 0.1 inches and less than or equal to 50 inches, preferably greater than or equal to 1 inch and less than or equal to 50 inches. In addition, OS transistors can be used in the display panel with a screen diagonal greater than or equal to 0.1 inches and less than or equal to 200 inches, preferably greater than or equal to 50 inches and less than or equal to 100 inches.

Note that with use of single crystal Si transistors, an increase in screen size is extremely difficult because of the size of a single crystal Si substrate. Furthermore, since a laser crystallization apparatus is used in the manufacturing process, LTPS transistors are unlikely to respond to an increase in screen size (typically to a screen diagonal greater than 30 inches). By contrast, since the manufacturing process does not necessarily require a laser crystallization apparatus or the like or can be performed at a relatively low process temperature (typically, lower than or equal to 450° C.), OS transistors can be used for a display panel with a relatively large area (typically, a screen diagonal greater than or equal to 50 inches and less than or equal to 100 inches). In addition, LTPO is applicable to a display panel with a size midway between the case of using LTPS transistors and the case of using OS transistors (typically, a diagonal size greater than or equal to 1 inch and less than or equal to 50 inches).

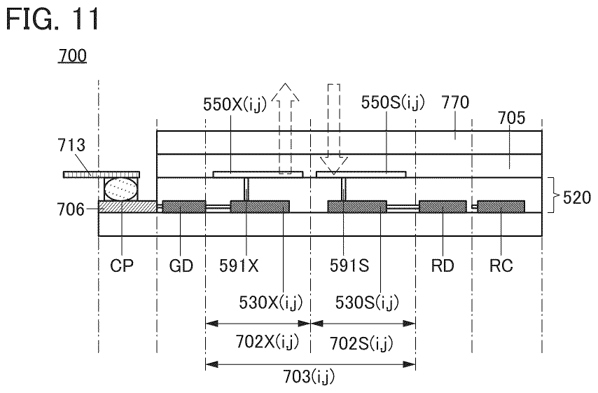

Next, a cross-sectional view of the light-emitting and light-receiving apparatus is shown. FIG. 11 is a cross-sectional view of the light-emitting and light-receiving apparatus illustrated in FIG. 9A.

FIG. 11 is a cross-sectional view of part of a region including the FPC 713 and the wiring 706, and part of the display region 701 including the pixel 703(i,j).

In FIG. 11, the light-emitting and light-receiving apparatus 700 includes the functional layer 520 between the first substrate 510 and the second substrate 770. The functional layer 520 includes, as well as the transistors (M11, M12, M13, M14, M15, M16, and M17), the capacitor (C2 and C3), and the like described with reference to FIG. 10, wirings (VS, VG, V1, V2, V3, V4, and V5) electrically connecting these components, for example. The structure of the functional layer 520 illustrated in FIG. 11 includes a pixel circuit 530X(i,j), a pixel circuit 530S(i,j), and the driver circuit GD; however, it is not limited thereto.

Each pixel circuit (e.g., the pixel circuit 530X(i,j) and the pixel circuit 530S(i,j) in FIG. 11) included in the functional layer 520 is electrically connected to light-emitting devices and light receiving devices (e.g., a light-emitting device 550X(i,j) and a light-receiving device 550S(i,j) in FIG. 11) formed over the functional layer 520. Specifically, the light-emitting device 550X(i,j) is electrically connected to the pixel circuit 530X(i,j) through a wiring 591X, and the light-receiving device 550S(i,j) is electrically connected to the pixel circuit 530S(i,j) through a wiring 591S. The insulating layer 705 is provided over the functional layer 520, the light-emitting devices, and the light-receiving devices and the insulating layer 705 has a function of bonding the second substrate 770 and the functional layer 520.

As the second substrate 770, a substrate where touch sensors are arranged in a matrix can be used. For example, a substrate provided with capacitive touch sensors or optical touch sensors can be used as the second substrate 770. Thus, the light-emitting and light receiving apparatus of one embodiment of the present invention can be used as a touch panel.

Note that the structure described in this embodiment can be used in an appropriate combination with any of the structures described in the other embodiments.

### Embodiment 5

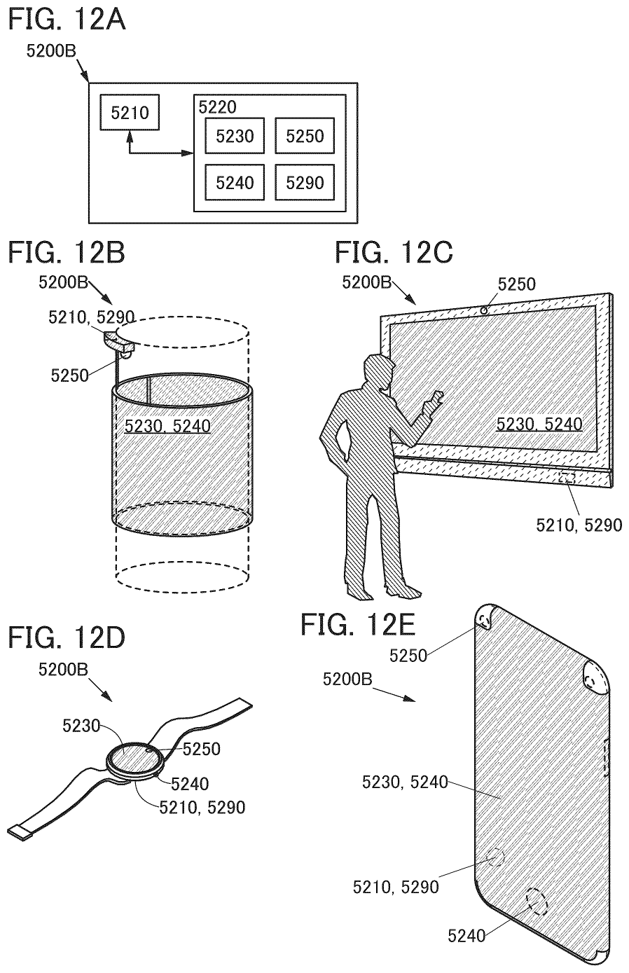

In this embodiment, electronic apparatuses of one embodiment of the present invention will be described with reference to FIG. 12A to FIG. 14B.

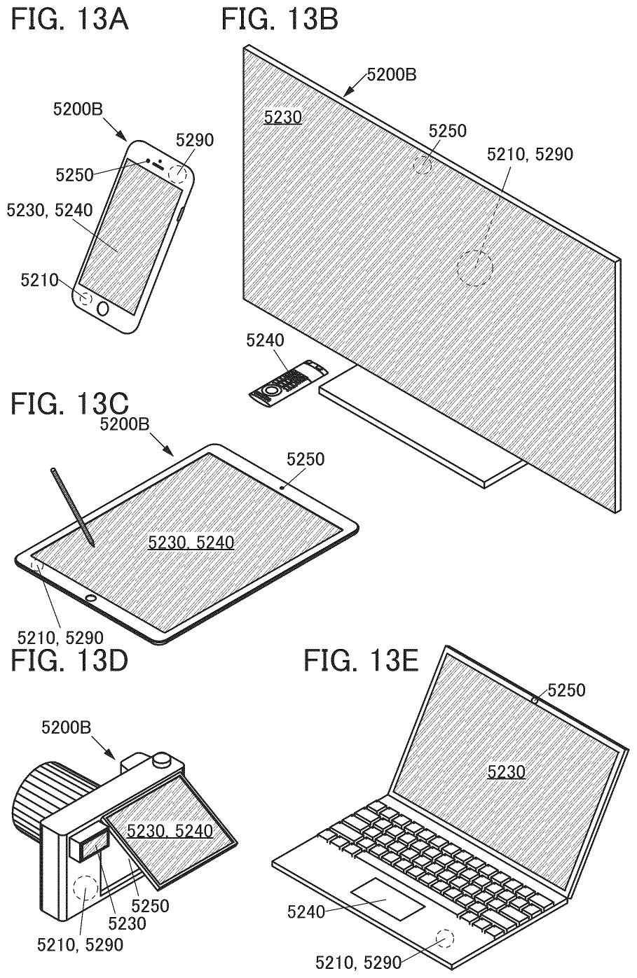

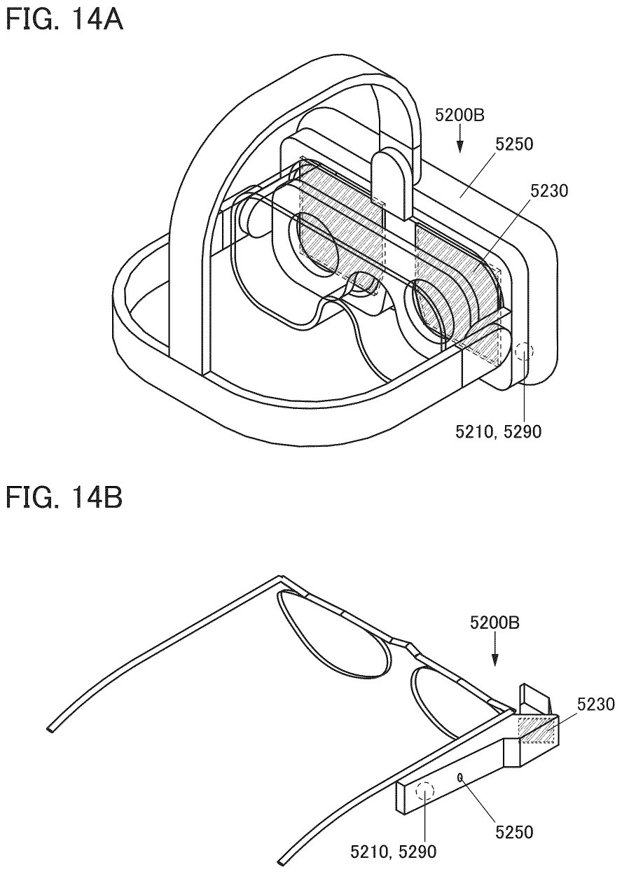

FIG. 12A to FIG. 14B are diagrams illustrating structures of electronic apparatuses of one embodiment of the present invention. FIG. 12A is a block diagram of the electronic apparatus and FIG. 12B to FIG. 12E are perspective views illustrating structures of the electronic apparatuses. FIG. 13A to FIG. 13E are perspective views illustrating structures of electronic apparatuses. FIG. 14A and FIG. 14B are perspective views illustrating structures of electronic apparatuses.

An electronic apparatus 5200B described in this embodiment includes an arithmetic device 5210 and an input/output device 5220 (see FIG. 12A).

The arithmetic device 5210 has a function of being supplied with operation data and has a function of supplying image data on the basis of the operation data.

The input/output device 5220 includes a display portion 5230, an input portion 5240, a detecting portion 5250, and a communication portion 5290 and has a function of supplying operation data and a function of being supplied with image data. The input/output device 5220 also has a function of supplying detection data, a function of supplying communication data, and a function of being supplied with communication data.

The input portion 5240 has a function of supplying operation data. For example, the input portion 5240 supplies operation data on the basis of operation by a user of the electronic apparatus 5200B.

Specifically, a keyboard, a hardware button, a pointing device, a touch sensor, an illuminance sensor, an imaging apparatus, an audio input device, an eye-gaze input device, an attitude detection device, or the like can be used as the input portion 5240.

The display portion 5230 includes a display panel and has a function of displaying image data. For example, the display panel described in Embodiment 3 can be used for the display portion 5230.

The detecting portion 5250 has a function of supplying detection data. For example, the detecting portion 5250 has a function of detecting a surrounding environment where the electronic apparatus is used and supplying detection data.

Specifically, an illuminance sensor, an imaging apparatus, an attitude detection device, a pressure sensor, a human motion sensor, or the like can be used as the detecting portion 5250.

The communication portion 5290 has a function of being supplied with communication data and a function of supplying communication data. For example, the communication portion 5290 has a function of being connected to another electronic apparatus or a communication network through wireless communication or wired communication. Specifically, the communication portion 5290 has a function of wireless local area network communication, telephone communication, near field communication, or the like.

FIG. 12B illustrates an electronic apparatus having an outer shape along a cylindrical column or the like. An example of such an electronic apparatus is digital signage. The display panel of one embodiment of the present invention can be used for the display portion 5230. Note that the electronic apparatus has a function of changing its display method in accordance with the illuminance of a usage environment. Furthermore, the electronic apparatus has a function of changing displayed content in response to detected existence of a person. Thus, for example, the electronic apparatus can be provided on a column of a building. The electronic apparatus can display advertising, guidance, or the like.

FIG. 12C illustrates an electronic apparatus having a function of generating image data on the basis of the path of a pointer used by the user. Examples of such an electronic apparatus include an electronic blackboard, an electronic bulletin board, and digital signage. Specifically, the display panel with a diagonal size of 20 inches or longer, preferably 40 inches or longer, and further preferably 55 inches or longer can be used. Alternatively, a plurality of display panels can be arranged and used as one display region. Alternatively, a plurality of display panels can be arranged and used as a multiscreen.

FIG. 12D illustrates an electronic apparatus that is capable of receiving data from another device and displaying the data on the display portion 5230. An example of such an electronic apparatus is a wearable electronic apparatus. Specifically, the electronic apparatus can display several options, or allow a user to choose some from the options and send a reply to the data transmitter. Alternatively, for example, the electronic apparatus has a function of changing its display method in accordance with the illuminance of a usage environment. Thus, the power consumption of the wearable electronic apparatus can be reduced, for example. Alternatively, an image can be displayed on the wearable electronic apparatus so that the wearable electronic apparatus can be suitably used even in an environment under strong external light, e.g., outdoors in fine weather, for example.

FIG. 12E illustrates an electronic apparatus including the display portion 5230 having a surface gently curved along a side surface of a housing. An example of such an electronic apparatus is a mobile phone. The display portion 5230 includes a display panel, and the display panel has a function of performing display on the front surface, the side surfaces, the top surface, and the rear surface, for example. Thus, for example, a mobile phone can display data not only on the front surface but also on the side surfaces, the top surface, and the rear surface.

FIG. 13A illustrates an electronic apparatus that is capable of receiving data via the Internet and displaying the data on the display portion 5230. An example of such an electronic apparatus is a smartphone. For example, a created message can be checked on the display portion 5230. The created message can be sent to another device. The electronic apparatus has a function of changing its display method in accordance with the illuminance of a usage environment, for example. Thus, the power consumption of a smartphone can be reduced. A smartphone can display an image so that the smartphone can be suitably used even in an environment under strong external light, e.g., outdoors in fine weather, for example.

FIG. 13B illustrates an electronic apparatus that can use a remote controller as the input portion 5240. An example of such an electronic apparatus is a television system. For example, the electronic apparatus that is capable of receiving data from a broadcast station or via the Internet and performing display on the display portion 5230. An image of a user can be taken using the detecting portion 5250. The image of the user can be transmitted. The electronic apparatus can acquire a viewing history of the user and provide it to a cloud service. The electronic apparatus can acquire recommendation data from a cloud service and display the data on the display portion 5230. A program or a moving image can be displayed on the basis of the recommendation data. The electronic apparatus has a function of changing its display method in accordance with the illuminance of a usage environment, for example. Accordingly, for example, the television system can display an image so that the television system can be suitably used even when irradiated with strong external light that enters a room in fine weather.

FIG. 13C illustrates an electronic apparatus that is capable of receiving educational materials via the Internet and displaying them on the display portion 5230. An example of such an electronic apparatus is a tablet computer. An assignment can be input with the input portion 5240 and sent via the Internet. A corrected assignment or the evaluation of the assignment can be obtained from a cloud service and displayed on the display portion 5230. Suitable educational materials can be selected on the basis of the evaluation and displayed.

For example, the display can be performed on the display portion 5230 using an image signal received from another electronic apparatus. When the electronic apparatus is placed on a stand or the like, the display portion 5230 can be used as a sub-display. Thus, for example, a tablet computer can display an image so that the tablet computer can be suitably used even in an environment under strong external light, e.g., outdoors in fine weather.

FIG. 13D illustrates an electronic apparatus including a plurality of display portions 5230. An example of such an electronic apparatus is a digital camera. For example, the display portion 5230 can display an image that the detecting portion 5250 is capturing. A captured image can be displayed on the detecting portion. A captured image can be decorated using the input portion 5240. A message can be attached to a captured image. A captured image can be transmitted via the Internet. The electronic apparatus has a function of changing its shooting conditions in accordance with the illuminance of a usage environment. Accordingly, for example, the digital camera can display an object so that an image is favorably viewed even in an environment under strong external light, e.g., outdoors in fine weather.

FIG. 13E illustrates an electronic apparatus in which the electronic apparatus of this embodiment is used as a master to control another electronic apparatus used as a slave. An example of such an electronic apparatus is a portable personal computer. As an example, part of image data can be displayed on the display portion 5230 and another part of image data can be displayed on a display portion of another electronic apparatus. Image signals can be supplied to another electronic apparatus. With the communication portion 5290, data to be written can be obtained from an input portion of another electronic apparatus. Thus, a large display region can be utilized by using the portable personal computer, for example.

FIG. 14A illustrates an electronic apparatus including the detecting portion 5250 that detects an acceleration or a direction. An example of such an electronic apparatus is a goggles-type electronic apparatus. The detecting portion 5250 can supply data on the position of the user or the direction in which the user faces. The electronic apparatus can generate image data for the right eye and image data for the left eye in accordance with the position of the user or the direction in which the user faces. The display portion 5230 includes a display region for the right eye and a display region for the left eye. Thus, a virtual reality image that gives the user a sense of immersion can be displayed on the goggles-type electronic apparatus, for example.

FIG. 14B illustrates an electronic apparatus including the detecting portion 5250 that detects an acceleration or a direction. An example of such an electronic apparatus is a glasses-type electronic apparatus. The detecting portion 5250 can supply data on the position of the user or the direction in which the user faces. The electronic apparatus can generate image data in accordance with the position of the user or the direction in which the user faces. Accordingly, the data can be shown together with a real-world scene, for example. An augmented reality image can be displayed on the glasses-type electronic apparatus.

Note that this embodiment can be combined with any of the other embodiments described in this specification as appropriate.

### Embodiment 6

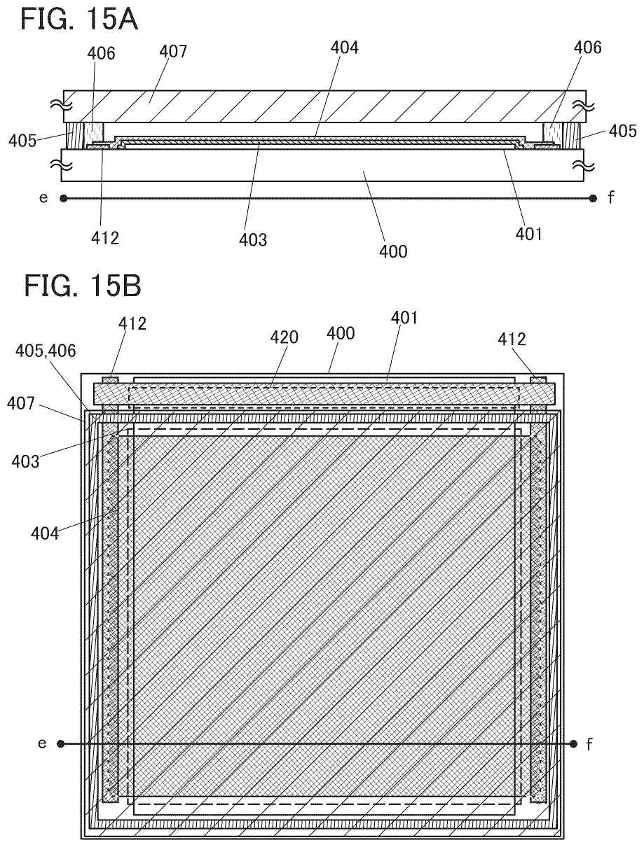

In this embodiment, a structure in which the light-emitting device described in Embodiment 2 is used for a lighting device will be described with reference to FIG. 15. FIG. 15A is a cross-sectional view taken along the line e-f in FIG. 15B which is a top view of a lighting device.

In the lighting device in this embodiment, a first electrode 401 is formed over a substrate 400 which is a support and has a light-transmitting property. The first electrode 401 corresponds to the first electrode 101 in Embodiment 2. In the case where light emission is extracted from the first electrode 401 side, the first electrode 401 is formed with a material having a light-transmitting property.

A pad 412 for supplying a voltage to a second electrode 404 is formed over the substrate 400.

An EL layer 403 is formed over the first electrode 401. The structure of the EL layer 403 corresponds to, for example, the structure of the EL layer 103 in Embodiment 2. Note that for these structures, the corresponding description can be referred to.

The second electrode 404 is formed to cover the EL layer 403. The second electrode 404 corresponds to the second electrode 102 in Embodiment 2. In the case where light-emission is extracted from the first electrode 401 side, the second electrode 404 is formed with a material having high reflectivity. The second electrode 404 is supplied with a voltage when connected to the pad 412.

As described above, the lighting device described in this embodiment includes a light-emitting device including the first electrode 401, the EL layer 403, and the second electrode 404. Since the light-emitting device is a light-emitting device with a high emission efficiency, the lighting device in this embodiment can be a lighting device with low power consumption.

The substrate 400 over which the light-emitting device having the above structure is formed is fixed to a sealing substrate 407 with sealants (405 and 406) and sealing is performed, whereby the lighting device is completed. It is possible to use only either the sealant 405 or the sealant 406. In addition, the inner sealant 406 (not illustrated in FIG. 15B) can be mixed with a desiccant, which enables moisture to be adsorbed, resulting in improved reliability.

When parts of the pad 412 and the first electrode 401 are provided to extend to the outside of the sealant 405 and the sealant 406, those can serve as external input terminals. An IC chip 420 mounted with a converter or the like may be provided over the external input terminals.

### Embodiment 7

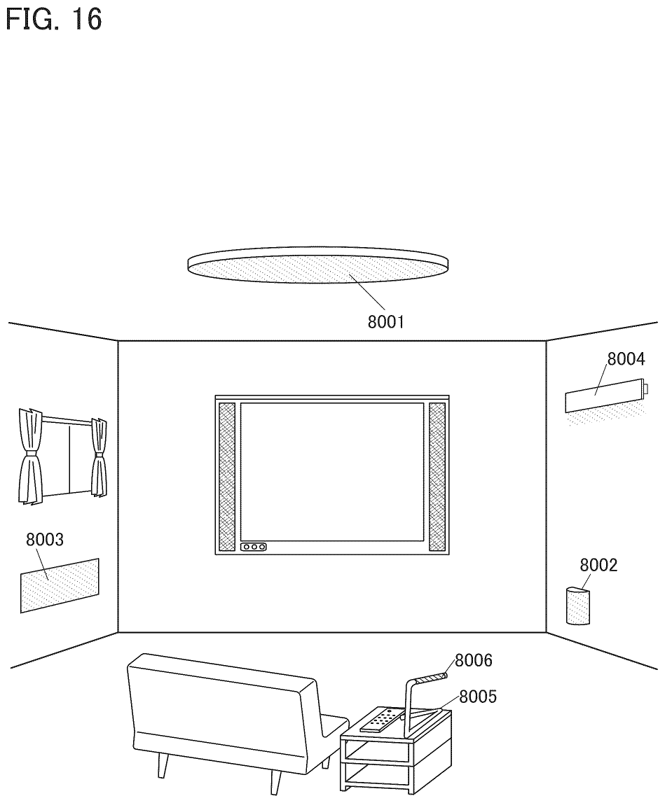

In this embodiment, application examples of lighting devices fabricated using the light-emitting apparatus of one embodiment of the present invention or the light-emitting device, which is part of the light-emitting apparatus, will be described with reference to FIG. 16.

A ceiling light 8001 can be used as an indoor lighting device. Examples of the ceiling light 8001 include a direct-mount light and an embedded light. Such lighting devices are fabricated using the light-emitting apparatus and a housing or a cover in combination. Other than that, application to a cord pendant light (light that is suspended from the ceiling by a cord) is also possible.

A foot light 8002 lights the floor so that safety on the floor can be improved. It can be effectively used in a bedroom, on a staircase, or in a passage, for example. In that case, the size or shape of the foot light can be changed in accordance with the area or structure of a room. The foot light can be a stationary lighting device made from the combination of the light-emitting apparatus and a support.

A sheet-like lighting 8003 is a thin sheet-like lighting device. The sheet-like lighting, which is attached to a wall when used, is space-saving and thus can be used for a wide variety of applications. Furthermore, the area of the sheet-like lighting can be easily increased. The sheet-like lighting can also be used on a wall or housing having a curved surface, for example.

In addition, a lighting device 8004 in which the light from a light source is controlled to be only in a desired direction can be used.

A desk lamp 8005 includes a light source 8006. As the light source 8006, the light-emitting apparatus of one embodiment of the present invention or the light-emitting device, which is part of the light-emitting apparatus, can be used.

In addition to the above examples, when the light-emitting apparatus of one embodiment of the present invention or the light-emitting device which, is part of the light-emitting apparatus, is used as a part of furniture in a room, a lighting device with functions of furniture can be obtained.

As described above, a variety of lighting devices that include the light-emitting apparatus can be obtained. Note that these lighting devices are also embodiments of the present invention.

The structures described in this embodiment can be used in an appropriate combination with any of the structures described in the other embodiments.

### Embodiment 8

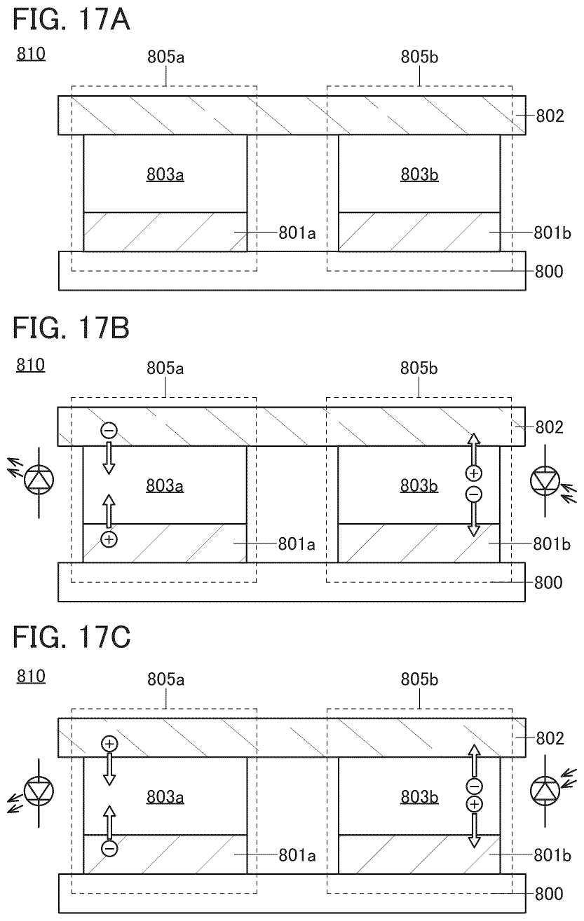

This embodiment will describe a light-emitting and light-receiving apparatus 810 with reference to FIG. 17, for description of a light-emitting device and a light-receiving device that can be used in a display apparatus of one embodiment of the present invention. The light-emitting and light-receiving apparatus 810 includes a light-emitting device and thus can be regarded as a light-emitting apparatus, includes a light-receiving device and thus can be regarded as a light-receiving apparatus, and can be used in a display portion in an electronic apparatus and thus can be regarded as a display panel or a display apparatus.

FIG. 17A is a schematic cross-sectional view illustrating a light-emitting device 805a and a light-receiving device 805b included in the light-emitting and light-receiving apparatus 810 of one embodiment of the present invention.

The light-emitting device 805a has a function of emitting light (hereinafter also referred to as a light-emitting function). The light-emitting device 805a includes an electrode 801a, an EL layer 803a, and an electrode 802. The light-emitting device 805a is preferably a light-emitting device utilizing organic EL (an organic EL device) described in Embodiment 2. The EL layer 803a interposed between the electrode 801a and the electrode 802 includes at least a light-emitting layer. The light-emitting layer contains a light-emitting substance. The EL layer 803a emits light when voltage is applied between the electrode 801a and the electrode 802. The EL layer 803a may include any of a variety of layers such as a hole-injection layer, a hole-transport layer, an electron-transport layer, an electron-injection layer, a carrier-blocking (hole-blocking or electron-blocking) layer, and a charge-generation layer, in addition to the light-emitting layer.

The light-receiving device 805b has a function of detecting light (hereinafter also referred to as a light-receiving function). For example, a pn or pin photodiode can be used as the light-receiving device 805b. The light-receiving device 805b includes an electrode 801b, alight-receiving layer 803b, and the electrode 802. The light-receiving layer 803b interposed between the electrode 801b and the electrode 802 includes at least an active layer. Note that for the light-receiving layer 803b, any of materials that are used for the variety of layers (e.g., the hole-injection layer, the hole-transport layer, the light-emitting layer, the electron-transport layer, the electron-injection layer, the carrier-blocking (hole-blocking or electron-blocking) layer, and the charge-generation layer) included in the above-described EL layer 803a can be used. The light-receiving device 805b functions as a photoelectric conversion device and generates charge on the basis of incident light on the light-receiving layer 803b, and the charge can be extracted as a current. At this time, voltage may be applied between the electrode 801b and the electrode 802. The amount of generated charge is determined depending on the amount of light incident on the light-receiving layer 803b.

The light-receiving device 805b has a function of detecting visible light. The light-receiving device 805b has sensitivity to visible light. The light-receiving device 805b further preferably has a function of detecting visible light and infrared light. The light-receiving device 805b preferably has sensitivity to visible light and infrared light.

In this specification and the like, a blue (B) wavelength range is greater than or equal to 400 nm and less than 490 nm, and blue (B) light has at least one emission spectrum peak in the wavelength range. A green (G) wavelength range is greater than or equal to 490 nm and less than 580 nm, and green (G) light has at least one emission spectrum peak in the wavelength range. A red (R) wavelength range is greater than or equal to 580 nm and less than 700 nm, and red (R) light has at least one emission spectrum peak in the wavelength range. In this specification and the like, a visible light wavelength is greater than or equal to 400 nm and less than 700 nm, and visible light has at least one emission spectrum peak in the wavelength range. An infrared (IR) wavelength range is greater than or equal to 700 nm and less than 900 nm, and infrared (IR) light has at least one emission spectrum peak in the wavelength range.

The active layer of the light-receiving device 805b contains a semiconductor. Examples of the semiconductor include an inorganic semiconductor such as silicon and an organic semiconductor including an organic compound. As the light-receiving device 805b, an organic semiconductor device (or an organic photodiode) including an organic semiconductor in the active layer is preferably used. An organic photodiode, which is easily made thin, lightweight, and large in area and has high flexibility in shape and design, can be employed for a variety of display apparatuses. With use of an organic semiconductor, the EL layer 803a included in the light-emitting device 805a and the light-receiving layer 803b included in the light-receiving device 805b can be formed by the same method (e.g., a vacuum evaporation method) with the same manufacturing apparatus, which is preferable. Note that the organic compound of one embodiment of the present invention can be used for the light-receiving layer 803b in the light-receiving device 805b.

In the display apparatus of one embodiment of the present invention, an organic EL device can be suitably used as the light-emitting device 805a and an organic photodiode can be suitably used as the light-receiving device 805b. The organic EL device and the organic photodiode can be formed over the same substrate. Thus, the organic photodiode can be incorporated in the display apparatus using the organic EL device. The display apparatus of one embodiment of the present invention has one or both of an image capturing function and a sensing function in addition to an image displaying function.

The electrode 801a and the electrode 801b are provided on the same plane. In FIG. 17A, the electrode 801a and the electrode 801b are provided over a substrate 800. The electrode 801a and the electrode 801b can be formed by processing a conductive film formed over the substrate 800 into island-like shapes, for example. In other words, the electrode 801a and the electrode 801b can be formed through the same process.

As the substrate 800, a substrate having heat resistance high enough to withstand the formation of the light-emitting device 805a and the light-receiving device 805b can be used. When an insulating substrate is used as the substrate 800, a glass substrate, a quartz substrate, a sapphire substrate, a ceramic substrate, an organic resin substrate, or the like can be used. Alternatively, a single crystal semiconductor substrate or a polycrystalline semiconductor substrate using silicon or silicon carbide as a material, a compound semiconductor substrate of silicon germanium or the like, or a semiconductor substrate such as an SOI substrate can be used.

As the substrate 800, it is particularly preferable to use the above-described insulating substrate or semiconductor substrate where a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

The electrode 802 is formed of a layer shared by the light-emitting device 805a and the light-receiving device 805b. A conductive film transmitting visible light and infrared light is used as the electrode through which light exits or enters among these electrodes. A conductive film reflecting visible light and infrared light is preferably used as the electrode through which light neither exits nor enters.

The electrode 802 in the display apparatus of one embodiment of the present invention functions as one of the electrodes in each of the light-emitting device 805a and the light-receiving device 805b.

In FIG. 17B, the electrode 801a of the light-emitting device 805a has a potential higher than that of the electrode 802. In this case, the electrode 801a functions as an anode and the electrode 802 functions as a cathode in the light-emitting device 805a. The electrode 801b of the light-receiving device 805b has a potential lower than that of the electrode 802. For easy understanding of the flow direction of current, a circuit symbol of a light-emitting diode is shown on the left of the light-emitting device 805a and a circuit symbol of a photodiode is shown on the right of the light-receiving device 805b in FIG. 17B. The flow directions of carriers (electrons and holes) are also schematically indicated in each device by arrows.

In the structure illustrated in FIG. 17B, when a first potential is supplied to the electrode 801a through a first wiring, a second potential is supplied to the electrode 802 through a second wiring, and a third potential is supplied to the electrode 801b through a third wiring, the following relationship is satisfied: the first potential>the second potential>the third potential.

FIG. 17C illustrates the case where the electrode 801a of the light-emitting device 805a has a potential lower than that of the electrode 802. In this case, the electrode 801a functions as a cathode and the electrode 802 function as an anode in the light-emitting device 805a. The electrode 801b of the light-receiving device 805b has a potential lower than that of the electrode 802 and a potential higher than that of the electrode 801a. For easy understanding of the flow direction of current, FIG. 17B illustrates a circuit symbol of a light-emitting diode on the left of the light-emitting device 805a and a circuit symbol of a photodiode on the right of the light-receiving device 805b. The flow directions of carriers (electrons and holes) are schematically indicated in each device by arrows.

In the light-emitting device 805a in the structure illustrated in FIG. 17C, when the first potential is supplied to the electrode 801a through the first wiring, the second potential is supplied to the electrode 802 through the second wiring, and the third potential is supplied to the electrode 801b through the third wiring, the following relationship is satisfied: the second potential>the third potential>the first potential.

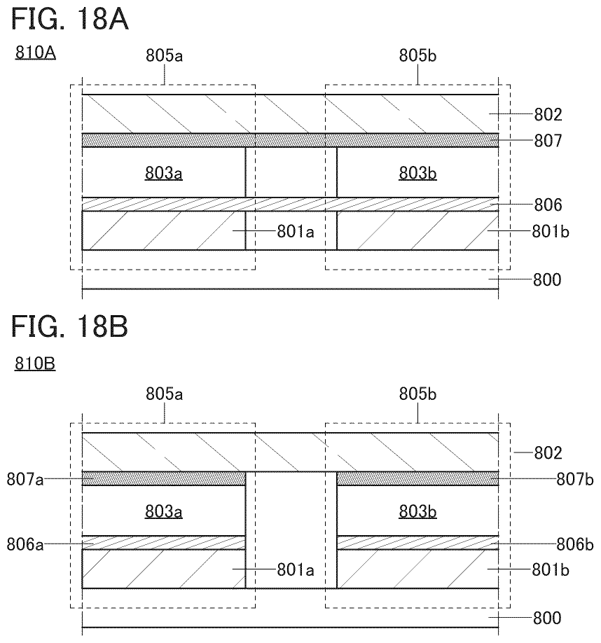

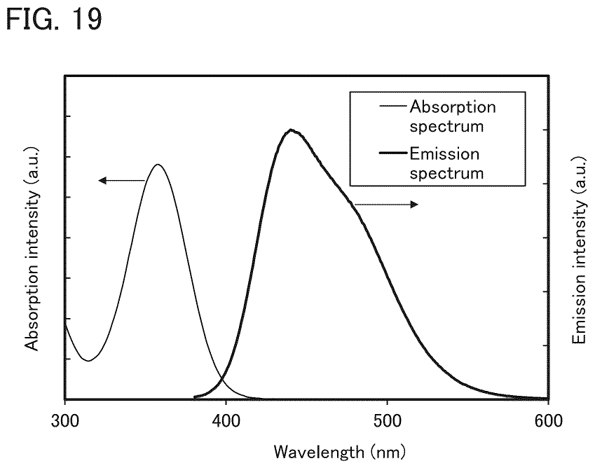

FIG. 18A illustrates a light-emitting and light-receiving apparatus 810A that is a variation example of the light-emitting and light-receiving apparatus 810. The light-emitting and light-receiving apparatus 810A is different from the light-emitting and light-receiving apparatus 810A in including a common layer 806 and a common layer 807. In the light-emitting device 805a, the common layer 806 and the common layer 807 function as part of the EL layer 803a. In the light-receiving device 805b, the common layer 806 and the common layer 807 function as part of the light-receiving layer 803b. The common layer 806 includes a hole-injection layer and a hole-transport layer, for example. The common layer 807 includes an electron-transport layer and an electron-injection layer, for example.

With the common layer 806 and the common layer 807, a light-receiving device can be incorporated without a significant increase in the number of times of separate formation of devices, whereby the light-emitting and light-receiving apparatus 810A can be manufactured with a high throughput.

FIG. 18B illustrates a light-emitting and light-receiving apparatus 810B that is a variation example of the light-emitting and light-receiving apparatus 810. The light-emitting and light-receiving apparatus 810B is different from the light-emitting and light-receiving apparatus 810 in that the EL layer 803a includes a layer 806a and a layer 807a and the light-receiving layer 803b includes a layer 806b and a layer 807b. The layer 806a and the layer 806b are formed using different materials, and each include a hole-injection layer and a hole-transport layer, for example. Note that the layer 806a and the layer 806b may be formed using the same material. The layer 807a and the layer 807b are formed using different materials, and each include an electron-transport layer and an electron-injection layer, for example. Note that the layer 807a and the layer 807b may be formed using the same material.

An optimum material for forming the light-emitting device 805a is selected for the layer 806a and the layer 807a and an optimum material for forming the light-receiving device 805b is selected for the layer 806b and the layer 807b, whereby the light-emitting device 805a and the light-receiving device 805b can have higher performance in the light-emitting and light-receiving apparatus 810B.

Note that the light-receiving devices 805b described in this embodiment can be arranged at a resolution higher than or equal to 100 ppi, preferably higher than or equal to 200 ppi, more preferably higher than or equal to 300 ppi, further preferably higher than or equal to 400 ppi, still further preferably higher than or equal to 500 ppi and lower than or equal to 2000 ppi, lower than or equal to 1000 ppi, or lower than or equal to 600 ppi, for example. In particular, when the light-receiving devices 805b are arranged at a resolution higher than or equal to 200 ppi and lower than or equal to 600 ppi, preferably higher than or equal to 300 ppi and lower than or equal to 600 ppi, the light-receiving devices can be suitably used for image capturing of a fingerprint. In the case where fingerprint authentication is performed with the display apparatus of one embodiment of the present invention, the increased resolution of the light-receiving devices 805b enables, for example, highly accurate extraction of the minutiae of fingerprints; thus, the accuracy of the fingerprint authentication can be increased. The resolution is preferably higher than or equal to 500 ppi, in which case the authentication conforms to the standard by the National Institute of Standards and Technology (NIST) or the like. On the assumption that the resolution at which the light-receiving devices are arranged is 500 ppi, the size of each pixel is 50.8 m, which indicates that the resolution is adequate for image capturing of a fingerprint ridge distance (typically, greater than or equal to 300 m and less than or equal to 500 m).

The structures described in this embodiment can be used in an appropriate combination with any of the structures described in the other embodiments.

### Example 1

### Synthesis Example 1

In this example, a method for synthesizing bis[hydrotris(pyrazolide-N1)borato(1-)—N2,N2′,N2″][dihydrobis(pyrazolide-N1)borato(1-)—N2,N2′]cerium(III) (abbreviation: [Ce(bpz₃)₂(bpz₂)]), which is one embodiment of the organometallic complex of the present invention represented by Structural Formula (125) in Embodiment 1, will be described. The structure of [Ce(bpz₃)₂(bpz₂)] is shown below.

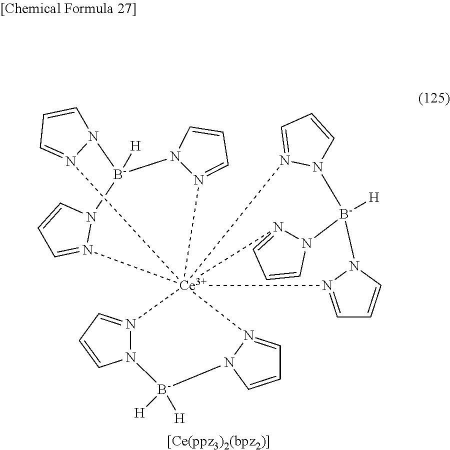

<Step 1: Synthesis of potassium bis(1-pyrazolyl)borate>

Into a 200 mL three-neck flask equipped with a reflux tower were put 20 g (294 mmol) of pyrazole and 4.0 g (73.5 mmol) of potassium borohydride, and the air in the system was replaced with nitrogen. After 70 mL of dehydrated toluene was added and the mixture was degassed, the mixture was stirred at 110° C. for 16 hours while being heated and refluxed. After the stirring, a white solid in the reaction solution was subjected to suction filtration, the white solid on filter paper was dissolved in heated toluene, and a filtrate was collected. The obtained filtrate was cooled to room temperature, whereby a white solid was precipitated. This white solid was subjected to suction filtration, washed with dichloromethane and diethyl ether, and then dried to give a white solid (7.0 g, a yield of 51%). The synthesis scheme in Step 1 is shown in Formula (a-1) below.

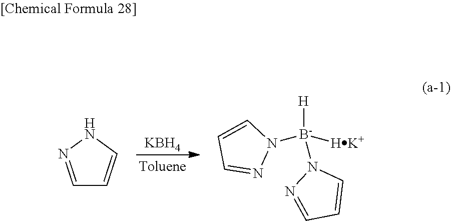

<Step 2: Synthesis of [Ce(bpz₃)₂(bpz₂)]>

Into a 500 mL three-neck flask were put 5.0 g (20 mmol) of potassium tris(1-pyrazolyl)borate, 1.9 g (9.9 mmol) of potassium bis(1-pyrazolyl)borate, and 3.7 g (9.9 mmol) of cerium(III) chloride heptahydrate, and the air in the system was replaced with nitrogen. Then, 230 mL of dehydrated methanol was added, and the mixture was stirred at room temperature for 2.5 hours. After the stirring, a white solid in the reaction solution was subjected to suction filtration through a membrane filter to give a filtrate. A solvent of this filtrate was distilled off with an evaporator, so that a white solid was obtained. Next, dichloromethane was added to the white solid, centrifugation was performed, and then a supernatant solution was filtered and a solvent of the obtained filtrate was distilled off with an evaporator, whereby a white solid (1.3 g, a yield of 18%) that is a target organometallic complex was obtained. The synthesis scheme in Step 2 is shown in Formula (a-2) below.

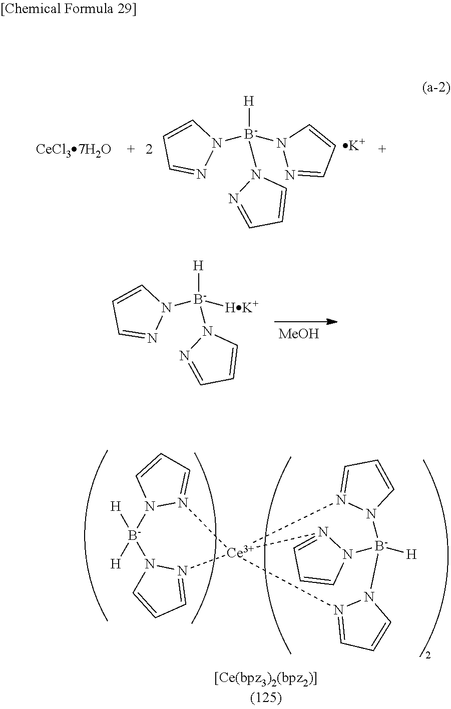

Then, 400 mg of the obtained white solid was sublimated and purified at 200° C. for 1.5 hours with a sublimation purification apparatus for a small quantity, whereby a white solid (143 mg, a collection rate of 36%) was obtained.

Measurement by matrix-assisted laser desorption-ionization mass spectrometry (MALDI-MS) was performed in order to find the molecular weight of the sample. The measurement was performed in a positive mode. From the MALDI-MS, ions with m/z=713.2, 566.1, and 500.1 were detected in the mass spectrum. From the result, the ions were presumed to be C₂₄H₂₈B₃CeN₁₆, which is a composition formula of a target substance, C₁₈H₂₀B₂CeN₁₂, which is a composition formula from which one bis(1-pyrazolyl)borate as a ligand was subtracted, and C₁₅H₁₈B₂CeN₁₀, which is a composition formula from which one tris(1-pyrazolyl)borate as a ligand was subtracted. It was found from the above that the target organometallic complex, [Ce(bpz₃)₂(bpz₂)], was obtained.

Next, an ultraviolet-visible absorption spectrum (hereinafter simply referred to as an “absorption spectrum”) and an emission spectrum of [Ce(bpz₃)₂(bpz₂)] in a dichloromethane solution were measured. The absorption spectrum was measured at room temperature with an ultraviolet-visible light spectrophotometer (V550 manufactured by JASCO Corporation). The absorption spectrum is the result obtained in such a way that the absorption spectrum measured by putting only dichloromethane in a quartz cell was subtracted from the absorption spectrum measured by putting the dichloromethane solution (0.10 mmol/L) in a quartz cell. The measurement of the emission spectrum was conducted at room temperature, for which an absolute PL quantum yield measurement system (C11347-01 manufactured by Hamamatsu Photonics K.K.) was used and the deoxidized dichloromethane solution (0.10 mmol/L) was put and sealed in a quartz cell under a nitrogen atmosphere in a glove box (LABstar M13 (1250/780) manufactured by Bright Co., Ltd.).

FIG. 19 shows measurement results of the absorption spectrum and the emission spectrum. The horizontal axis represents a wavelength and the vertical axes represent absorption intensity and emission intensity. Of the two solid lines, the thin line represents the absorption spectrum and the thick line represents the emission spectrum.

As shown in FIG. 19, [Ce(bpz₃)₂(bpz₂)] had an emission peak at 440 nm, and blue light emission from the dichloromethane solution was observed.

### Example 2

### Synthesis Example 2

In this example, a method for synthesizing bis[hydrotris(1,2,4-triazolide-N1)borato(1-)—N2,N2′,N2″ ][dihydrobis(1,2,4-triazolide-NT)borato(1-)—N2,N2′]cerium(III) (abbreviation: [Ce(btaz₃)₂(btaz₂)]), which is one embodiment of the organometallic complex of the present invention represented by Structural Formula (150) in Embodiment 1, will be described. The structure of [Ce(btaz₃)₂(btaz₂)] is shown below.

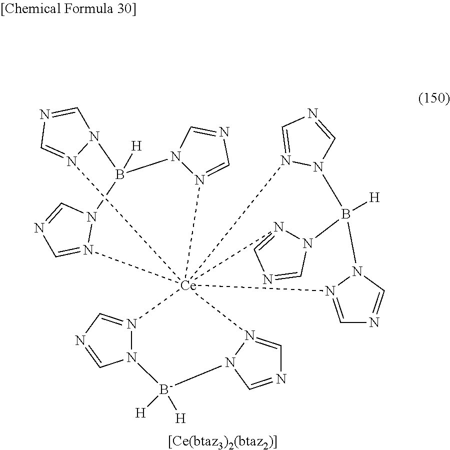

<Step 1: Synthesis of potassium bis(1-triazolyl)borate>

Into a 100 mL three-neck flask equipped with a reflux tower were put 10.0 g (144.8 mmol) of 1,2,4-triazole and 2.0 g (36.2 mmol) of sodium borohydride, and the air in the system was replaced with nitrogen. After 35 mL of dehydrated toluene was added and the mixture was degassed, the mixture was stirred at 110° C. for 13 hours while being heated and refluxed. After the stirring, a solid precipitated in the reaction solution was subjected to suction filtration and was washed with dichloromethane. The obtained white solid was dissolved in ethanol, recrystallization was performed using dichloromethane as a poor solvent, and then the resultant substance was subjected to suction filtration, washed with dichloromethane, and dried to give a white solid (4.9 g, a yield of 73%). The synthesis scheme in Step 1 is shown in Formula (b-1) below.

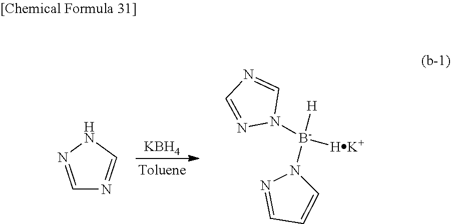

### Step 2: Synthesis of potassium tris(1-triazolyl)borate

Into a 100 mL three-neck flask equipped with a reflux tower were put 15.0 g (217.2 mmol) of 1,2,4-triazole and 2.9 g (54.3 mmol) of sodium borohydride, and the air in the system was replaced with nitrogen. The heating temperature was gradually increased to 190° C., and the mixture was stirred for 5 hours while being heated. After the reaction, a solid in the flask was dissolved in ethanol, and recrystallization was performed using toluene as a poor solvent. The precipitate was subjected to suction filtration, washed with dichloromethane, and then dried to give a white solid (8.8 g, a yield of 64%). The synthesis scheme in Step 2 is shown in Formula (b-2) below.

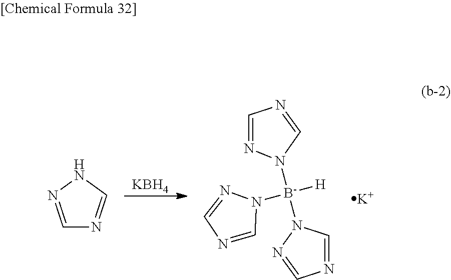

### Step 3: Synthesis of [Ce(btaz₃)₂(btaz₂)]

Into a 300 mL three-neck flask were put 2.2 g (8.6 mmol) of potassium tris(1-triazolyl)borate, 0.81 g (4.3 mmol) of potassium bis(1-triazolyl)borate, and 1.6 g (4.3 mmol) of cerium(III) chloride heptahydrate, and the air in the system was replaced with nitrogen. Then, 100 mL of dehydrated methanol was added, and the mixture was stirred at room temperature for 64 hours. After the stirring, the solvent was distilled off. The obtained solid was subjected to suction filtration with hexane, whereby a white solid (1.8 g, a yield of 57%) that is a target organometallic complex was obtained. The synthesis scheme in Step 3 is shown in Formula (b-3) below.

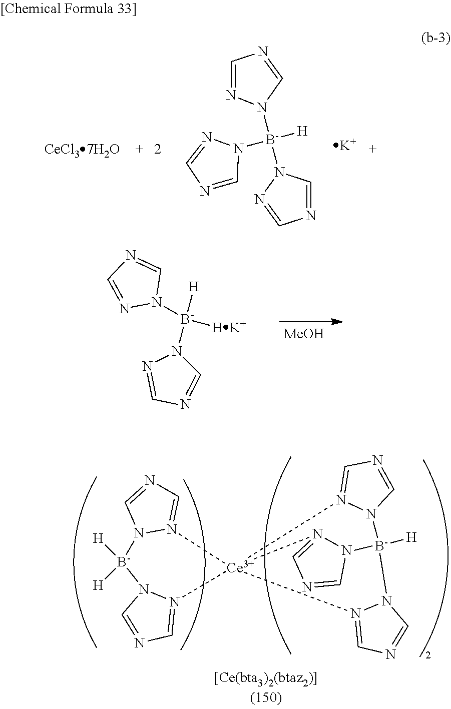

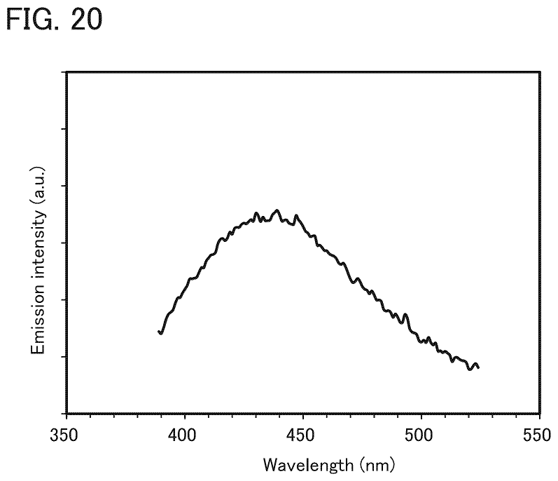

Next, an emission spectrum of [Ce(btaz₃)₂(btaz₂)] in a dichloromethane solution was measured. The measurement of the emission spectrum was conducted at room temperature, for which a spectrofluorometer (FP8600 manufactured by JASCO Corporation) was used and the deoxygenated dichloromethane solution (0.10 mmol/L) was put and hermetically sealed into a quartz cell in a nitrogen atmosphere. The measurement result of the emission spectrum is shown in FIG. 20. The horizontal axis represents a wavelength and the vertical axis represents emission intensity.

From the results in FIG. 20, an emission wavelength peak of [Ce(btaz₃)₂(btaz₂)] in the dichloromethane solution was observed at around 440 nm.

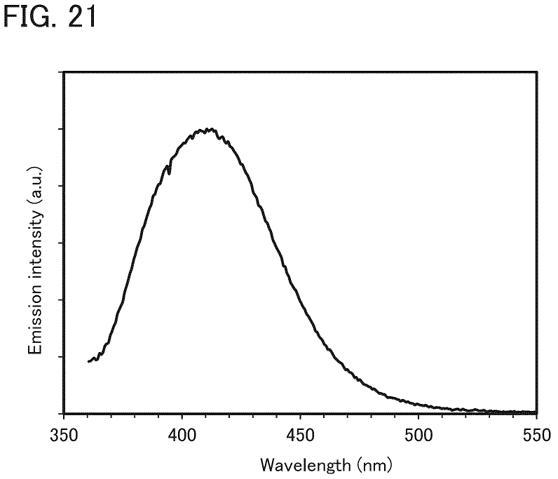

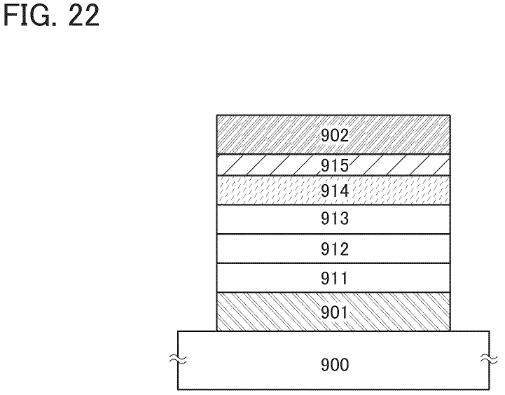

Next, an emission spectrum of a powder of [Ce(btaz₃)₂(btaz₂)] were measured. The measurement of the emission spectrum was conducted at room temperature, for which an absolute PL quantum yield measurement system (C11347-01 manufactured by Hamamatsu Photonics K.K.) was used and the powder was put on a sallet for powder measurement. FIG. 21 shows the obtained measurement result of the emission spectrum of the powder. The horizontal axis represents wavelength, and the vertical axis represents emission intensity.

From the result in FIG. 21, an emission wavelength peak of the powder of [Ce(btaz₃)₂(btaz₂)] was observed at around 413 nm.

### Example 3

This example will describe a device structure and characteristics of a light-emitting device 1 using [Ce(bpz₃)₂(bpz₂)], which is described in Example 1, in a light-emitting layer as the light-emitting device of one embodiment of the present invention. Table 1 shows specific components of the light-emitting device 1 used in this example. Chemical formulae of materials used in this example are shown below.

TABLE 1

| | Film | |
|---|---|---|
| | thickness | |
| | (nm) | Light-emitting device 1 |
| Second electrode | 200 | Al |
| Electron-injection | 1 | LiF |
| layer | | |
| Electron-transport | 15 | NBPhen |
| layer | 10 | TPBI |
| Light-emitting layer | 25 | PCCP:35DCzPPy:[Ce(bpz₃)₂(bpz₂)] |
| | | (0.7:0.3:1) |
| Hole-transport layer | 30 | PCCP |
| Hole-injection layer | 10 | DBT3P-II:MoOx (4:2) |
| First electrode | 70 | ITSO |

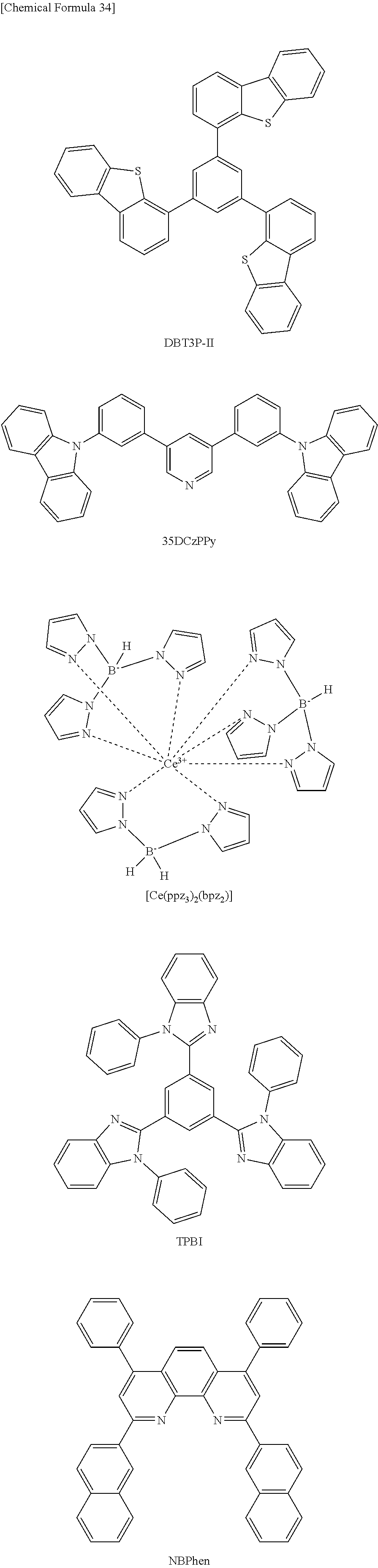

### <<Fabrication of Light-Emitting Device 1>>

The light-emitting device 1 described in this example has a structure, as illustrated in FIG. 22, in which a hole-injection layer 911, a hole-transport layer 912, alight-emitting layer 913, an electron-transport layer 914, and an electron-injection layer 915 are stacked in this order over a first electrode 901 formed over a substrate 900, and a second electrode 902 is stacked over the electron-injection layer 915.

First, the first electrode 901 was formed over the substrate 900. The electrode area was set to 4 mm² (2 mm×2 mm). A glass substrate was used as the substrate 900. The first electrode 901 was formed by deposition of indium tin oxide containing silicon oxide (ITSO) by a sputtering method to a film thickness of 70 nm. Note that in this example, the first electrode 901 functioned as an anode.

As pretreatment, a surface of the substrate was washed with water, baking was performed at 200° C. for one hour, and then UV ozone treatment was performed for 370 seconds. After that, the substrate was transferred into a vacuum evaporation apparatus where the inside pressure had been reduced to approximately 10⁻⁴ Pa, and was subjected to vacuum baking at 170° C. for 60 minutes in a heating chamber of the vacuum evaporation apparatus, and then the substrate was cooled down for approximately 30 minutes.

Next, the hole-injection layer 911 was formed over the first electrode 901. For the formation of the hole-injection layer 911, the pressure in the vacuum evaporation apparatus was reduced to 10-4 Pa, and then 4,4′,4″-(benzene-1,3,5-triyl)tri(dibenzothiophene) (abbreviation: DBT3P-II) and molybdenum oxide (abbreviation: MoOx) were co-evaporated such that DBT3P-II: MoOx was 4:2 (mass ratio) and the thickness was 10 nm.

Then, the hole-transport layer 912 was formed over the hole-injection layer 911. The hole-transport layer 912 was formed to a thickness of 30 nm by evaporation of 3,3′-bis(9-phenyl-9H-carbazole) (abbreviation: PCCP).

Next, the light-emitting layer 913 was formed over the hole-transport layer 912.

The light-emitting layer 913 was formed to a thickness of 25 nm by co-evaporation of PCCP, 3,5-bis[3-(9H-carbazol-9-yl)phenyl]pyridine (abbreviation: 35DCzPPy) (abbreviation: 35DCzPPy), and [Ce(bpz₃)₂(bpz₂)] at 0.7:0.3:1.

Next, the electron-transport layer 914 was formed over the light-emitting layer 913. The electron-transport layer 914 was formed in the following manner: 2,2′,2″-(1,3,5-benzenetriyl)tris(1-phenyl-1H-benzimidazole) (abbreviation: TPBI) was deposited by evaporation to a thickness of 10 nm, and then 2,9-di(2-naphthyl)-4,7-diphenyl-1,10-phenanthroline (abbreviation: NBPhen) was deposited by evaporation to a thickness of 15 nm.

Then, the electron-injection layer 915 was formed over the electron-transport layer 914. The electron-injection layer 915 was formed to a thickness of 1 nm by evaporation of lithium fluoride (LiF).

Next, the second electrode 902 was formed over the electron-injection layer 915. The second electrode 902 was formed using aluminum by an evaporation method such that the film thickness was 200 nm. In this example, the second electrode 902 functions as a cathode.

Through the above steps, the light-emitting device 1 in which an EL layer was provided between the pair of electrodes over the substrate 900 was formed. The hole-injection layer 911, the hole-transport layer 912, the light-emitting layer 913, the electron-transport layer 914, and the electron-injection layer 915 described in the above steps are functional layers forming the EL layer in one embodiment of the present invention. Furthermore, in all the evaporation steps in the above fabrication method, an evaporation method by a resistance-heating method was used.

The fabricated light-emitting device 1 was sealed in a glove box containing a nitrogen atmosphere so as not to be exposed to the air (a sealant was applied to surround the device, and at the time of sealing, UV treatment was performed and then heat treatment was performed at 80° C. for one hour).

### <<Operating Characteristics of Light-Emitting Device 1>>

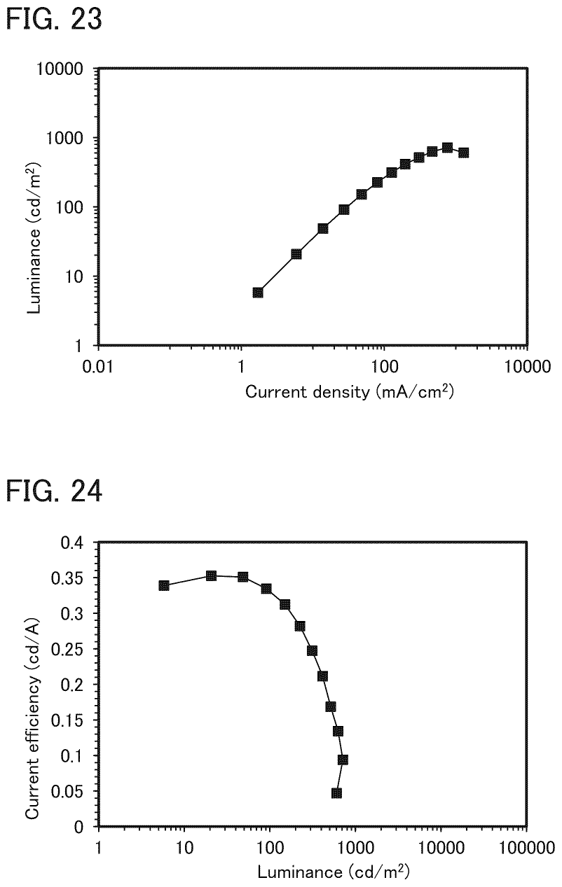

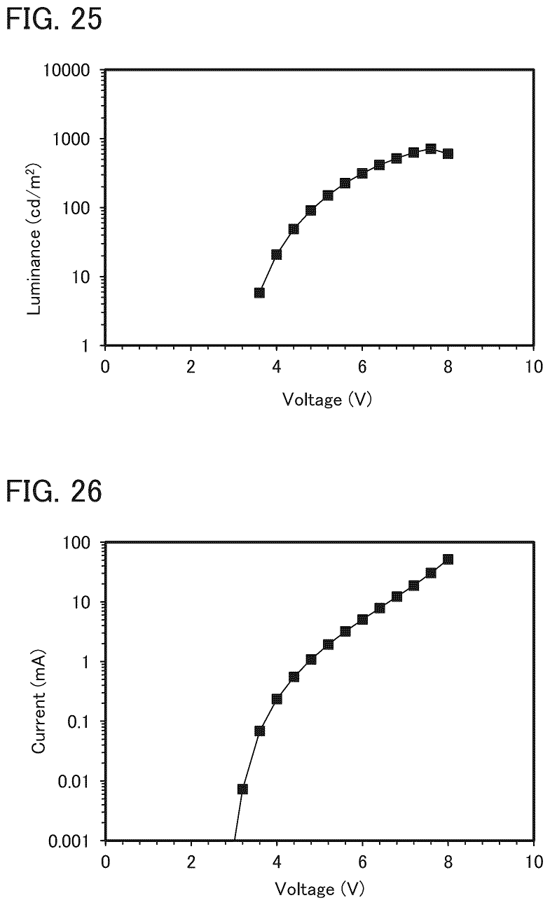

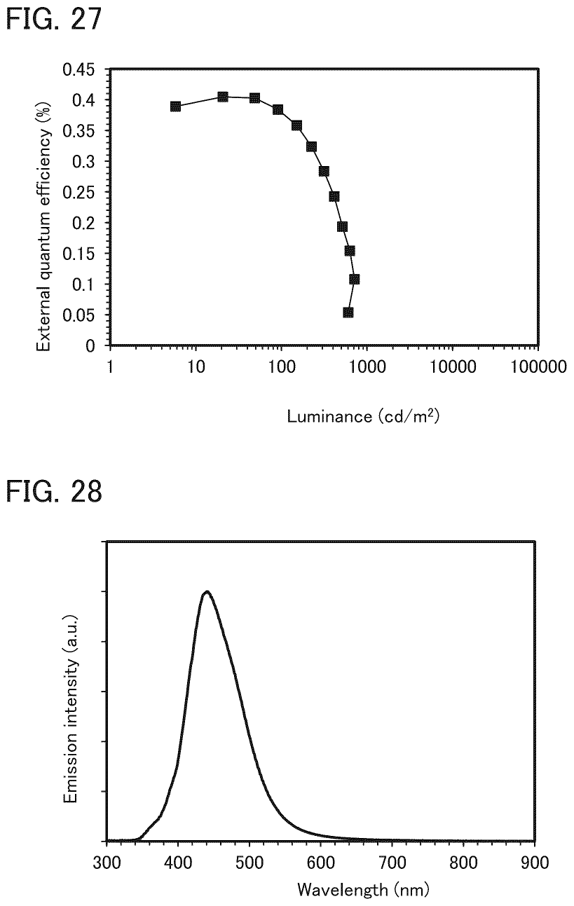

Next, the operating characteristics of the light-emitting device 1 were measured. Note that the measurement was conducted at room temperature (in an atmosphere maintained at 25° C.). FIG. 23 shows the luminance-current density characteristics of the light-emitting device 1, FIG. 24 shows the current efficiency-luminance characteristics thereof, FIG. 25 shows the luminance-voltage characteristics thereof, FIG. 26 shows the current-voltage characteristics thereof, and FIG. 27 shows the external quantum efficiency-luminance characteristics thereof. The initial values of main characteristics of the light-emitting device 1 at approximately 630 cd/m² are listed in Table 2 below.

TABLE 2

| | | | Current | | | Current | |
|---|---|---|---|---|---|---|---|
| | Voltage | Current | density | Chromaticity | Chromaticity | efficiency | External quantum |
| | (V) | (mA) | (mA/cm²) | x | y | (cd/A) | efficiency (%) |
| Light-emitting device 1 | 7.2 | 18.7 | 468 | 0.174 | 0.190 | 0.134 | 0.154 |

FIG. 28 shows the emission spectrum of the light-emitting device 1 to which current flows at a current density of 2.5 mA/cm². As shown in FIG. 28, the emission spectrum of the light-emitting device 1 has a peak at 440 nm, which indicates that the light-emitting device 1 emits light derived from the organometallic complex [Ce(bpz₃)₂(bpz₂)] included in the EL layer.

### REFERENCE NUMERALS

GD: driver circuit, IR: subpixel, M11: transistor, M12: transistor, M13: transistor, M14: transistor, M15: transistor, M16: transistor, M17: transistor, MS: wiring, PS: subpixel, RES: resist mask, RE1: wiring, SET: wiring, SE: distance, TX: wiring, VG: wiring, VS: wiring, 101: first electrode, 102: second electrode, 103: EL layer, 103a: EL layer, 103b: EL layer, 103B: EL layer, 103G: EL layer, 103R: EL layer, 103PS: light-receiving layer, 104B: hole-injection/transport layer, 104G: hole-injection/transport layer, 104R: hole-injection/transport layer, 104PS: hole-injection/transport layer, 105B: light-emitting layer, 105G: light-emitting layer, 105R: light-emitting layer, 105PS: active layer, 106: charge generation layer, 106a: charge generation layer, 106b: charge generation layer, 107: insulating layer, 108B: electron-transport layer, 108G: electron-transport layer, 108R: electron-transport layer, 108PS: electron-transport layer, 109: electron-injection layer, 110B: sacrificial layer, 110G: sacrificial layer, 110R: sacrificial layer, 110PS: sacrificial layer, 111: hole-injection layer, 111a: hole-injection layer, 111b: hole-injection layer, 112: hole-transport layer, 112a: hole-transport layer, 112b: hole-transport layer, 113: light-emitting layer, 113a: light-emitting layer, 113b: light-emitting layer, 113c: light-emitting layer, 114: electron-transport layer, 114a: electron-transport layer, 114b: electron-transport layer, 115: electron-injection layer, 115a: electron-injection layer, 115b: electron-injection layer, 130: connection portion, 400: substrate, 401: first electrode, 403: EL layer, 404: second electrode, 405: sealant, 406: sealant, 407: sealing substrate, 412: pad, 420: IC chip, 501C: insulating film, 501D: insulating film, 504: conductive film, 506: insulating film, 508: semiconductor film, 508A: region, 508B: region, 508C: region, 510: first substrate, 512A: conductive film, 512B: conductive film, 516: insulating film, 516A: insulating film, 516B: insulating film, 518: insulating film, 520: functional layer, 524: conductive film, 528: partition, 528a: resin film, 530: pixel circuit, 530S: pixel circuit, 530X: pixel circuit, 531: pixel circuit, 550: light-emitting device, 550X: light-emitting device, 550S: light-receiving device, 550B: light-emitting device, 550G: light-emitting device, 550R: light-emitting device, 550PS: light-receiving device, 551B: electrode, 551C: connection electrode, 551G: electrode, 551R: electrode, 551PS: electrode, 552: electrode, 580: space, 591S: wiring, 591X: wiring, 700: light-emitting and light-receiving apparatus, 701: display region, 702B: subpixel, 702G: subpixel, 702PS: subpixel, 702R: subpixel, 702IR: subpixel, 703: pixel, 704: circuit, 705: insulating layer, 706: wiring, 710: substrate, 711: substrate, 712: IC, 713: FPC, 720: apparatus, 770: substrate, 800: substrate, 801a: electrode, 801b: electrode, 802: electrode, 803a: EL layer, 803b: light-receiving layer, 805a: light-emitting device, 805b: light-receiving device, 810: light-emitting and light-receiving apparatus, 810A: light-emitting and light-receiving apparatus, 810B: light-emitting and light-receiving apparatus, 900: substrate, 901: first electrode, 902: second electrode, 911: hole-injection layer, 912: hole-transport layer, 913: light-emitting layer, 914: electron-transport layer, 915: electron-injection layer, 5200B: electronic apparatus, 5210: arithmetic device, 5220: input/output device, 5230: display portion, 5240: input portion, 5250: detecting portion, 5290: communication portion, 8001: ceiling light, 8002: foot light, 8003: sheet-like lighting, 8004: lighting device, 8005: desk lamp, 8006: light source

1. An organometallic complex represented by General Formula (G1): 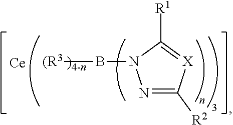
wherein:
X represents carbon or nitrogen;
the carbon is bonded to any one of hydrogen, a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms;
R¹ to R³ each independently represent any one of hydrogen, a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms; and
n represents an integer greater than or equal to 1 and less than or equal to 4.

2. The organometallic complex according to claim 1,
wherein the organometallic complex is represented by General Formula (G2):

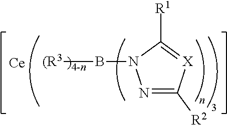

3. The organometallic complex according to claim 1,
wherein the organometallic complex is represented by General Formula (G3): 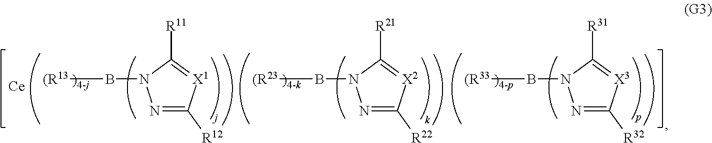
wherein:
X¹ to X³ each independently represent carbon or nitrogen;
the carbons are each independently bonded to any one of hydrogen, a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms;
R¹¹ to R¹³, R²¹ to R²³, and R³¹ to R³³ each independently represent any one of hydrogen, a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms; and
j, k, and p each independently represent an integer greater than or equal to 1 and less than or equal to 4.

4. The organometallic complex according to claim 3,
wherein j represents an integer greater than or equal to 1 and less than or equal to 3.

5. The organometallic complex according to claim 1,
wherein the organometallic complex is represented by General Formula (G4): 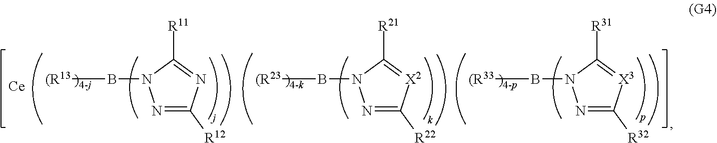
wherein:
X² and X³ each independently represent carbon or nitrogen;
the carbons are each independently bonded to any one of hydrogen, a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms;
R¹¹ to R¹³, R²¹ to R²³, and R³¹ to R³³ each independently represent any one of hydrogen, a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms; and
j, k, and p each independently represent an integer greater than or equal to 1 and less than or equal to 4.

6. The organometallic complex according to claim 1,
wherein the organometallic complex is represented by General Formula (G5): 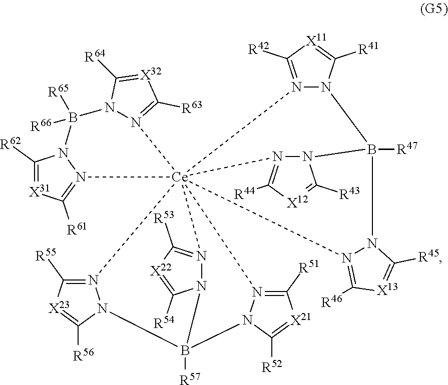
wherein:
X¹¹ to X¹³, X²¹ to X²³, X³¹, and X³² each independently represent carbon or nitrogen;
the carbons are each independently bonded to any one of hydrogen, a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms; and
R⁴¹ to R⁴⁷, R⁵¹ to R⁵⁷, and R⁶¹ to R⁶⁶ each independently represent any one of hydrogen, a substituted or unsubstituted alkyl group having 1 to 10 carbon atoms, a substituted or unsubstituted cycloalkyl group having 3 to 10 carbon atoms, and a substituted or unsubstituted aryl group having 6 to 30 carbon atoms.

7. The organometallic complex according to claim 1,
wherein the organometallic complex is represented by Structural Formula (125) or (150):

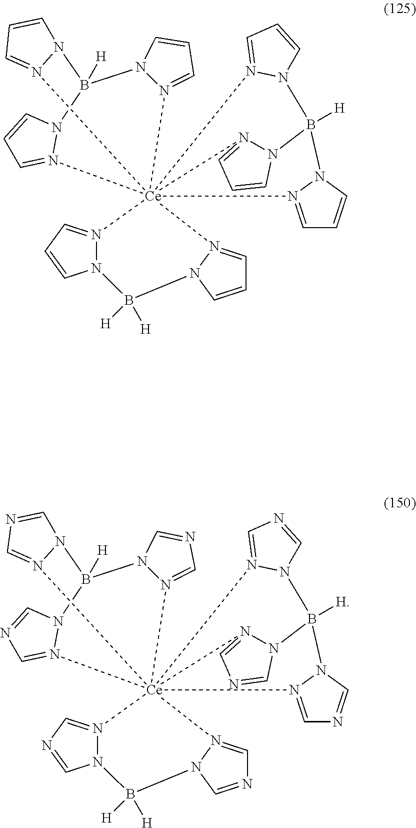

8. A light-emitting device comprising the organometallic complex according to claim 1.

9. A light-emitting apparatus comprising:
the light-emitting device according to claim 8, and
a transistor or a substrate.

10. An electronic apparatus comprising:
the light-emitting apparatus according to claim 9, and
any one of a detecting portion, an input portion, and a communication portion.

11. A lighting device comprising:
the light-emitting apparatus according to claim 9, and
a housing.

12. The organometallic complex according to claim 1,
wherein borate ligands are the same.

13. The organometallic complex according to claim 1,
wherein n of one borate ligand is the same as n of another borate ligand.

14. The organometallic complex according to claim 1,
wherein in the case where n is 2 or more, X of one borate ligand is the same as X of another borate ligand.

15. The organometallic complex according to claim 1,
wherein in the case where n is 2 or more, R¹ of one borate ligand is the same as R¹ of another borate ligand.

16. The organometallic complex according to claim 1,
wherein in the case where n is 2 or more, R² of one borate ligand is the same as or different from R² of another borate ligand.

17. The organometallic complex according to claim 1,
wherein in the case where n is 2 or less, R³ of one borate ligand is the same as R³ of another borate ligand.

18. The organometallic complex according to claim 3,
in the case where j is 2 or more, X¹'s are the same each other, R¹¹'s are the same each other and R¹²'s are the same each other;
in the case where k is 2 or more, X²'s are the same each other, R²¹'s are the same each other, and R²²'s are the same each other;
in the case where p is 2 or more, X³'s are the same each other, R³¹'s are the same each other, and R³²'s are the same each other;
in the case where j is 2 or less, R¹³'s are the same each other;
in the case where k is 2 or less, R²³'s are the same each other; and
in the case where p is 2 or less, R³³'s are the same each other.

19. The organometallic complex according to claim 5,
in the case where j is 2 or more, R¹¹'s are the same each other and R¹²'s are the same each other;
in the case where k is 2 or more, X²'s are the same each other, R²¹'s are the same each other, and R²²'s are the same each other;
in the case where p is 2 or more, X³'s are the same each other, R³¹'s are the same each other, and R³²'s are the same each other;
in the case where j is 2 or less, R¹³'s are the same each other;
in the case where k is 2 or less, R²³'s are the same each other; and
in the case where p is 2 or less, R³³'s are the same each other.
